(19) United States
(12) Patent Application Publication
(10) Pub. No.: US 2016/0247931 A1
(43) Pub. Date: Aug. 25, 2016

(54) METHOD OF MANUFACTURING SEMICONDUCTOR DEVICE

(71) Applicant: Renesas Electronics Corporation, Tokyo (JP)

(72) Inventor: Akira MITSUIKI, Tokyo (JP)

(73) Assignee: Renesas Electronics Corporation, Tokyo (JP)

(21) Appl. No.: 15/047,732

(22) Filed: Feb. 19, 2016

(30) Foreign Application Priority Data
Feb. 23, 2015 (JP) 2015-032916

(51) Int. Cl. H01L 29/788; H01L 21/28

(52) U.S. Cl. CPC H01L 29/7887; H01L 21/28273; H01L 21/28282

(57) ABSTRACT

An improvement is achieved in the reliability of a semiconductor device. Over a semiconductor substrate, a silicon film, for the memory gate electrode of a memory cell in a nonvolatile memory is formed via an insulating film so as to cover the control gate electrode of the memory cell. After the silicon film and the insulating film are removed from a peripheral circuit region, a silicon film for the gate electrode of a MISFET is formed over the silicon film over a memory cell region of the semiconductor substrate and over the peripheral circuit region thereof. After the silicon film is patterned to form a gate electrode over the peripheral circuit region, the insulating film is removed from the memory cell region. Then, over the silicon film over the memory cell region, an oxide film is formed. Subsequently, the oxide film, and, the silicon film over the silicon film over the memory cell region are etched back to form the memory gate electrode adjacent to the control gate electrode via the insulating film.

### CROSS-REFERENCE TO RELATED APPLICATIONS

The disclosure of Japanese Patent Application No. 2015-032916 filed on Feb. 23, 2015 including the specification, drawings and abstract is incorporated herein by reference in its entirety.

### BACKGROUND

The present invention relates to a method of manufacturing a semiconductor device and can be used appropriately as a method of manufacturing, e.g., a semiconductor device including a nonvolatile memory.

As an electrically writable/erasable nonvolatile semiconductor storage device, an EEPROM (Electrically Erasable and Programmable Read Only Memory) has been used widely. Such a storage device represented by a flash memory which is currently used widely has a conductive floating gate electrode or a trapping insulating film surrounded by oxide films under the gate electrode of a MISFET. A charge storage state in the floating gate electrode or trapping insulating film is used as stored information and read as the threshold of the transistor. The trapping insulating film refers to an insulating film capable of storing charges therein, and examples thereof include a silicon nitride film. By injection/release of charges into/from such a charge storage region, the threshold of the MISFET is shifted to allow the MISFET to operate as a storage element. Examples of the flash memory include a split-gate cell using a MONOS (Metal-Oxide-Nitride-Oxide-Semiconductor) film. In such a memory, a silicon nitride film is used as a charge storage region. This provides advantages over a conductive floating gate film such that, due to discrete storage of charges, data retention reliability is high, and the high data retention reliability allows the oxide films over and under the silicon nitride film to be thinned and allows a voltage for a write/erase operation to be reduced.

Japanese Unexamined Patent Publication No. 2007-184323 (Patent Document 1) describes a technique related to a nonvolatile semiconductor storage device.

### RELATED ART DOCUMENT

### Patent Document

### Patent Document 1

Japanese Unexamined Patent Publication No. 2007-184323

### SUMMARY

Even in a semiconductor device having a nonvolatile memory, it is desired to maximize reliability.

Other problems and novel features of the present invention will become apparent from a statement in the present specification and the accompanying drawings.

According to an embodiment, a method of manufacturing a semiconductor device is a method of manufacturing a semiconductor device including a memory cell in a nonvolatile memory formed in a first region of a semiconductor substrate and a MISFET formed in a second region of the semiconductor substrate. The method of manufacturing the semiconductor device includes the steps of forming a first gate electrode for the memory cell over the first region of the semiconductor substrate via a first insulating film and forming a first conductive film for a second gate electrode of the memory cell over the semiconductor substrate via a second insulating film so as to cover the first gate electrode. The method of manufacturing the semiconductor device further includes the steps of removing the first conductive film and the second insulating film from the second region to leave the first conductive film and the second insulating film over the first region and then forming a second conductive film for a third gate electrode of the MISFET over the first conductive film over the first region and over the second region of the semiconductor substrate via a third insulating film. The method of manufacturing the semiconductor device further includes the steps of patterning the second conductive film to form the third gate electrode for the MISFET over the second region, then removing the third insulating film from the first region, and then forming a fourth insulating film over the first conductive film over the first region. The method of manufacturing the semiconductor device further includes the step of etching back the fourth insulating film and the first conductive film to form the second gate electrode for the memory cell which is adjacent to the first gate electrode via the second insulating film.

According to the embodiment, the reliability of the semiconductor device can be improved.

### BRIEF DESCRIPTION OF THE DRAWINGS

FIG. 1 is a process flow chart showing a part of the manufacturing process of a semiconductor device in an embodiment;

FIG. 2 is a process flow chart showing another part of the manufacturing process of the semiconductor device in the embodiment;

FIG. 3 is a main-portion cross-sectional view of the semiconductor device in the embodiment during the manufacturing process thereof;

FIG. 4 is a main-portion cross-sectional view of the semiconductor device during the manufacturing process thereof, which is subsequent to FIG. 3;

FIG. 5 is a main-portion cross-sectional view of the semiconductor device during the manufacturing process thereof, which is subsequent to FIG. 4;

FIG. 6 is a main-portion cross-sectional view of the semiconductor device during the manufacturing process thereof, which is subsequent to FIG. 5;

FIG. 7 is a main-portion cross-sectional view of the semiconductor device during the manufacturing process thereof, which is subsequent to FIG. 6;

FIG. 8 is a main-portion cross-sectional view of the semiconductor device during the manufacturing process thereof, which is subsequent to FIG. 7;

FIG. 9 is a main-portion cross-sectional view of the semiconductor device during the manufacturing process thereof, which is subsequent to FIG. 8;

FIG. 10 is a main-portion cross-sectional view of the semiconductor device during the manufacturing process thereof, which is subsequent to FIG. 9;

FIG. 11 is a main-portion cross-sectional view of the semiconductor device during the manufacturing process thereof, which is subsequent to FIG. 10;

FIG. 12 is a main-portion cross-sectional view of the semiconductor device during the manufacturing process thereof, which is subsequent to FIG. 11;

FIG. 13 is a main-portion cross-sectional view of the semiconductor device during the manufacturing process thereof, which is subsequent to FIG. 12;

FIG. 14 is a main-portion cross-sectional view of the semiconductor device during the manufacturing process thereof, which is subsequent to FIG. 13;

FIG. 15 is a main-portion cross-sectional view of the semiconductor device during the manufacturing process thereof, which is subsequent to FIG. 14;

FIG. 16 is a main-portion cross-sectional view of the semiconductor device during the manufacturing process thereof, which is subsequent to FIG. 15;

FIGS. 17A, 17B, and 17C are illustrative views illustrating an etch-back step in Step S14;

FIG. 18 is a main-portion cross-sectional view of the semiconductor device during the manufacturing process thereof, which is subsequent to FIG. 16;

FIG. 19 is a main-portion cross-sectional view of the semiconductor device during the manufacturing process thereof, which is subsequent to FIG. 18;

FIG. 20 is a main-portion cross-sectional view of the semiconductor device during the manufacturing process thereof, which is subsequent to FIG. 19;

FIG. 21 is a main-portion cross-sectional view of the semiconductor device during the manufacturing process thereof, which is subsequent to FIG. 20;

FIG. 22 is a main-portion cross-sectional view of the semiconductor device during the manufacturing process thereof, which is subsequent to FIG. 21;

FIG. 23 is a main-portion cross-sectional view of the semiconductor device during the manufacturing process thereof, which is subsequent to FIG. 22;

FIG. 24 is a main-portion cross-sectional view of the semiconductor device during the manufacturing process thereof, which is subsequent to FIG. 23;

FIG. 25 is a main-portion cross-sectional view of the semiconductor device in the embodiment;

FIG. 26 is an equivalent circuit diagram of a memory cell;

FIG. 27 is a table showing an example of conditions under which voltages are applied to the individual portions of a selected memory cell during “Write”, “Erase”, and “Read” operations;

FIG. 28 is a main-portion cross-sectional view of a semiconductor device in a first studied example during the manufacturing process thereof;

FIG. 29 is a main-portion cross-sectional view of the semiconductor device in the first studied example during the manufacturing process thereof, which is subsequent to FIG. 28;

FIG. 30 is a main-portion cross-sectional view of a semiconductor device in a second studied example during the manufacturing process thereof;

FIG. 31 is a main-portion cross-sectional view of the semiconductor device in the second studied example during the manufacturing process thereof, which is subsequent to FIG. 30;

FIG. 32 is a process flow chart showing a part of the manufacturing process of a semiconductor device in another embodiment;

FIG. 33 is a main-portion cross-sectional view of the semiconductor device in the other embodiment during the manufacturing process thereof;

FIG. 34 is a main-portion cross-sectional view of the semiconductor device during the manufacturing process thereof, which is subsequent to FIG. 33;

FIG. 35 is a main-portion cross-sectional view of the semiconductor device during the manufacturing process thereof, which is subsequent to FIG. 34;

FIG. 36 is a main-portion cross-sectional view of the semiconductor device during the manufacturing process thereof, which is subsequent to FIG. 35;

FIG. 37 is a main-portion cross-sectional view of a semiconductor device in still another embodiment during the manufacturing process thereof;

FIG. 38 is a main-portion cross-sectional view of the semiconductor device in the still other embodiment during the manufacturing process thereof;

FIG. 39 is a main-portion cross-sectional view of the semiconductor device during the manufacturing process thereof, which is subsequent to FIG. 38;

FIG. 40 is a main-portion cross-sectional view of the semiconductor device during the manufacturing process thereof, which is subsequent to FIG. 39;

FIG. 41 is a main-portion cross-sectional view of the semiconductor device during the manufacturing process thereof, which is subsequent to FIG. 40;

FIG. 42 is a main-portion cross-sectional view of the semiconductor device during the manufacturing process thereof, which is subsequent to FIG. 41;

FIG. 43 is a main-portion cross-sectional view of the semiconductor device during the manufacturing process thereof, which is subsequent to FIG. 37;

FIG. 44 is a main-portion cross-sectional view of the semiconductor device during the manufacturing process thereof, which is subsequent to FIG. 43;

FIG. 45 is a main-portion cross-sectional view of the semiconductor device during the manufacturing process thereof, which is subsequent to FIG. 44;

FIG. 46 is a main-portion cross-sectional view of the semiconductor device during the manufacturing process thereof, which is subsequent to FIG. 45;

FIG. 47 is a main-portion cross-sectional view of the semiconductor device during the manufacturing process thereof, which is subsequent to FIG. 46;

FIG. 48 is a main-portion cross-sectional view of the semiconductor device during the manufacturing process thereof, which is subsequent to FIG. 47;

FIG. 49 is a main-portion cross-sectional view of the semiconductor device during the manufacturing process thereof, which is subsequent to FIG. 48;

FIG. 50 is a main-portion cross-sectional view of the semiconductor device during the manufacturing process thereof, which is subsequent to FIG. 49;

FIG. 51 is a main-portion cross-sectional view of the semiconductor device during the manufacturing process thereof, which is subsequent to FIG. 50;

FIG. 52 is a main-portion cross-sectional view of the semiconductor device during the manufacturing process thereof, which is subsequent to FIG. 51;

FIG. 53 is a main-portion cross-sectional view of the semiconductor device during the manufacturing process thereof, which is subsequent to FIG. 52;

FIG. 54 is a main-portion cross-sectional view of the semiconductor device during the manufacturing process thereof, which is subsequent to FIG. 53; and

FIG. 55 is a main-portion cross-sectional view of the semiconductor device during the manufacturing process thereof, which is subsequent to FIG. 54.

### DETAILED DESCRIPTION

In the following embodiments, if necessary for the sake of convenience, the embodiments will be each described by being divided into a plurality of sections or embodiments. However, they are by no means irrelevant to each other unless particularly explicitly described otherwise, but are in relations such that one of the sections or embodiments is a modification, details, supplementary explanation, and so forth of part or the whole of the others. Also, in the following embodiments, when the number and the like (including the number, numerical value, amount, range, and the like) of elements are referred to, they are not limited to specific numbers unless particularly explicitly described otherwise or unless they are obviously limited to specific numbers in principle. The number and the like of the elements may be not less than or not more than specific numbers. Also, in the following embodiments, it goes without saying that the components thereof (including also elements, steps, and the like) are not necessarily indispensable unless particularly explicitly described otherwise or unless the components are considered to be obviously indispensable in principle. Likewise, if the shapes, positional relationships, and the like of the components and the like are referred to in the following embodiments, the shapes and the like are assumed to include those substantially proximate or similar thereto and the like unless particularly explicitly described otherwise or unless it can be considered that they obviously do not in principle. The same shall apply in regard to the foregoing numerical value and range.

The embodiments will be described below in detail on the basis of the drawings. Note that, throughout all the drawings for illustrating the embodiments, members having the same functions are designated by the same reference numerals, and a repeated description thereof is omitted. In the following embodiments, a description of the same or like parts will not be repeated in principle unless particularly necessary.

In the drawings used in the embodiments, hatching may be omitted even in a cross section for improved clarity of illustration, while even a plan view may be hatched for improved clarity of illustration.

### Embodiment 1

### About Manufacturing Process of Semiconductor Device

Each of semiconductor devices in the present and following embodiments includes a nonvolatile memory (nonvolatile storage element, flash memory, or nonvolatile semiconductor storage device). In each of the present and following embodiments, the nonvolatile memory will be described on the basis of a memory cell based on an n-channel MISFET (Metal Insulator Semiconductor Field Effect Transistor). Also, in each of the present and following embodiments, polarities (the polarities of voltages applied during write/erase/read operations and carriers) are for describing operations when the memory cell is based on the n-channel MISFET. When the memory cell is based on a p-channel MISFET, by inverting all the polarities such as the polarities of applied potentials and carriers, basically the same operations can be obtained.

Referring to the drawings, a method of manufacturing the semiconductor device in the present embodiment will be described.

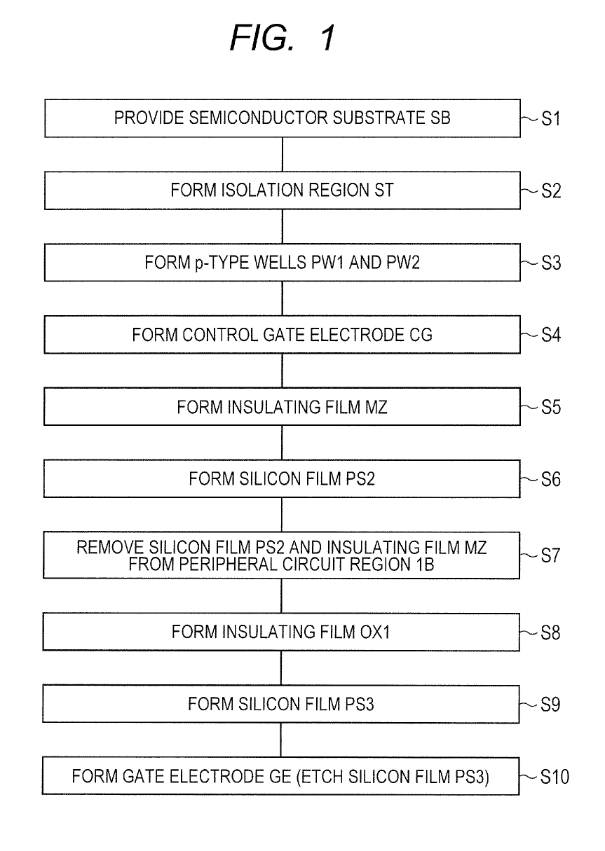

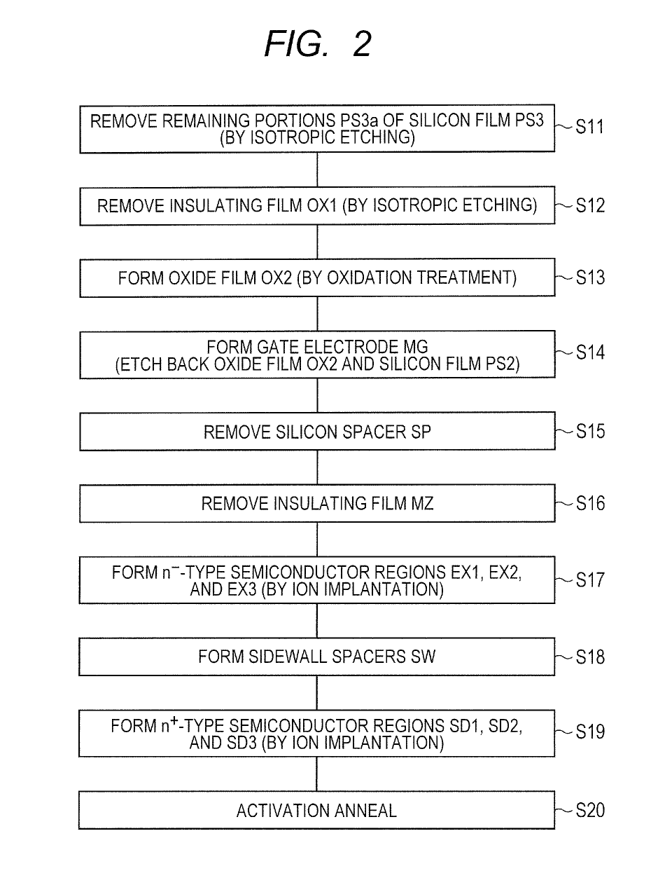

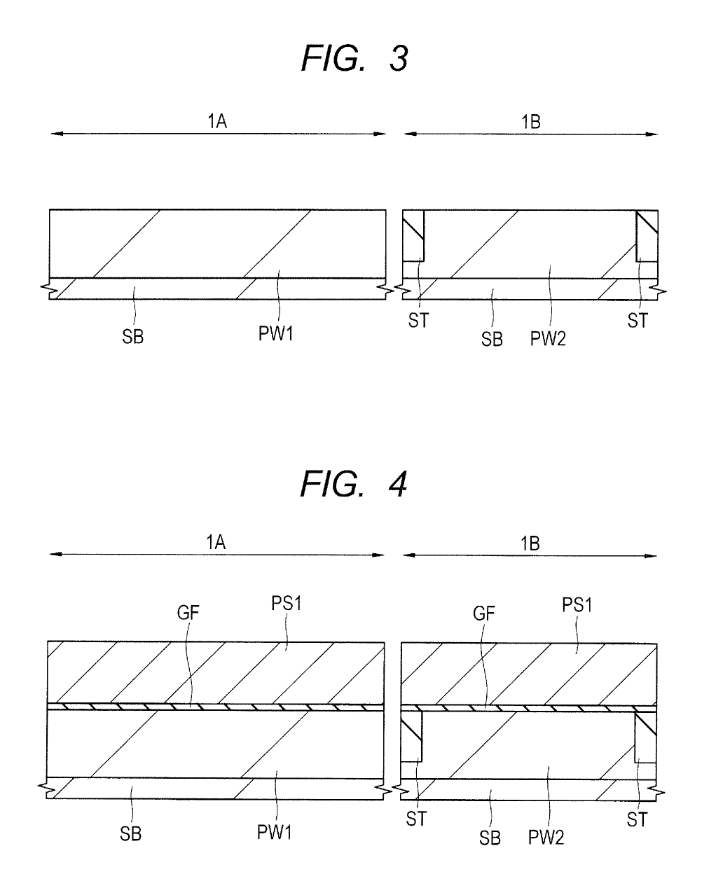

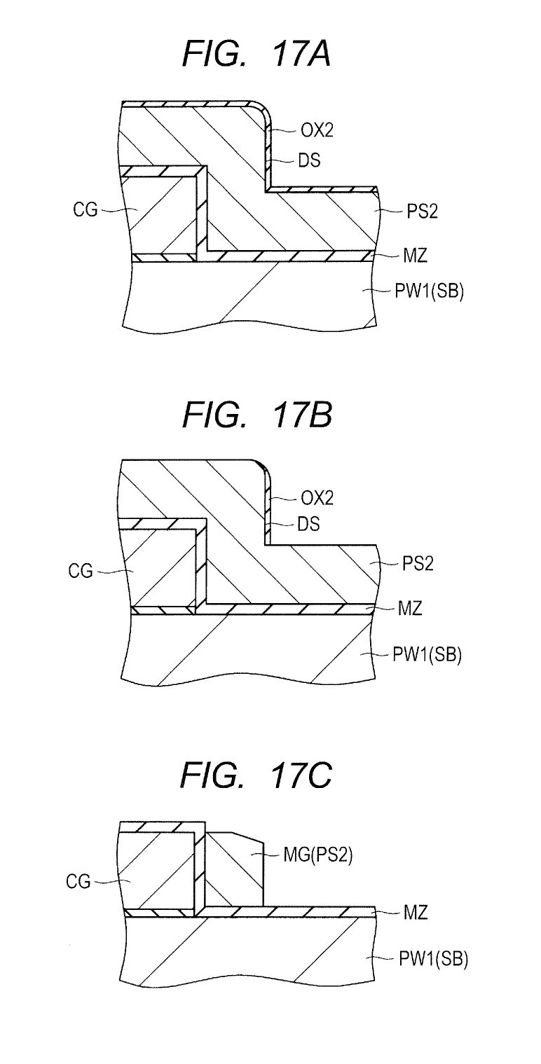

FIGS. 1 and 2 are process flow charts each showing a part of the manufacturing process of the semiconductor device in the present embodiment. FIGS. 3 to 16 and 18 to 24 are main-portion cross-sectional views of the semiconductor device in the present embodiment during the manufacturing process thereof. FIGS. 17A, 17B, and 17C are illustrative views illustrating an etch-back step in Step S14. FIGS. 3 to 16 and 18 to 24 are main-portion cross-sectional views of a memory cell region 1A and a peripheral circuit region 1B, which show the formation of a memory cell in a nonvolatile memory in the memory cell region 1A, while showing the formation of a MISFET in the peripheral circuit region 1B.

The memory cell region 1A is the region of the main surface of the semiconductor substrate SB where memory cells in the nonvolatile memory are to be formed. The peripheral circuit region 1B is the region of the main surface of the semiconductor substrate SB where a peripheral circuit is to be formed. That is, the memory cell region 1A and the peripheral circuit region 1B correspond to the different two-dimensional regions of the main surface of the same semiconductor substrate SB. The memory cell region 1A and the peripheral circuit region 1B need not be adjacent to each other. However, for easier understanding, in the cross-sectional views of FIGS. 3 to 16 and 18 to 24, the peripheral circuit region 1B is shown next to the memory cell region 1A.

A peripheral circuit is a circuit other than the nonvolatile memory. Examples of the peripheral circuit include a processor such as a CPU, a control circuit, a sense amplifier, a column decoder, a row decoder, and an input/output circuit. The MISFET formed in the peripheral circuit 1B is a MISFET for a peripheral circuit.

The present embodiment will describe the case where an re-channel MISFET (a control transistor and a memory transistor) is formed in the memory cell region 1A. However, it is also possible to invert the conductivity type and form a p-channel MISFET (a control transistor and a memory transistor) in the memory cell region 1A. Likewise, the present embodiment will describe the case where an n-channel MISFET is formed in the peripheral circuit region 1B. However, it is also possible to invert the conductivity type and form a p-channel MISFET in the peripheral circuit region 1B. Alternatively, it is also possible to form both of the n-channel MISFET and the p-channel MISFET, i.e., a CMISFET (Complementary MISFET) in the peripheral circuit region 1B.

To manufacture the semiconductor device, first, as shown in FIG. 3, the semiconductor substrate (semiconductor wafer) SB made of, e.g., p-type monocrystalline silicon having a specific resistance of, e.g., about 1 to 10 Ωcm or the like is provided (prepared) (Step S1 in FIG. 1). Then, in the main surface of the semiconductor substrate SB, an isolation region ST defining an active region is formed (Step S2 in FIG. 1).

The isolation region ST is made of an insulator such as silicon dioxide. For example, the isolation region ST can be formed by, e.g., a STI (Shallow Trench Isolation) method, a LOCOS (Local Oxidization of Silicon) method, or the like. The isolation region ST can be formed by, e.g., forming an isolation trench in the main surface of the semiconductor substrate SB and then embedding an insulating film made of, e.g., silicon dioxide in the isolation trench.

Next, in the memory cell region 1A of the semiconductor substrate SB, a p-type well PW1 is formed while, in the peripheral circuit region 1B, a p-type well PW2 is formed (Step S3 in FIG. 1).

The p-type wells PW1 and PW2 can be formed by ion-implanting a p-type impurity such as, e.g., boron (B) into the semiconductor substrate SB. Each of the p-type wells PW1 and PW2 is formed over a predetermined depth from the main surface of the semiconductor substrate SB. Since the p-type wells PW1 and PW2 have the same conductivity type, the p-type wells PW1 and PW2 may be formed either in the same ion implantation step or in different ion implantation steps.

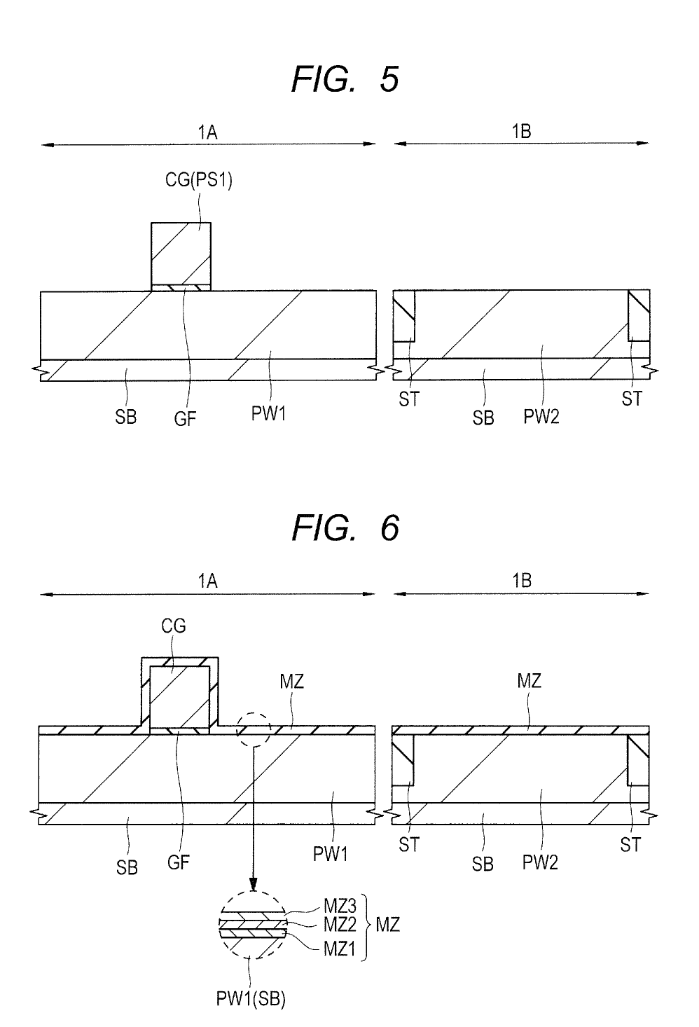

Next, in the memory cell region 1A, a control gate electrode CG is formed over the semiconductor substrate SB (p-type well PW1) via an insulating film (gate insulating film) GF (Step S4 in FIG. 1). Specifically, Step S4 can be performed as follows (FIGS. 4 and 5).

That is, after the top surface of the semiconductor substrate SB (p-type wells PW1 and PW2) is cleaned by diluted hydrofluoric acid cleaning or the like, as shown in FIG. 4, the insulating film GF for the gate insulating film is formed over the main surface of the semiconductor substrate SB (the top surfaces of the p-type wells PW1 and PW2). The insulating film GF is formed over the memory cell region 1A of the top surface of the semiconductor substrate SB (i.e., the upper surface of the p-type well PW1) and over the peripheral circuit region 1B of the top surface of the semiconductor substrate SB (i.e., the upper surface of the p-type well PW2). As the insulating film GF, e.g., a silicon dioxide film can be used and formed using a thermal oxidation method or the like. The formed film thickness of the insulating film GF can be controlled to, e.g., about 2 to 3 nm. Note that, for the sake of convenience, the insulating film GF illustrated in FIG. 4 is formed also over the isolation region ST. However, when the insulating film GF is formed by a thermal oxidation method, the insulating film GF is not actually formed over the isolation region ST.

Then, as shown in FIG. 4, over the entire main surface of the semiconductor substrate SB, i.e., over the insulating film GF over each of the memory cell region 1A and the peripheral circuit region 1B, a silicon film PS1 is formed as a conductive film for forming the control gate electrode CG. The silicon film PS1 is a conductive film for the gate electrode of the control transistor, i.e., a conductive film for forming the control gate electrode CG described later.

The silicon film PS1 is made of a polycrystalline silicon film and can be formed using a CVD (Chemical Vapor Deposition) method or the like. The film thickness (deposited film thickness) of the silicon film PS1 can be controlled to, e.g., about 50 to 300 nm. It is also possible to form an amorphous silicon film as the silicon film PS1 during the film deposition and then change the silicon film PS1 made of the amorphous silicon film to the silicon film PS1 made of the polycrystalline silicon film by the subsequent heat treatment. The same applies also to silicon films PS2 and PS3 described later. The silicon film PS1 can also be changed to a low-resistance semiconductor film (doped polysilicon film) by performing the introduction of an impurity during the film deposition, the ion implantation of an impurity after the film deposition, or the like. The silicon film PS1 over the memory cell region 1A is preferably an n-type silicon film into which an n-type impurity such as phosphorus (P) or arsenic (As) has been introduced.

Then, over the silicon film PS1, a photoresist pattern (not shown) is formed using a photolithographic method. Then, using the photoresist pattern as an etching mask, the silicon film PS1 is etched (preferably dry-etched) to be patterned. Thus, the silicon film PS1 is patterned and, as shown in FIG. 5, the control gate electrode CG made of the patterned silicon film PS1 is formed over the memory cell region 1A. At this time, the silicon film PS1 has been removed from the peripheral circuit region 1.

In this manner, in Step S4, the control gate electrode CG is formed over the semiconductor substrate SB (p-type well PW1) via the insulating film GF. The insulating film GF remaining under the control gate electrode CG over the memory cell region 1A serves as the gate insulating film of the control transistor. The insulating film GF except for the portion thereof covered with the control gate electrode CG (i.e., the insulating film GF except for the portion thereof serving as the gate insulating film) may be removed by dry etching for patterning the silicon film PS1 or by performing wet etching after the dry etching.

Next, cleaning treatment is performed to clean the main surface of the semiconductor substrate SB. Then, as shown in FIG. 6, over the entire main surface of the semiconductor substrate SB, i.e., over the main surface (top surface) of the semiconductor substrate SB and over the surfaces (upper and side surfaces) of the control gate electrode CG, an insulating film MZ for the gate insulating film of the memory transistor is formed (Step S5 in FIG. 1). Accordingly, the insulating film MZ is formed over the semiconductor substrate SB so as to cover the control gate electrode CG.

The insulating film MZ is an insulating film for the gate insulating film of the memory transistor and has an internal charge storage portion (charge storage layer). The insulating film MZ is made of a laminated film including a silicon dioxide film (oxide film) MZ1, a silicon nitride film (nitride film) MZ2 formed over the silicon dioxide film MZ1, and a silicon dioxide film (oxide film) MZ3 formed over the silicon nitride film MZ2. The laminated film including the silicon dioxide film MZ1, the silicon nitride film MZ2, and the silicon dioxide film MZ3 can also be regarded as an ONO (oxide-nitride-oxide) film.

Note that, for improved clarity of illustration, in FIG. 6, the insulating film MZ including the silicon dioxide film MZ1, the silicon nitride film MZ2, and the silicon dioxide film MZ3 is illustrated as the single-layer insulating film MZ. However, in an actual situation, as shown in an enlarged view of the region encircled by the broken-line circle in FIG. 6, the insulating film MZ is made of the laminated film including the silicon dioxide film MZ1, the silicon nitride film MZ2, and the silicon dioxide film MZ3.

Of the insulating film MZ, the silicon dioxide films MZ1 and MZ3 can be formed by, e.g., oxidation treatment (thermal oxidation treatment), a CVD method, or a combination thereof. At this time, as the oxidation treatment, ISSG (In Situ Steam Generation) oxidation can also be used. Of the insulating film MZ, the silicon nitride film MZ2 can be formed by, e.g., a CVD method.

In the present embodiment, as an insulating film (charge storage layer) having a trap level, the silicon nitride film MZ2 is formed. In terms of reliability or the like, the silicon nitride film is appropriate, but the insulating film having a trap level is not limited to the silicon nitride film. A high-dielectric-constant film having a dielectric constant higher than that of the silicon nitride film such as, e.g., an aluminum oxide (alumina) film, a hafnium oxide film, or a tantalum oxide film can also be used as the charge storage layer or charge storage portion. The charge storage layer or charge storage portion can also be formed of silicon nanodots.

To form the insulating film MZ, e.g., the silicon dioxide film MZ1 is formed first by a thermal oxidation method (preferably by ISSG oxidation). Then, over the silicon dioxide film MZ1, the silicon nitride film MZ2 is deposited by a CVD method. Further, over the silicon nitride film MZ2, the silicon dioxide film MZ3 is formed by a CVD method, a thermal oxidation method, or both of the CVD method and the thermal oxidation method. Thus, the insulating film MZ made of the laminated film including the silicon dioxide film MZ1, the silicon nitride film MZ2, and the silicon dioxide film MZ3 can be formed.

The thickness of the silicon dioxide film MZ1 can be controlled to, e.g., about 2 to 10 nm. The thickness of the silicon nitride film MZ2 can be controlled to, e.g., about 5 to 15 nm. The thickness of the silicon dioxide film MZ3 can be controlled to, e.g., about 2 to 10 nm.

The insulating film MZ functions as the gate insulating film of a memory gate electrode MG formed later and has a charge retaining (charge storing) function. Accordingly, the insulating film MZ has a laminated structure including at least three layers so as to be able to function as the gate insulating film of the memory transistor having the charge retaining function. The inner layer (which is the silicon nitride film MZ2 herein) functioning as the charge storage portion has a potential barrier height lower than the potential barrier height of each of the outer layers (which are the silicon dioxide films MZ1 and MZ3) functioning as a charge block layer. This can be achieved by forming the insulating film MZ as the laminated film including the silicon dioxide film MZ1, the silicon nitride film MZ2 over the silicon dioxide film MZ1, and the silicon dioxide film MZ3 over the silicon nitride film MZ2, as in the present embodiment.

In the insulating film MZ, each of the top insulating film (which is the silicon dioxide film MZ3 herein) and the bottom insulating film (which is the silicon dioxide film MZ1 herein) needs to have a band gap which is larger than the band gap of the charge storage layer (which is the silicon nitride film MZ2 herein) between the top and bottom insulating films. By providing each of the silicon dioxide films MZ3 and MZ1 with a band gap larger than that of the silicon nitride film MZ2, each of the silicon dioxide films MZ3 and MZ1 between which the silicon nitride film MZ2 as the charge storage layer is interposed is allowed to function as the charge block layer (or charge confinement layer) for confining charges to the charge storage layer. Since a silicon dioxide film has a band gap larger than the band gap of a silicon nitride film, it is possible to use the silicon nitride film as the charge storage layer and use the silicon dioxide film as each of the top and bottom insulating films.

Next, as shown in FIG. 7, over the main surface (entire main surface) of the semiconductor substrate SB, i.e., over the insulating film MZ, the silicon film (first conductive film) PS2 is formed as a conductive film for forming the memory gate electrode MG so as to cover the control gate electrode CG over the memory cell region 1A (Step S6 in FIG. 1).

The silicon film PS2 is a film (conductive film) for forming the memory gate electrode MG described later. The silicon film PS2 is made of a polycrystalline silicon film and can be formed using a CVD method or the like. The deposited film thickness of the silicon film PS2 can be controlled to, e.g., about 50 to 300 nm.

The silicon film PS2 has been changed to a low-resistance semiconductor film (doped polysilicon film) into which an impurity has been introduced by the introduction of an impurity during the film deposition, the ion implantation of an impurity after the film deposition, or the like. The silicon film PS2 is preferably an n-type silicon film into which an n-type impurity such as phosphorus (P) or arsenic (As) has been introduced.

By thus performing Steps S5 and S6, a conductive film (which is the silicon film PS2) for the memory gate electrode MG of the memory cell is formed over the semiconductor substrate SB via the insulating film MZ so as to cover the control gate electrode CG.

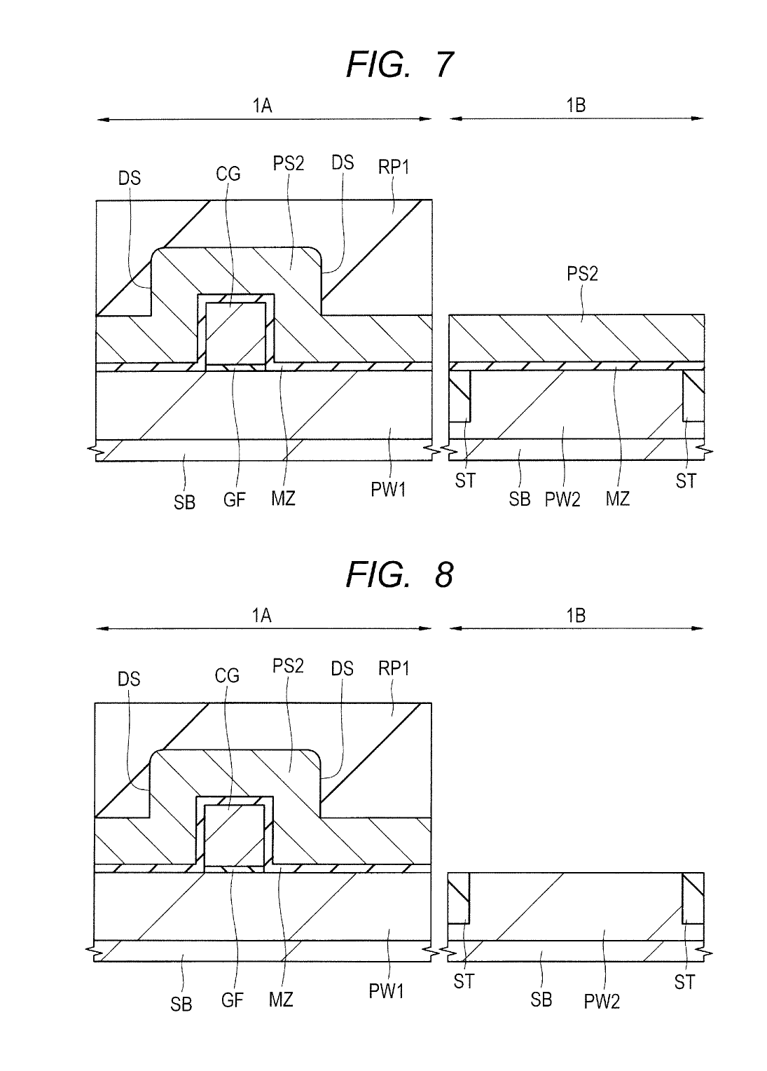

Next, as shown in FIG. 7, a photoresist pattern (mask layer) RP1 is formed as a mask layer over the silicon film PS2 using a photolithographic method to cover the silicon film PS2 over the memory cell region 1A. Then, as shown in FIG. 8, the silicon film PS2 and the insulating film MZ are removed from the peripheral circuit region 1B using an etching method (Step S7 in FIG. 1).

In Step S7, the silicon film PS1 and the insulating film MZ over the peripheral circuit region 1B are successively etched and removed therefrom. However, the silicon film PS2 over the memory cell region 1A is covered with the photoresist pattern RP1 and therefore left without being removed (etched). As a result, when Step S7 is performed, a state is achieved in which the control gate electrode CG, the insulating film MZ, and the silicon film PS2 are left over the memory cell region 1A without being etched, while the silicon film PS1 and the insulating film MZ are etched and removed from the peripheral circuit region 1B. The silicon film PS2 can be removed by dry etching. The insulating film MZ can be removed by dry etching, wet etching, or a combination of dry etching and wet etching. After Step S7, the photoresist pattern RP 1 is removed. After the step of removing the photoresist pattern RP1, wet cleaning treatment is preferably performed. This can more reliably prevent the residues of the photoresist pattern RP1 from being left.

Thus, in Step S7, the silicon film PS2 and the insulating film MZ are removed from the peripheral circuit region 1B, while the silicon film PS2 and the insulating film MZ are left over the memory cell region 1A.

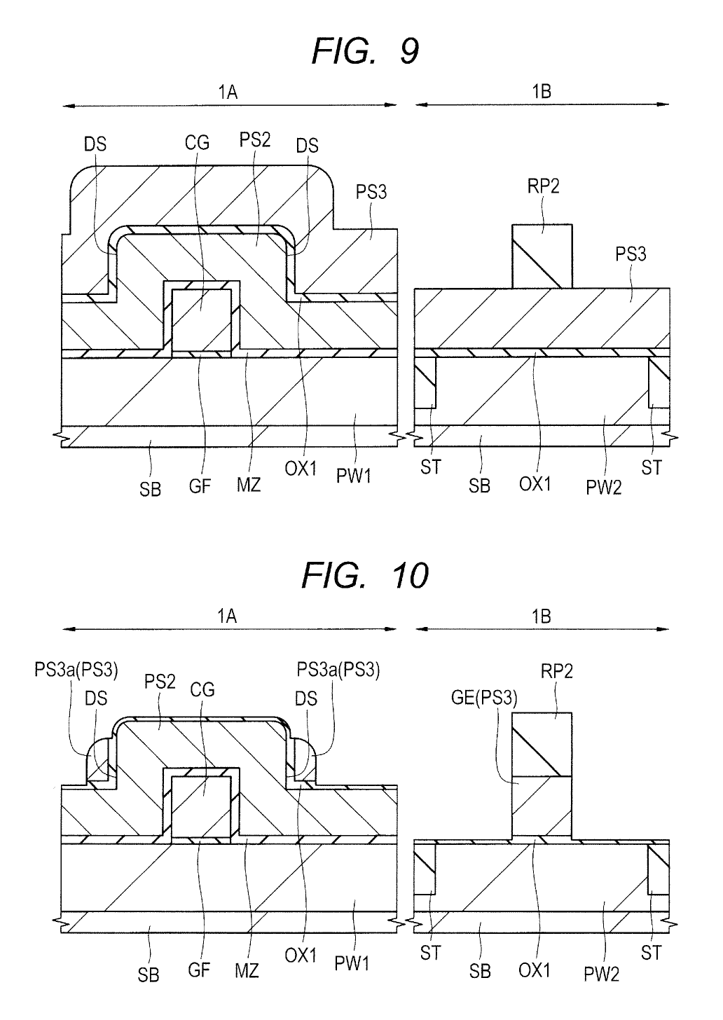

Next, as shown in FIG. 9, an insulating film OX1 is formed over the top surface of the silicon film PS2 and over the main surface of the peripheral circuit region 1B of the semiconductor substrate SB (the top surface of the p-type well PW2) (Step S8 in FIG. 1).

The insulating film OX1 is preferably an oxide film (silicon dioxide film) and can be formed by preferably using a thermal oxidation method. Since the silicon film PS2 is left over the memory cell region 1A, the surfaces (upper and side surfaces) of the silicon film PS2 are oxidized in Step S8 to form the insulating film OX1 made of the oxide film (silicon dioxide film) over the surfaces (upper and side surfaces) of the silicon film PS2. On the other hand, since the silicon film PS2 and the insulating film MZ have been removed from the peripheral circuit region 1B in Step S7, the top surface of the semiconductor substrate SB (top surface of the p-type well PW2) is oxidized in Step S8 to form the insulating film OX1 made of the oxide film (silicon dioxide film) over the top surface of the semiconductor substrate SB (top surface of the p-type well PW2). The formed film thickness of the insulating film OX1 can be controlled to, e.g., about 2 to 10 nm. Note that, for the sake of convenience, the insulating film OX1 illustrated in FIG. 9 is formed also over the portion of the isolation region ST which is uncovered with the silicon film PS2. However, when the insulating film OX1 is formed by a thermal oxidation method, the insulating film OX is not actually formed over the isolation region ST.

Next, as shown in FIG. 9, over the main surface (entire main surface) of the semiconductor substrate SB, i.e., over the insulating film OX1, the silicon film (second conductive film) PS3 is formed as a conductive film for forming a gate electrode GE so as to cover the control gate electrode CG, the insulating film MZ, and the silicon film PS2 over the memory cell region 1A (Step S9 in FIG. 1).

The silicon film PS3 is a film (conductive film) for forming the gate electrode GE described later. The silicon film PS3 is made of a polycrystalline silicon film and can be formed using a CVD method or the like. The deposited film thickness of the silicon film PS3 can be controlled to, e.g., about 50 to 200 nm.

The silicon film PS3 has been changed to a low-resistance semiconductor film (doped polysilicon film) into which an impurity has been introduced by the introduction of an impurity during the film deposition, the ion implantation of an impurity after the film deposition, or the like. In the case of forming an n-channel MISFET in the peripheral circuit region 1B, the silicon film PS3 in the region where the n-channel MISFET is formed is preferably an n-type silicon film into which an n-type impurity such as phosphorus (P) or arsenic (As) has been introduced.

By thus performing Steps S8 and S9, a conductive film for the gate electrode GE of the MISFET (which is the silicon film PS3 herein) is formed over the silicon film PS2 over the memory cell region 1A and over the peripheral circuit region 1B of the semiconductor substrate SB via the insulating film OX1.

Next, as shown in FIG. 9, a photoresist pattern (mask layer) RP2 is formed as a mask layer over the silicon film PS3 over the peripheral circuit region 1B using a photolithographic method. The photoresist pattern RP2 is formed over the area of the peripheral circuit region 1B where the gate electrode GE is to be formed. Even when the photoresist pattern RP2 has been formed, the silicon film PS2 over the memory cell region 1A is uncovered with the photoresist pattern RP2 and exposed.

Next, as shown in FIG. 10, using the photoresist pattern RP2 as an etching mask, the silicon film PS3 is etched (dry-etched or anisotropically etched) using an anisotropic etching technique to form the gate electrode GE (Step S10 in FIG. 1). The gate electrode GE is made of the silicon film PS3 remaining under the photoresist pattern RP2, i.e., the patterned silicon film PS3.

In Step S10, the silicon film PS3 is locally left under the photoresist pattern RP2 to form the gate electrode GE, while being etched and removed from the other region. Accordingly, in Step S10, it is necessary to anisotropically etch the silicon film PS3 so that anisotropic dry etching is performed.

The silicon film PS3 over the memory cell region 1A is uncovered with the photoresist pattern RP2 and exposed so that the etching in Step S10 is performed in a state where the silicon film PS3 is exposed over the memory cell region 1A. As a result, when the etching step in Step S10 is performed, the silicon film PS3 is etched and removed from the memory cell region 1A. On the other hand, the etching step in Step S10 is performed in a state where the silicon film PS3 is covered with the photoresist pattern RP2 over the area of the peripheral circuit region 1B where the gate electrode GE is to be formed, while the silicon film PS3 is exposed over the other region. Accordingly, when the etching step in Step S10 is performed, the silicon film PS3 over the peripheral circuit region 1B is not etched but is left under the photoresist pattern RP2, while the silicon film PS3 over the other region is etched and removed.

During the etching of the silicon film PS3 in Step S10, the insulating film OX1 is allowed to function as an etching stopper film. That is, in the etching step in Step S10, it is preferable to selectively remove the silicon film PS3 to cause the insulating film OX1 to function as an etching stopper and end the etching before the silicon film PS2 over the memory cell region 1A and the semiconductor substrate SB (p-type well PW2) over the peripheral circuit region 1B are exposed. In other words, at the stage where the etching step in Step S10 is ended, the insulating film OX1 is left in the form of a layer to prevent the silicon film PS2 from being exposed. This can prevent the silicon film PS2 over the memory cell region 1A and the peripheral circuit region 1B of the semiconductor substrate SB (p-type well PW2) from being etched in the etching step in Step S10.

Accordingly, in the etching in Step S10, the silicon film PS3 is preferably etched under etching conditions such that the insulating film OX1 is less likely to be etched than the silicon film PS3. That is, in the etching in Step S10, the silicon film PS3 is preferably etched under etching conditions such that the speed of etching the insulating film OX1 is lower than the speed of etching the silicon film PS3. This allows the insulating film OX1 to function as an etching stopper film in the etching step in Step S10.

Note that the wording “B is less likely to be etched than A” means that “the speed of etching B is lower (slower) than the speed of etching A”.

After anisotropic dry etching is performed in Step S10, the photoresist pattern RP2 is removed. For the step of removing the photoresist RP2, e.g., ashing (ashing treatment using an oxygen plasma) or the like can be used. After the step of removing the photoresist pattern RP2, wet cleaning treatment is preferably performed. This can more reliably prevent the residues of the photoresist pattern RP2 from being left. In the wet cleaning treatment performed after the step of removing the photoresist pattern RP2, as a cleaning solution (treatment solution), e.g., sulfuric acid hydrogen peroxide (SPM: Sulfuric acid-Hydrogen Peroxide Mixture which is a solution mixture of sulfuric acid and hydrogen peroxide), ammonia hydrogen peroxide (APM: Ammonia-Hydrogen Peroxide Mixture which is a solution mixture of ammonia and hydrogen peroxide), or the like can be used. For example, after SPM cleaning is performed, APM cleaning can be performed.

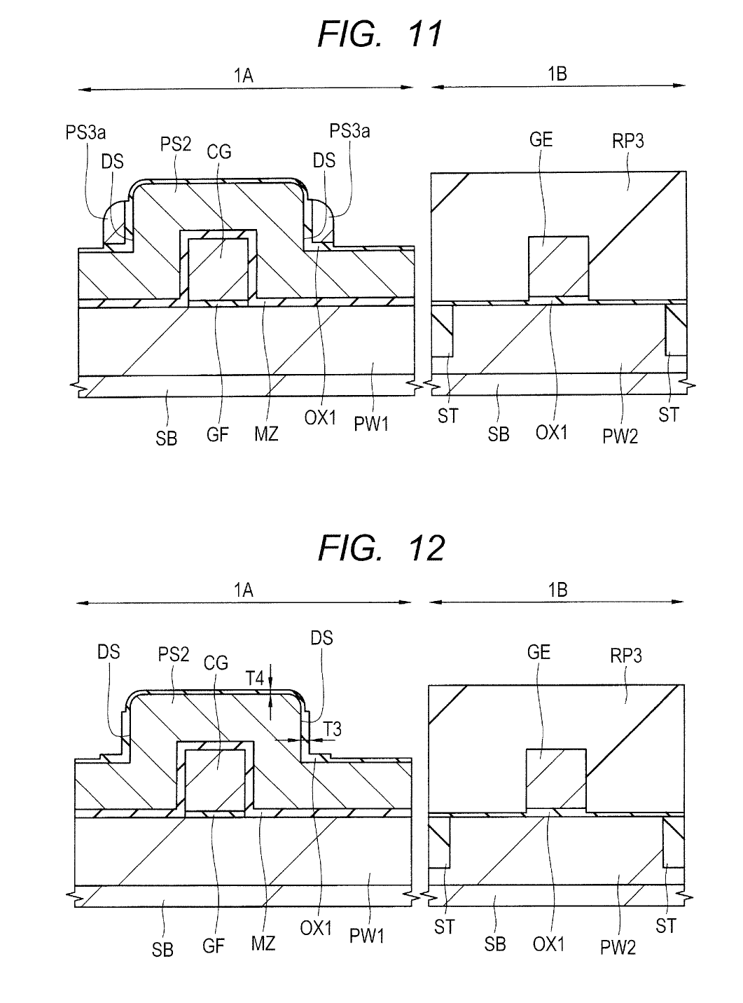

Next, as shown in FIG. 11, over the semiconductor substrate SB, a photoresist pattern (mask layer) RP3 is formed as a mask layer using a photolithographic method to expose the memory cell region 1A and cover the entire peripheral circuit region 1B. Of the gate electrode GE, not only the upper surface but also the side surfaces are covered with the photoresist pattern RP3. When the photoresist pattern RP3 is formed, the gate electrode GE and the insulating film OX1 under the gate electrode GE are covered with the photoresist pattern RP3 to come into an uncovered state. On the other hand, the photoresist pattern RP3 is not formed over the memory cell region 1A. Accordingly, over the memory cell region 1A, a state where the insulating film OX1 is exposed is maintained before and after the formation of the photoresist pattern RP3.

Next, using the photoresist pattern RP3 as an etching mask, isotropic etching is performed (Step S11 in FIG. 2). FIG. 12 shows the stage where the etching step in Step S11 has been performed. The etching step in Step S11 is treatment performed to remove remaining portions PS3a of the silicon film PS3 from the memory cell region 1A by etching. The gate electrode GE, which is covered with the photoresist pattern RP3, is not etched in the etching step in Step S11.

That is, since anisotropic etching is performed in the etching step in Step S10, at positions adjacent to stepped portions DS of the silicon film PS2 via the insulating film OX1 over the memory cell region 1A, parts of the silicon film PS3 are left as the remaining portions PS3a. The stepped portions DS are steps resulting from the control gate electrode CG. Unlike in the present embodiment, if the etching step in Step S10 is isotropic etching, the remaining portions PS3a are not left, but the gate electrode GE cannot properly be formed. Accordingly, in the etching step in Step S10, anisotropic etching needs to be performed. However, this leaves the remaining portions PS3a of the silicon film PS3 at the positions adjacent to the stepped portions DS of the silicon film PS3 via the insulating film OX1. If the stepped portions DS of the silicon film PS2 are not present, the remaining portions PS3a are not formed. However, since the silicon film PS2 has been formed so as to cover the control gate electrode CG over the memory cell region 1A, the stepped portions DS reflecting the control gate electrode CG are undesirably formed in the top surface of the silicon film PS2. Consequently, over the memory cell region 1A, the stepped portions DS reflecting the control gate electrode CG are formed in the top surface of the silicon film PS2. It follows that, since anisotropic etching is performed in Step S10, at the positions adjacent to the stepped portions DS of the silicon film PS2 via the insulating film OX1, the remaining portions PS3a of the silicon film PS3 are left.

Accordingly, in the present embodiment, the remaining portions PS3a of the silicon film PS3 are removed by the etching step in Step S11. Therefore, in the etching step in Step S11, isotropic etching is performed. By performing isotropic etching, the remaining portions PS3a of the silicon film PS3 remaining at the positions adjacent to the stepped portions DS of the silicon film PS2 via the insulating film OX1 can reliably be removed.

When the remaining portions PS3a of the silicon film PS3 are etched in Step S11, the insulating film OX1 is allowed to function as an etching stopper film. That is, in the etching step in Step S11, it is preferable to selectively remove the remaining portions PS3a of the silicon film PS3 to allow the insulating film OX1 to function as the etching stopper and end the etching before the silicon film PS2 over the memory cell region 1A is exposed. In other words, at the stage where the etching step in Step S10 is ended, the insulating film OX1 is left in the form of a layer to prevent the silicon film PS2 from being exposed. This can prevent the silicon film PS2 over the memory cell region 1A from being etched in the etching step in Step S11.

Accordingly, in the etching in Step S11, the silicon film PS3 (remaining portions PS3a) is preferably etched under etching conditions such that the insulating film OX1 is less likely to be etched than the silicon film PS3 (remaining portions PS3a). That is, the silicon film PS3 (remaining portions PS3a) is preferably etched under etching conditions such that the speed of etching the insulating film OX1 is lower than the speed of etching the silicon film PS3 (remaining portions PS3a). This allows the insulating film OX1 to function as an etching stopper film in the etching step in Step S11.

The etching in Step S11 is isotropic etching. Since the etching in Step S11 is for selectively removing the silicon film PS3 (remaining portion PS3a), isotropic dry etching is preferable.

When the etching step in Step S11 is performed in a state where the photoresist pattern RP2 is left over the gate electrode GE without forming the photoresist pattern RP3 unlike in the present embodiment, the side surfaces of the gate electrode GE are exposed. As a result, the side surfaces of the gate electrode GE are side-etched to deform the shape of the gate electrode GE. By contrast, in the present embodiment, the etching step in Step S11 is performed after the photoresist pattern RP2 is removed and the gate electrode GE is covered with the photoresist pattern RP3. Accordingly, the etching step in Step S11 is performed in a state where neither the upper surface nor side surfaces of the gate electrode GE are exposed. This keeps the gate electrode GE from being etched (side-etched) in Step S11 and can prevent the shape of the gate electrode GE from being deformed.

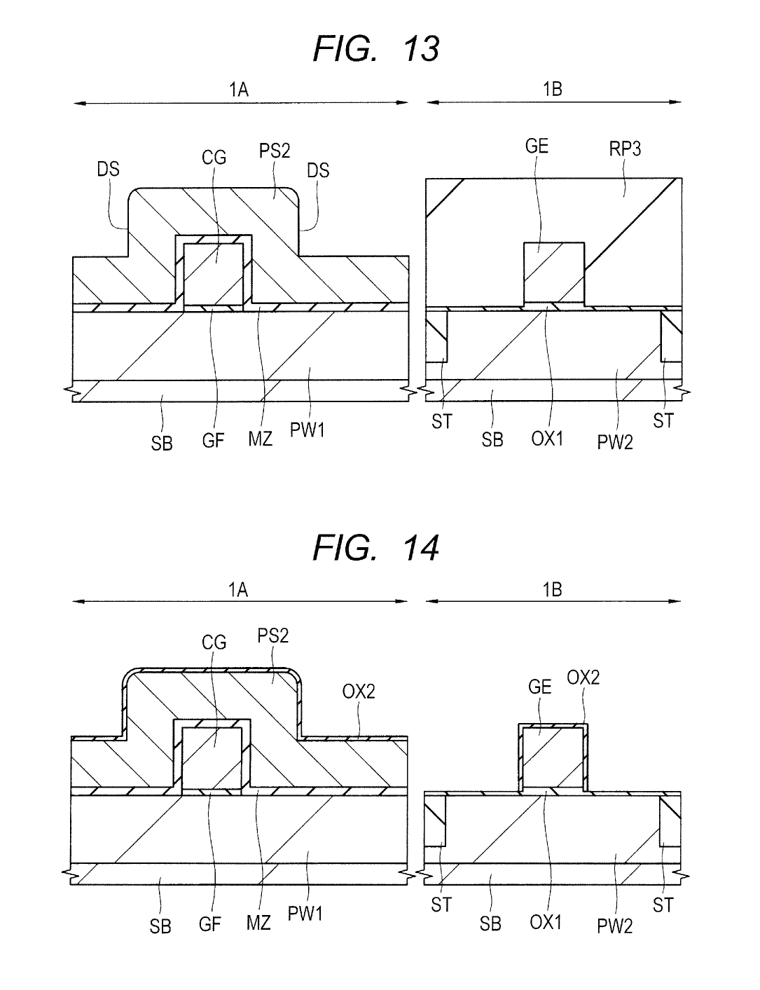

Next, as shown in FIG. 13, using the photoresist pattern RP3 as an etching mask, the insulating film OX1 is etched and removed from the memory cell region 1A (Step S12).

In the etching in Step S12, the insulating film OX1 is preferably etched under etching conditions such that the silicon film PS2 is less likely to be etched than the insulating film OX1. That is, in the etching in Step S12, the insulating film OX1 is preferably etched under etching conditions such that the speed of etching the silicon film PS2 is lower than the speed of etching the insulating film OX1. This can selectively remove the insulating film OX1 in the etching step in Step S12 and inhibit or prevent the silicon film PS2 from being etched.

As the etching in Step S12, isotropic etching is used. Unlike in the present embodiment, when anisotropic etching is used as the etching in Step S12, the etching residues of the insulating film OX1 may be left over the stepped portions DS of the silicon film PS1. By contrast, in the present embodiment, isotropic etching is used as the etching in Step S12. This can prevent the etching residues of the insulating film OX1 from being left over the stepped portions DS of the silicon film PS2. Since the etching step in Step S12 is for selectively removing the insulating film OX1, wet etching is preferable.

By performing the etching step in Step S12, over the memory cell region 1A, a state is achieved where the top surface of the silicon film PS2 is exposed.

In the etching step in Step S12, the entire peripheral circuit region 1B is covered with the photoresist pattern RP3. This can prevent the insulating film OX1 (the portion of the insulating film OX1 which serves as the gate insulating film) under the gate electrode GE from being etched.

That is, since the etching step in Step S11 and the etching step in Step S12 are performed after the entire peripheral circuit region 1B is covered with the photoresist pattern RP3, it is possible to prevent the gate electrode GE over the peripheral circuit region 1B, the insulating film OX1 under the gate electrode GE, and the peripheral circuit region 1B of the semiconductor substrate SB from being etched in the etching step in Step S11 or the etching step in Step S12. That is, since the etching step in Step S11 and the etching step in Step S12 are performed in a state where the photoresist pattern RP3 is formed, it is possible to remove the remaining portions PS3a of the silicon film PS3 and the insulating film OX1 from the memory region 1A without adversely affecting the peripheral circuit region 1B in Steps S11 and S12.

After the etching step in Step S12 is performed, the photoresist pattern RP3 is removed. For the step of removing the photoresist pattern RP3, e.g., ashing (ashing treatment using an oxygen plasma) or the like can be used. After the step of removing the photoresist pattern RP3, wet cleaning treatment is preferably performed. This can more reliably prevent the residues of the photoresist pattern RP3 from being left. In the wet cleaning treatment performed after the step of removing the photoresist pattern RP1, as a cleaning solution (treatment solution), e.g., sulfuric acid hydrogen peroxide (SPM), ammonia hydrogen peroxide (APM), or the like can be used. For example, after SPM cleaning is performed, APM cleaning can be performed.

Next, over the silicon film PS2, an insulating film (which is an oxide film OX2 herein) is formed (Step S13 in FIG. 2). Specifically, in Step S13, as shown in FIG. 14, the top surface of the silicon film PS2 is oxidized to form the oxide film (silicon dioxide film) OX2 as an insulating film over the top surface of the silicon film PS2.

For the oxidation treatment in Step S13, plasma oxidation using an oxygen plasma is preferably performed. Since the silicon film PS2 is formed over the memory cell region 1A, over the memory cell region 1A, the surfaces (upper and side surfaces) of the silicon film PS2 are oxidized in Step S13 to form the oxide film OX2 over the surfaces (upper and side surfaces) of the silicon film PS2. Over the peripheral circuit region 1B, the silicon film PS2 is not formed, but the gate electrode GE is formed. Consequently, by the oxidation treatment in Step S13, the surfaces (upper and side surfaces) of the gate electrode GE may also be oxidized to form the oxide film (silicon dioxide film) OX2 over the surfaces (upper and side surfaces) of the gate electrode GE. As a result, in Step S13, the oxide film (silicon dioxide film) OX2 is formed over each of the top surface of the silicon film PS2 and the surfaces of the gate electrode GE. The thickness (formed film thickness) of the oxide film OX2 can be controlled to, e.g., about 1 to 5 nm.

The following is an example of conditions for the plasma oxidation performed in Step S13. In a plasma treatment apparatus, oxidation plasma treatment is performed for about 15 to 120 seconds under conditions such that the pressure in a treatment chamber is about 100 to 500 Pa, the temperature (corresponding to the temperature of the semiconductor substrate SB) of a stage over which the semiconductor substrate SB is placed is about 200 to 300° C., a microwave power is about 1 to 5 kW, and the flow rate of an oxygen gas is about 1 to 5 slm. This allows the oxide film OX2 having a thickness of about 1 to 5 nm to be formed.

In the present embodiment, the step of removing the photoresist pattern RP3 and the oxidation treatment in Step S13 are performed in different steps. In another form, it is also possible to perform the step of removing the photoresist pattern RP3 and the oxidation treatment in Step S13 in the same step. In that case, the number of the steps in the manufacturing process of the semiconductor device can be reduced. In this case, after the etching step in Step S12 is performed, the removal of the photoresist pattern RP3 (removal by asking) and the formation of the oxide film OX2 (plasma oxidation) are simultaneously performed by the oxidation plasma treatment. Note that, in this case, when wet cleaning treatment for removing the residues of the photoresist pattern RP3 is performed after the oxygen plasma treatment, the oxide film OX2 may be etched by the wet cleaning treatment. However, when the wet cleaning treatment is not performed, the residues of the photoresist pattern RP3 may be left.

Therefore, it is more preferable to perform the oxidation treatment in Step S13 in a step different from the step of removing the photoresist pattern RP3. By doing so, even when the wet cleaning treatment is performed after the step of removing the photoresist pattern RP3, the oxide film OX2 is formed in Step S13 after the wet cleaning treatment. As a result, it is possible to avoid the possibility that the oxide film OX2 is etched by the wet cleaning treatment.

In the present embodiment, in Step S13, the oxide film OX2 is formed by the oxidation treatment but, in another form, the oxide film OX2 can also be formed by a method which deposits an insulating film by a CVD method or the like. However, more preferably, the oxide film OX2 is formed by the oxidation treatment. As the oxidation treatment for forming the oxidation film OX2, plasma oxidation is most preferable. This allows easy control of the formed film thickness of the thin oxide film OX2 to an intended film thickness. As a result, the oxide film OX2 having a film thickness appropriate to allow the oxide film OX2 to function as an etching inhibiting film in an etch-back step in Step S14 described later can more reliably be formed in Step S13.

An oxide film formed by plasma oxidation has a quality inferior to that of an oxide film formed by thermal oxidation. However, since the oxide film OX2 is removed in Step S14 described later, even when the oxide film OX2 is formed by plasma oxidation, there is no problem. On the other hand, since the foregoing insulating film OX1 is used as the gate insulating film of the MISFET, the quality of the insulating film OX1 is also important. When an oxide film is used as the insulating film OX1, the oxide film is formed more preferably by thermal oxidation than by plasma oxidation.

In the present embodiment, the oxide film OX2 is formed in Step S13. However, in another form, an insulating film (such as, e.g., a silicon nitride film) other than an oxide film (silicon dioxide film) can also be formed instead of the oxide film OX2. In that case, it follows that the insulating film formed instead of the oxide film OX2 in Step S13 functions as an etching inhibiting film in the etch-back step in Step S14 described later. Note that, to allow the etching selectivity to the silicon film PS2 to be more easily ensured in the etch-back step in Step S14 described later and form the etching inhibiting film having a small film thickness with excellent controllability, it is more preferable to use the oxide film (silicon dioxide film) OX2.

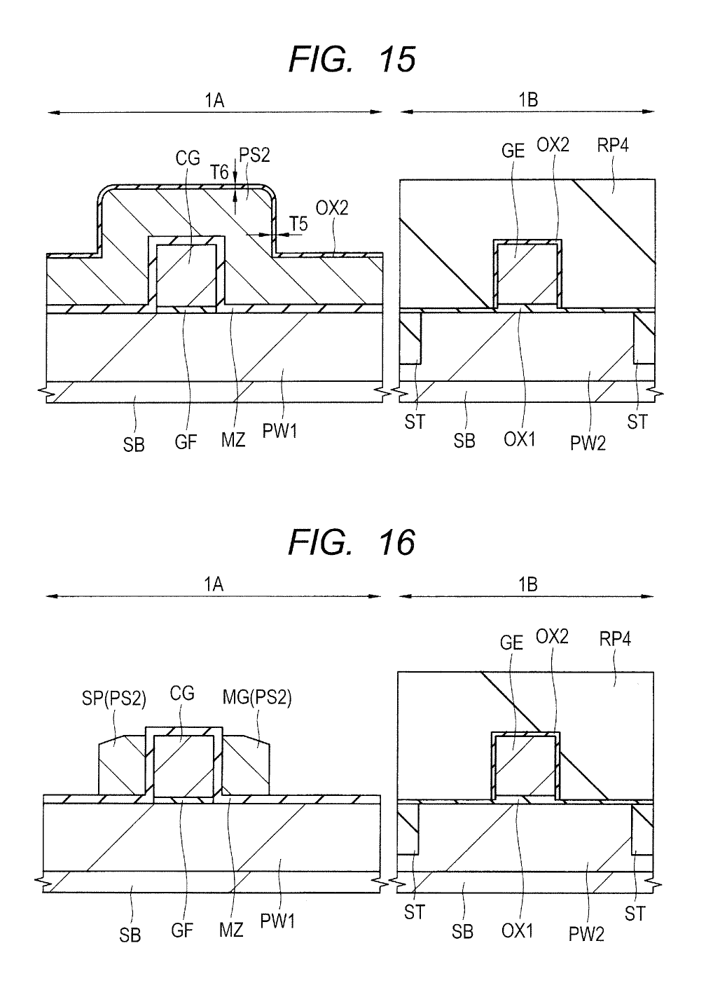

Next, as shown in FIG. 15, over the semiconductor substrate SB, a photoresist pattern (mask layer) RP4 is formed as a mask layer using a photolithographic method so as to expose the memory cell region 1A and cover the entire peripheral circuit region 1B. Of the gate electrode GE, not only the upper surface but also the side surfaces are covered with the photoresist pattern RP4. When the photoresist pattern RP4 is formed, the gate electrode GE and the insulating film OX1 under the gate electrode GE are covered with the photoresist pattern RP4 and brought into an unexposed state. On the other hand, over the memory cell region 1A, the photoresist pattern RP4 is not formed. Accordingly, over the memory cell region 1A, a state where the oxide film OX2 is exposed is maintained before and after the formation of the photoresist pattern RP4.

Next, using an anisotropic etching technique, the oxide film OX2 and the silicon film PS2 are etched back (etched, dry-etched, or anisotropically etched) (Step S14 in FIG. 2).

In the etch-back step in Step S14, the oxide film OX2 and the silicon film PS2 are anisotropically etched (etched back) in succession. Thus, the oxide film OX2 is removed, while the silicon film PS2 is left in sidewall spacer shapes over the both side walls of the control gate electrode CG via the insulating films MZ and removed from the other region. As a result, as shown in FIG. 16, the memory gate electrode MG is formed of the silicon film PS2 left in the sidewall spacer shape over one of the both side walls of the control gate electrode CG via the insulating film MZ over the memory cell region 1A. Also, over the memory cell region 1A, a silicon spacer SP is formed of the silicon film PS2 left in the sidewall spacer shape over the other of the both side walls of the control gate electrode CG via the insulating film MZ. The memory gate electrode MG is formed over the insulating film MZ so as to be adjacent to the control gate electrode CG via the insulating film MA.

The memory gate electrode MG is a gate electrode for a memory cell. More specifically, the memory gate electrode MG is a gate electrode for the memory transistor of the memory cell.

The silicon spacer SP can also be regarded as a sidewall spacer made of silicon. The memory gate electrode MG and the silicon spacer SP are formed over the side walls of the control gate electrode CG which are opposite to each other and have substantially symmetrical structures with the control gate electrode CG being interposed therebetween.

By performing the etch-back step in Step S14, over the memory cell region 1A, the regions of the insulating film MA which are uncovered with the silicon spacer SP and the memory gate electrode MG are exposed. Between the memory gate electrode MG formed in Step S14 and the semiconductor substrate SB (p-type well PW1) and between the memory gate electrode MG and the control gate electrode CG, the insulating film MZ is interposed. The insulating film MZ under the memory gate electrode MG over the memory cell region 1A serves as the gate insulating film of the memory transistor. By adjusting the deposited film thickness of the silicon film PS2 deposited in Step S6 described above, the gate length of the memory gate electrode MG can be adjusted.

In the etching step in Step S14, the entire peripheral circuit region 1B is covered with the photoresist pattern RP4. This can prevent the gate electrode GE and the insulating film OX1 (the portion of the insulating film OX1 which serves as the gate insulating film) under the gate electrode GE from being etched.

That is, since the etch-back step in Step S14 is performed after the entire peripheral circuit region 1B is covered with the photoresist pattern RP4, it is possible to prevent the gate electrode GE over the peripheral circuit region 1B, the insulating film OX1 under the gate electrode GE, and the peripheral circuit region 1B of the semiconductor substrate SB from being etched in the etch-back step in Step S14. That is, since the etch-back step in Step S14 is performed in a state where the photoresist pattern RP4 is formed, it is possible to remove the oxide film OX2 and the silicon film PS2 except for the portions thereof serving as the memory gate electrode MG and the silicon spacer SP from the memory cell region 1A without adversely affecting the peripheral circuit region 1B in Step S14.

FIGS. 17A and 17B are illustrative views each illustrating the etch-back step in Step S14 and shows a part of the memory cell region 1A in enlarged relation. Note that FIG. 17A shows a stage (i.e., a stage corresponding to FIG. 15) immediately before the etch-back step in Step S14 is performed, FIG. 17B shows a stage during the etch-back step in Step S14, and FIG. 17C shows a stage (i.e., a stage corresponding to FIG. 16) after the etch-back step in Step S14 is performed.

In the present embodiment, the etch-back step in Step S14 is performed in a state where the oxide film OX2 is formed over the top surface of the silicon film PS2. In the case where the oxide film OX2 has not been formed at the stage where the etch-back step in Step S14 is performed unlike in the present embodiment, when the memory gate electrode MG and the silicon spacer SP are formed by etching back the silicon film PS2 in Step S14, the memory gate electrode MG is less likely to have a cross-sectional shape appropriate for the memory gate electrode. That is, the memory gate electrode MG is more likely to have a cross-sectional shape like the cross-sectional shape of a memory gate electrode MG102 shown in FIG. 31 described later.

By contrast, in the present embodiment, the etch-back step in Step S14 is performed in a state where the oxide film OX2 is formed over the top surface of the silicon film PS2. Accordingly, in the etch-back step in Step S14, the oxide film OX2 can function as an etching inhibiting film. This allows the memory gate electrode MG to have a shape (shape closer to a rectangle) appropriate for the memory gate electrode.

Specifically, as shown in FIG. 17A, the etch-back process is started in a state where the oxide film OX2 is formed over the top surface of the silicon film PS2. Since the etch-back process is anisotropic etching, the portion of the oxide film OX2 which is formed over the horizontal surface (surface generally parallel with the main surface of the semiconductor substrate SB) among the surfaces of the silicon film PS2 is removed first, as shown in FIG. 17B. Over the side surfaces of the stepped portions DS of the silicon film PS2, the oxide film OX2 remains for a while. Consequently, the horizontal surface among the surfaces of the silicon film PS2 is exposed first to be etched while, at the side surface of the stepped portion DS of the silicon film PS2, the silicon film PS2 is inhibited or prevented from being etched as long as the oxide film OX2 remains. When the silicon film PS2 is etched back over the thickness of the silicon film PS2, the memory gate electrode MG and the silicon spacer SP are formed as shown in FIG. 17C. It is possible to inhibit or prevent the heights of the shoulder portions of the formed memory gate electrode MG and the formed silicon spacer SP from being reduced as a result of the fact that the oxide film OX2 remaining over the side surfaces of the stepped portions DS of the silicon film PS2 has inhibited the side surfaces of the stepped portions DS of the silicon film PS2 from being etched. Each of the memory gate electrode MG and the silicon spacer SP has a cross-sectional shape close to a rectangle.

Thus, in the present embodiment, the memory gate electrode MG is formed by etching back the oxide film OX2 and the silicon film PS2 in a state where the oxide film OX2 is formed as the etching inhibiting film over the top surface of the silicon film PS2. This can inhibit or prevent the height of the shoulder portion of the formed memory gate electrode MG from being reduced and bring the cross-sectional shape (cross-sectional shape generally perpendicular to the gate width direction) of the memory gate electrode MG closer to a rectangle. That is, the memory gate electrode MG can be formed such that the side surface (side surface opposite to the side surface adjacent to the control gate electrode CG via the insulating film MZ) thereof is generally perpendicular to the main surface of the semiconductor substrate SB. In addition, in the cross-sectional shape (cross-sectional shape generally perpendicular to the gate width direction), it is possible to hold the width (dimension in the gate length direction) of the memory gate electrode MG substantially constant in the height direction.

Note that, when the cross-sectional shape of the gate electrode is mentioned in the present application, the cross-sectional shape of the gate electrode indicates the cross-sectional shape of the gate electrode in a cross section generally perpendicular to the gate width direction of the gate electrode. In other words, when the cross-sectional shape of the gate electrode is mentioned, the cross-sectional shape of the gate electrode indicates the cross-sectional shape of the gate electrode in a cross section parallel with the gate length direction of the gate electrode and generally perpendicular to the main surface of the semiconductor substrate SB.

In the etch-back (anisotropic etching) process in Step S14, the oxide film OX2 and the silicon film PS2 are preferably etched back under etching conditions such that the oxide film OX2 is less likely to be etched than the silicon film PS2. That is, in Step S14, the oxide film OX2 and the silicon film PS2 are preferably etched back under etching conditions such that the speed of etching the oxide film OX2 is lower than the speed of etching the silicon film PS2. In other words, in the etch-back process in Step S14, the oxide film OX2 and the silicon film PS2 are preferably etched back under etching conditions such that the silicon film PS2 is more likely to be etched than the oxide film OX2. This allows the oxide film OX2 over the stepped portions DS of the silicon film PS2 to properly function as an etching inhibiting film in the etch-back step in Step S14. As a result, the memory gate electrode MG is more likely to have a cross-sectional shape (shape close to a rectangle) appropriate for the memory gate electrode.

After the etch-back step in Step S14 is performed, the photoresist pattern RP4 is removed. For the step of removing the photoresist pattern RP4, e.g., ashing (ashing treatment using an oxygen plasma) or the like can be used. After the step of removing the photoresist pattern RP4, wet cleaning treatment is preferably performed. This can more reliably prevent the residues of the photoresist pattern RP4 from being left. In the wet cleaning treatment performed after the step of removing the photoresist pattern RP4, as a cleaning solution (treatment solution), e.g., sulfuric acid hydrogen peroxide (SPM), ammonia hydrogen peroxide (APM), or the like can be used. For example, after SPM cleaning is performed, APM cleaning can be performed.

After the etch-back step in Step S14, wet etching can also be performed. As a result, even when a part of the oxide film OX2 remains over the side wall of the memory gate electrode MG at the stage where the etch-back step in Step S14 is ended, the remaining portion of the oxide film OX2 can be removed by wet etching after the etch-back step in Step S14. Accordingly, when wet etching is performed after the etch-back step in Step S14, it is preferable to use etching conditions such that the memory gate electrode MG is less likely to be etched than the oxide film OX2. That is, it is preferable to use etching conditions such that the speed of etching the memory gate electrode MG is lower than the speed of etching the oxide film OX2. This allows the remaining portions of the oxide film OX2 to be reliably removed by wet etching performed after the etch-back step in Step S14, while inhibiting the memory gate electrode MG from being etched.

The wet etching performed after the etch-back step in Step S14 can also be performed after the removal of the photoresist pattern RP4. In that case, it is possible to allow the wet etching to remove the remaining portion of the oxide film OX2 from the memory cell region 1A and also remove the oxide film OX2 over the top surface of the gate electrode GE from the peripheral circuit region 1B.

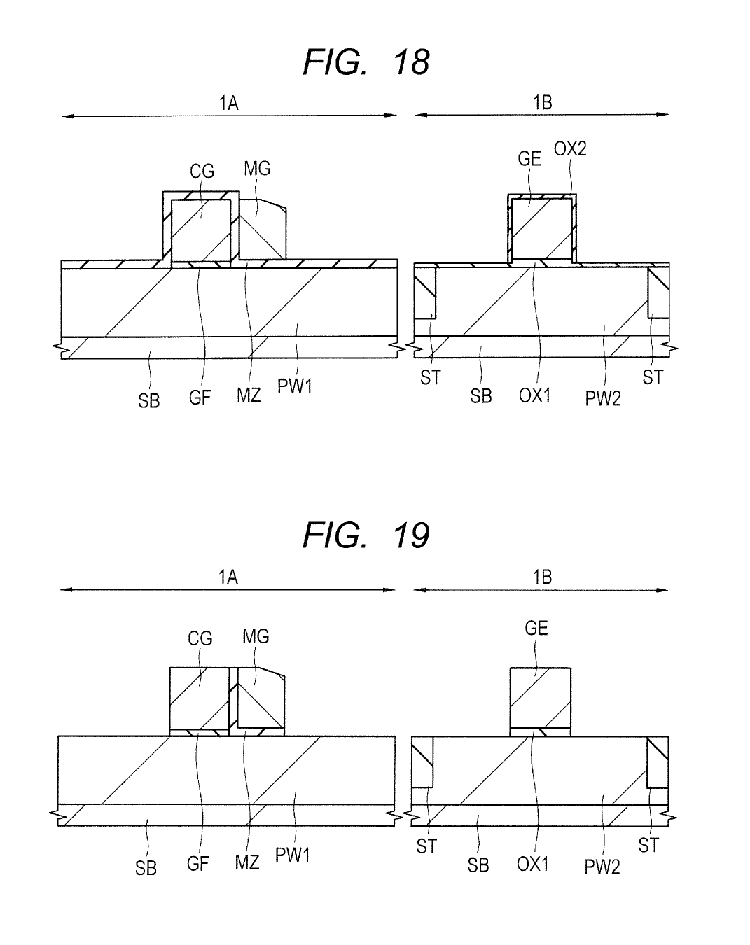

Next, using a photolithographic technique, a photoresist pattern (not shown) is formed over the semiconductor substrate SB so as to cover the entire peripheral circuit region 1B (including the gate electrode GE), while covering the memory gate electrode MG and exposing the silicon spacer SP over the memory cell region 1A. Then, by dry etching using the photoresist pattern as an etching mask, the silicon spacer SP is removed (Step S15 in FIG. 2). Subsequently, the photoresist pattern is removed. By the etching step in Step S15, the silicon spacer SP is removed, as shown in FIG. 18. However, since the memory gate electrode MG and the gate electrode GE have been covered with the photoresist pattern, the memory gate electrode MG and the gate electrode GE are not etched but remain.

Next, of the insulating film MZ, the portion uncovered with the memory gate electrode MG and exposed is removed by etching (e.g., wet etching) (Step S16 in FIG. 2). FIG. 19 shows this stage. At this time, over the memory cell region 1A, the insulating film MZ located under the memory gate electrode MG and between the memory gate electrode MG and the control gate electrodes CG is not removed but remains, while the insulating film MZ is removed from the other region. As can also be seen from FIG. 19, the insulating film MZ continuously extends over two regions which are the region between the memory gate electrode MG and the semiconductor substrate SB (p-type well PW1) and the region between the memory gate electrode MG and the control gate electrode CG. Note that, as has already been described above, the insulating film MZ is made of the laminated film including the foregoing silicon dioxide film MZ1, the foregoing silicon nitride film MZ over the silicon dioxide film MZ1, and the foregoing silicon dioxide film MZ3 over the silicon nitride film MZ2.

In Step S16, the oxide film OX2 that has been formed over the top surface of the gate electrode GE may also be removed from the peripheral circuit region 1B. Also, in Step S16, the insulating film OX1 located under the gate electrode GE is not removed from the peripheral circuit region 1B but remains thereover, while the insulating film OX1 may be removed from the other region. As a result, over the peripheral circuit region 1B, a state is achieved where the gate electrode GE is formed over the semiconductor substrate SB (p-type well PW2) via the insulating film OX1. The insulating film OZ1 remaining under the gate electrode GE serves as the gate insulating film of the MISFET.

Thus, over the semiconductor substrate SB (p-type well PW1), the memory gate electrode MG for the memory cell is formed via the insulating film MZ having an internal charge storage portion so as to be adjacent to the control gate electrode CG. More specifically, over the semiconductor substrate SB (p-type well PW1), the memory gate electrode MG for the memory cell is formed via the insulating film MZ having the internal charge storage portion so as to be adjacent to the control gate electrode CG via the insulating film MZ.

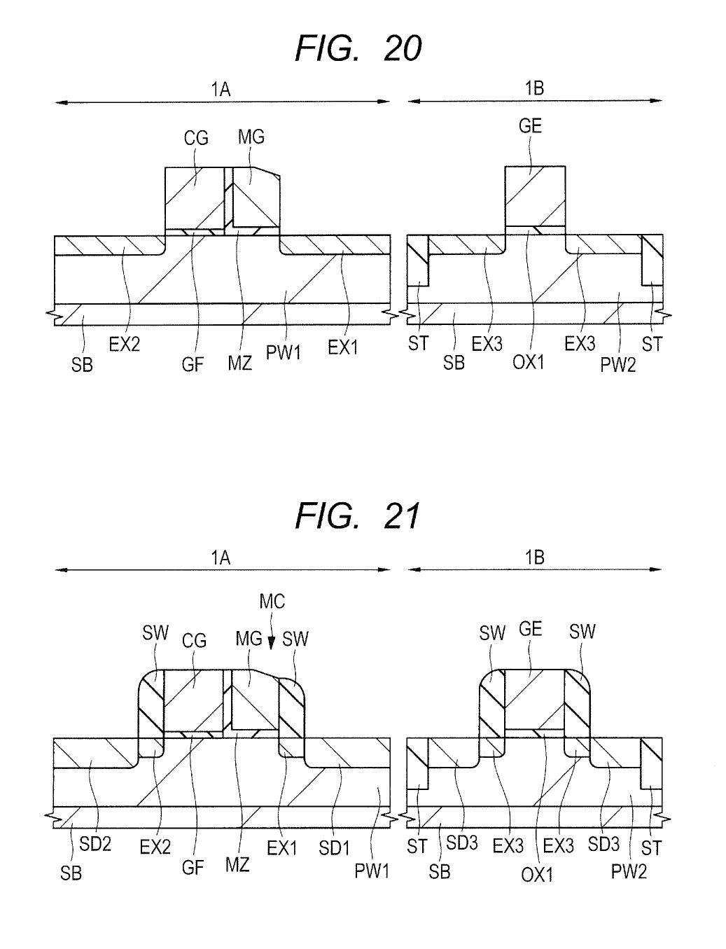

Next, as shown in FIG. 20, n-type semiconductor regions (n-type impurity diffusion layers, extension regions, or LDD regions) EX1, EX2, and EX3 are formed using an ion implantation method (Step S17 in FIG. 2).

In Step S17, using the control gate electrode CG, the memory gate electrode MG, and the gate electrode GE as a mask (ion implantation inhibiting mask), an n-type impurity such as, e.g., arsenic (As) or phosphorus (P) is introduced by an ion implantation method into the semiconductor substrate SB (p-type wells PW1 and PW2) to thus be able to form the n⁻-type semiconductor regions EX1, EX2, and EX3. At this time, in the memory cell region 1A, the n⁻-type semiconductor region EX1 is formed by self-alignment with the side wall (side wall opposite to the side wall adjacent to the control gate electrode CG via the insulating film MZ) of the memory gate electrode MG as a result of the memory gate electrode MG functioning as a mask. Also, in the memory cell region 1A, the n⁻-type semiconductor region EX2 is formed by self-alignment with the side wall (side wall opposite to the side wall adjacent to the memory gate electrode MG via the insulating film MZ) of the control gate electrode CG as a result of the control gate electrode CG functioning as a mask. On the other hand, in the peripheral circuit region 1B, the n⁻-type semiconductor regions EX3 are formed by self-alignment with the both side walls of the gate electrode GE as a result of the gate electrode GE functioning as a mask.

Each of the n⁻-type semiconductor regions EX1 and EX2 can function as a part of the source/drain region (source or drain region) of the memory cell formed in the memory cell region 1A. On the other hand, each of the n⁻-type semiconductor region EX3 can function as a part of the source/drain region (source or drain region) of the MISFET formed in the peripheral circuit region 1B. The n⁻-type semiconductor regions EX1, EX2, and EX3 can be formed in the same ion implantation step, but can also be formed in different ion implantation steps.

Next, over the respective side walls of the control gate electrode CG and the memory gate electrode MG and over the side walls of the gate electrode GE, sidewall spacers (sidewalls or side-wall insulating films) SW each made of an insulating film are formed (Step S18 in FIG. 2). The sidewall spacers SW can be regarded as side-wall insulating films.

Specifically, the step of forming the sidewall spacers SW in Step S18 can be performed as follows. That is, an insulating film for forming the sidewall spacers SW is deposited over the entire main surface of the semiconductor substrate SB using a CVD method or the like and then anisotropically etched (etched back). Thus, as shown in FIG. 21, the insulating film is selectively left over the respective side walls of the control gate electrode CG and the memory gate electrode MG and over the side walls of the gate electrode GE to be able to form the sidewall spacers SW. The sidewall spacers SW are formed over the both side walls of the gate electrode GE, over the side wall of the control gate electrode CG opposite to the side wall thereof adjacent to the memory gate electrode MG via the insulating film MZ, and over the side wall of the memory gate electrode MG opposite to the side wall thereof adjacent to the control gate electrode CG via the insulating film MZ.

Next, as shown in FIG. 21, n⁺-type semiconductor regions (n-type impurity diffusion layers or source/drain regions) SD1, SD2, and SD3 are formed using an ion implantation method (Step S19 in FIG. 2).

In Step S19, using the control gate electrode CG, the memory gate electrode MG, the gate electrode GE, and the sidewall spacers SW over the side walls thereof as a mask (ion implantation inhibiting mask), an n-type impurity such as, e.g., arsenic (As) or phosphorus (P) is ion-implanted into the semiconductor substrate SB (n-type wells PW1 and PW2) to thus be able to form the n⁺-type semiconductor regions SD1, SD2, and SD3. At this time, in the memory cell region 1A, the n⁺-type semiconductor region SD1 is formed by self-alignment with the sidewall spacer SW over the side wall of the memory gate electrode MG as a result of the memory gate electrode MG and the sidewall spacer SW over the side wall of the memory gate electrode MG each functioning as the mask. Also, in the memory cell region 1A, the n⁺-type semiconductor region SD2 is formed by self-alignment with the sidewall spacer SW over the side wall of the control gate electrode CG as a result of the control gate electrode CG and the sidewall spacer SW over the side wall of the control gate electrode CG each functioning as the mask. On the other hand, in the peripheral circuit region 1B, the n⁺-type semiconductor regions SD3 are formed by self-alignment with the sidewall spacers SW over the both side walls of the gate electrode GE as a result of the gate electrode GE and the sidewall spacers SW over the side walls thereof functioning as a mask. Thus, LDD (Lightly doped Drain) structures are formed. The n⁺-type semiconductor regions SD1, SD2, and SD3 can be formed in the same ion implantation step, but can also be formed in different ion implantation steps.

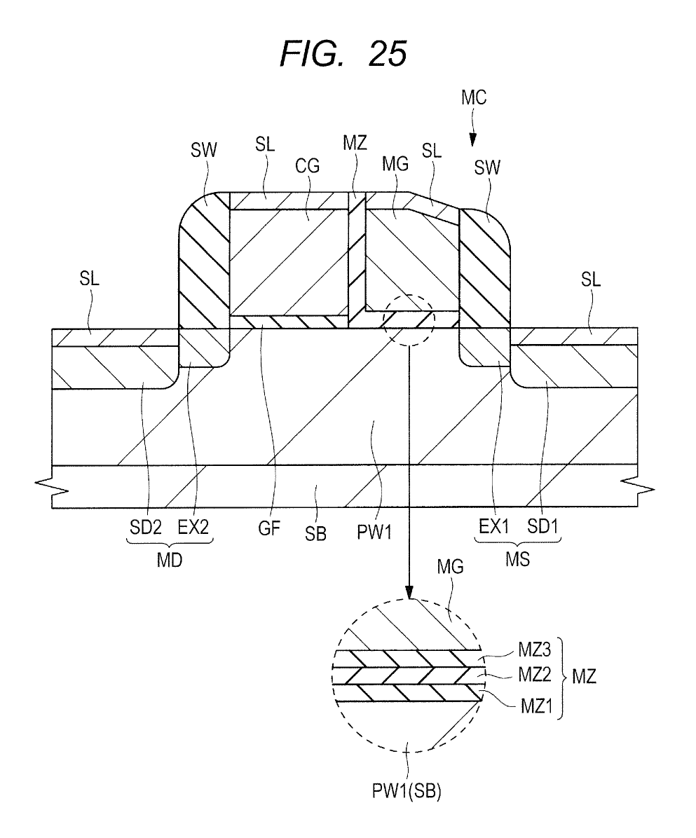

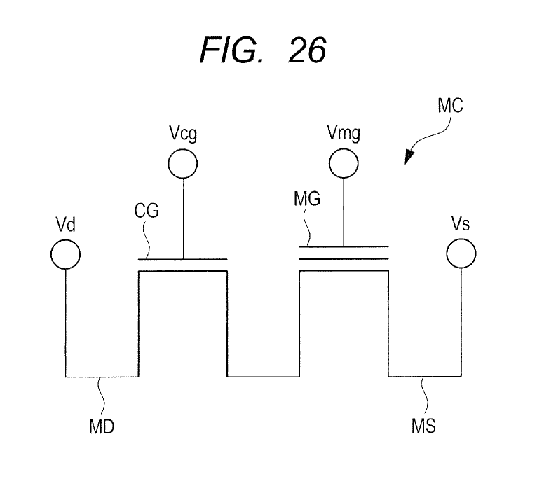

In this manner, the n⁻-type semiconductor region EX1 and the n⁺-type semiconductor region SD1 having an impurity concentration higher than that of the n-type semiconductor region EX1 form an n-type semiconductor region (corresponding to a semiconductor region MS in FIG. 25 described later) functioning as the source region of the memory transistor. Also, the n⁻-type semiconductor region EX2 and the n⁺-type semiconductor region SD2 having an impurity concentration higher than that of the n⁻-type semiconductor region EX2 form an n-type semiconductor region (corresponding to a semiconductor region MD in FIG. 25 described later) functioning as the drain region of the control transistor. Also, the n⁻-type semiconductor regions EX3 and the n⁺-type semiconductor regions SD3 having impurity concentrations higher than those of the n⁻-type semiconductor regions EX3 form n-type semiconductor regions each functioning as the source/drain region (source or drain semiconductor region) of the MISFET in the peripheral circuit region 1B. The n⁺-type semiconductor region SD1 has an impurity concentration higher than that of the n⁻-type semiconductor region EX1 and a junction depth deeper than that thereof. The n⁺-type semiconductor region SD2 has an impurity concentration higher than that of the n⁻-type semiconductor region EX2 and a junction depth deeper than that thereof. Each of the n⁺-type semiconductor regions SD3 has an impurity concentration higher than that of each of the n⁻-type semiconductor regions EX3 and a junction depth deeper than that thereof.

Next, activation anneal (Step S20 in FIG. 2) as heat treatment for activating the impurities introduced into the source and drain semiconductor regions (the n⁻-type semiconductor regions EX1, EX2, and EX3 and the n⁺-type semiconductor region SD1, SD2, and SD3) is performed (Step S20 in FIG. 2).

In this manner, a memory cell MC in the nonvolatile memory is formed in the memory cell region 1A and the MISFET is formed in the peripheral circuit region 1B.

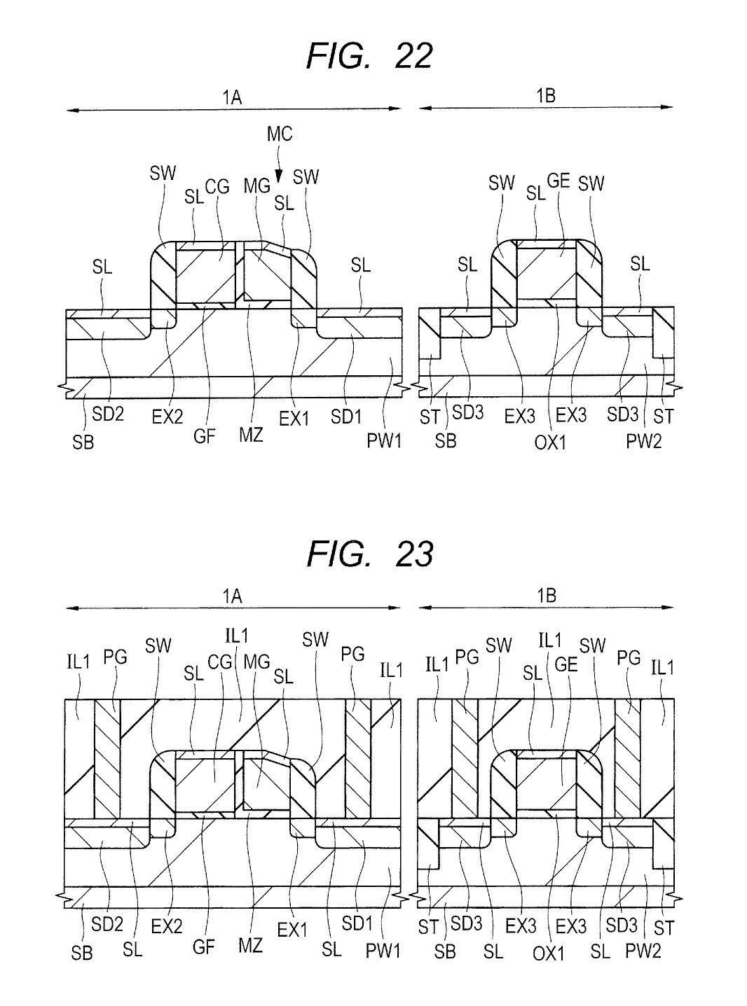

Next, as shown in FIG. 22, metal silicide layers SL are formed. The metal silicide layers SL are made of, e.g., nickel silicide, platinum-added nickel silicide, or the like. The metal silicide layers SL can be formed in the respective upper portions of the control gate electrode CG, the metal gate electrode MG, the gate electrode GE, and the n⁺-type semiconductor regions SD1, SD2, and SD3 by performing a so-called salicide (Self Aligned Silicide) process. By forming the metal silicide layers SL, diffusion resistances, contact resistances, and the like can be reduced. However, the formation of the metal silicide layers SL can also be omitted as unnecessary. The metal silicide layers SL can be formed in not all of the control gate electrode CG, the memory gate electrode MG, the gate electrode GE, and the n⁺-type semiconductor regions SD1, SD2, and SD3, but only some thereof.

Next, as shown in FIG. 23, over the entire main surface of the semiconductor substrate SB, an interlayer insulating film IL1 is formed as an insulating film so as to cover the control gate electrode CG, the memory gate electrode MG, the gate electrode GE, and the sidewall spacers SW.

The interlayer insulating film IL1 is made of a single-layer silicon dioxide film, a laminated film including a silicon nitride film and a silicon dioxide film formed over the silicon nitride film to be thicker than the silicon nitride film, or the like and can be formed using, e.g., a CVD method or the like. After the formation of the interlayer insulating film IL1, the upper surface of the interlayer insulating film IL1 is planarized as necessary using a CMP (Chemical Mechanical Polishing) method or the like.

Next, using a photoresist pattern (not shown) formed over the interlayer insulating film IL1 using a photolithographic method as an etching mask, the interlayer insulating film IL1 is dry-etched to be formed with contact holes (openings or through holes).

Next, in the contact holes, conductive plugs PG made of tungsten (W) or the like are formed as coupling conductor portions.

To form the plugs PG, e.g., over the interlayer insulating film IL1 including the insides (bottom portions and side walls) of the contact holes, a barrier conductor film is formed. The barrier conductor film is made of, e.g., a titanium film, a titanium nitride film, or a laminated film thereof. Then, over the barrier conductor film, a main conductor film made of a tungsten film or the like is formed so as to be embedded in the contact holes. Subsequently, the unneeded main conductor film and the unneeded barrier conductor film over the interlayer insulating film IL1 are removed by a CMP method, an etch-back method, or the like to be able to form the plugs PG. Note that, for simpler illustration, FIG. 23 integrally shows the barrier conductor film and the main conductor film which are included in each of the plugs PG.

The contact holes and the plugs PG embedded therein are formed over the n⁺-type semiconductor regions SD1, SD2, and SD3, the control gate electrode CG, the memory gate electrode MG, the gate electrode GE, and the like. At the bottom portion of each of the contact holes, a part of the main surface of the semiconductor substrate SB, e.g., a part of the n⁺-type semiconductor region SD1, SD2, or SD3 (metal silicide layer SL over the top surface thereof), a part of the control gate electrode CG (metal silicide layer SL over the top surface thereof), a part of the memory gate electrode MG (metal silicide layer SL over the top surface thereof), a part of the gate electrode GE (metal silicide layer SL over the top surface thereof), or the like is exposed. Note that the cross-sectional view of FIG. 23 shows a cross section in which parts of the n⁺-type semiconductor regions SD1, SD2, and SD3 (metal silicide layers SL over the top surfaces thereof) are exposed at the bottom portions of the contact holes and electrically coupled to the plugs PG embedded in the contact holes.

Next, over the interlayer insulating film IL1 in which the plugs PG are embedded, wires (wiring layers) M1 as first-layer wires are formed. A description will be given of the case where the wires M1 are formed using a damascene technique (which is a single damascene technique herein).

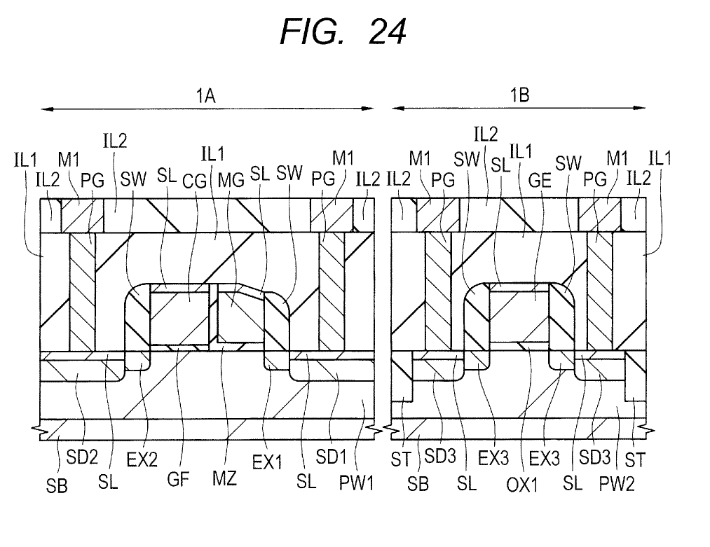

First, as shown in FIG. 24, over the interlayer insulating film IL1 in which the plugs PG are embedded, an insulating film IL2 is formed. The insulating film IL2 can also be formed of a laminated film including a plurality of insulating films. Then, in the predetermined regions of the insulating film IL2, wire trenches (trenches for the wires) are formed by dry etching using a photoresist pattern (not shown) as an etching mask. Subsequently, over the insulating film IL2 including the bottom portions and side walls of the wire trenches, a barrier conductor film is formed. The barrier conductor film is made of, e.g., a titanium nitride film, a tantalum film, a tantalum nitride film, or the like. Then, by a CVD method, a sputtering method, or the like, a copper seed layer is formed over the barrier conductor film. Further, using an electrolytic plating method or the like, a copper plating film is formed over the seed layer to be embedded in each of the wire trenches. Then, by removing the main conductor film (the copper plating film and the seed layer) and the barrier conductor film over the region other than in the wire trenches by a CMP method, the first-layer wires M1 using copper embedded in the wire trenches as a main conductive material are formed. In FIG. 24, for simpler illustration, the barrier conductor film, the seed layer, and the copper plating film are integrally shown as each of the wires M1.

The wires M1 are electrically coupled to the source region (semiconductor region MS) of the memory transistor, the drain region (semiconductor region MD) of the control transistor, the source/drain regions (n⁺-type semiconductor regions SD3) of the MISFET in the peripheral circuit region 1B, the control gate electrode CG, the memory gate electrode MG, the gate electrode GE, and the like via the plugs PG. Then, second- and higher-layer wires are formed by a dual damascene method or the like, but the illustration and description thereof is omitted herein. The wires M1 and the wires in the layers located thereover are not limited to damascene wires. The wires M1 and the wires in the layers located thereover can also be formed by patterning a conductor film for the wires. For example, the wires M1 and the wires in the layers located thereover can also be tungsten wires, aluminum wires, or the like.

Thus, the semiconductor device in the present embodiment is manufactured.

<About Structure of Semiconductor Device>

Next, a description will be given of a configuration of each of the memory cells in the nonvolatile memory in the semiconductor device in the present embodiment with reference to FIGS. 25 and 26.

FIG. 25 shows a main-portion cross-sectional view of the semiconductor device in the present embodiment, which is a main-portion cross-sectional view of the memory cell region of the nonvolatile memory. FIG. 26 is an equivalent circuit diagram of the memory cell. Note that, in FIG. 25, for simpler illustration, the illustration of the interlayer insulating films IL1 and IL2, the plugs PG, and the wires M1 of the structure in FIG. 24 described above is omitted.

As shown in FIG. 25, in the semiconductor substrate SB, the memory cell MC in the nonvolatile memory including the memory transistor and the control transistor is formed. In an actual situation, in the semiconductor substrate SB, a plurality of the memory cells MC are formed in an array-like configuration. Each of the memory cell regions is electrically isolated from the other region by an isolation region (corresponding to the foregoing isolation region ST and not shown in FIG. 25).

As shown in FIGS. 25 and 26, the memory cell MC in the nonvolatile memory in the semiconductor device in the present embodiment is a split-gate memory cell in which two MISFETs which are the control transistor (transistor for selecting the memory cell) having the control gate electrode CG and the memory transistor (transistor for storage) having the memory gate electrode MG are coupled to each other.

Here, the MISFET including the gate insulating film including the charge storage portion (charge storage layer) and the memory gate electrode MG is referred to as the memory transistor, and the MISFET including the gate insulating film and the control gate electrode CG is referred to as the control transistor.

The following will specifically describe the configuration of the memory cell MC.

As shown in FIG. 25, the memory cell MC in the nonvolatile memory includes the source and drain n-type semiconductor regions MS and MD formed in the p-type well PW1 of the semiconductor substrate SB, the control gate electrode CG formed over the semiconductor substrate SB (p-type well PW1), and the memory gate electrode MG formed over the semiconductor substrate SB (p-type well PW1) to be adjacent to the control gate electrode CG. The memory cell MC in the nonvolatile memory further includes the insulating film (gate insulating film) GF formed between the control gate electrode CG and the semiconductor substrate SB (p-type well PW1) and the insulating film MZ formed between the memory gate electrode MG and the semiconductor substrate SB (p-type well PW1).

The control gate electrode CG and the memory gate electrode MG extend along the main surface of the semiconductor substrate SB with the insulating film MZ being interposed between the respective facing side surfaces of the control gate electrode CG and the memory gate electrode MG and are arranged side by side. The extending directions of the control gate electrode CG and the memory gate electrode MG are generally perpendicular to the surfaces of the paper sheets with FIG. 25 and FIGS. 3 to 24 described above. The control gate electrode CG and the memory gate electrode MG are formed over the semiconductor substrate SB (p-type well PW1) between the semiconductor regions MD and MS via the insulating film GF or the insulating film MZ. The memory gate electrode MG is located closer to the semiconductor region MS. The control gate electrode CG is located closer to the semiconductor region MD. Note that the control gate electrode CG is formed over the semiconductor substrate SB via the insulating film GF, while the memory gate electrode MG is formed over the semiconductor substrate SB via the insulating film MZ.

The control gate electrode CG and the memory gate electrode MG are adjacent to each other with the insulating film MZ being interposed therebetween. The insulating film MZ extends over the two regions which are the region between the memory gate electrode MG and the semiconductor substrate SB (p-type well PW1) and the region between the memory gate electrode MG and the control gate electrode CG.

The insulating film GF formed between the control gate electrode CG and the semiconductor substrate SB (p-type well PW1) functions as the gate insulating film of the control transistor. On the other hand, the insulating film MZ between the memory gate electrode MG and the semiconductor substrate SB (p-type well PW1) functions as the gate insulating film (gate insulating film having the internal charge storage portion) of the memory transistor, while the insulating film MZ between the memory gate electrode MG and the control gate electrode CG functions as the insulating film for providing insulation (electrical insulation) between the memory gate electrode MG and the control gate electrode CG.

Of the insulating film MZ, the silicon nitride film MZ2 is an insulating film for storing charges and functions as a charge storage layer (charge storage portion). That is, the silicon nitride film MZ2 is a trapping insulating film formed in the insulating film MZ. Accordingly, the insulating film MZ can be regarded as the insulating film having the internal charge storage portion (which is the silicon nitride film MZ2 herein).

Each of the silicon dioxide films MZ3 and MZ1 located over and under the silicon nitride film MZ2 can function as a charge block layer or a charge confinement layer. By providing the insulating film MZ between the memory gate electrode MG and the semiconductor substrate SB with the structure in which the silicon nitride film MZ2 is interposed between the silicon dioxide films MZ3 and MZ1, charges can be stored in the silicon nitride film MZ2.

Each of the semiconductor regions MS and MD is a source or drain n-type semiconductor region. Here, the semiconductor region MS is the n-type semiconductor region functioning as a source region. The semiconductor region MD is the n-type semiconductor region functioning as a drain region. The source semiconductor region MS includes the n⁻-type semiconductor region EX1 (extension region) and the n⁺-type semiconductor region SD1 (source region) having an impurity concentration higher than that of the n⁻-type semiconductor region EX1. The drain semiconductor region MD includes the n⁻-type semiconductor region EX2 (extension region) and the n⁺-type semiconductor region SD2 (drain region) having an impurity concentration higher than that of the n⁻-type semiconductor region EX2.

The semiconductor region MS is formed at a position in the semiconductor substrate SB which is adjacent to the memory gate electrode MG in the gate length direction (gate length direction of the memory gate electrode MG). The semiconductor region MD is formed at a position in the semiconductor substrate SB which is adjacent to the control gate electrode CG in the gate length direction (gate length direction of the control gate electrode CG). Over the respective side walls of the memory gate electrode MG and the control gate electrode CG which are not adjacent to each other, the sidewall spacers SW are formed.

In the manufactured semiconductor device, the lower-concentration n⁻-type semiconductor region EX1 is formed under the sidewall spacer SW over the side wall of the memory gate electrode MG and the higher-concentration n⁺-type semiconductor region SD1 is formed outside the lower-concentration n⁻-type semiconductor region EX1. Consequently, the lower-concentration n⁻-type semiconductor region EX1 is formed to be adjacent to the channel region of the memory transistor and the higher-concentration n⁺-type semiconductor region SD1 is formed to be adjacent to the lower-concentration n⁻-type semiconductor region EX1 and spaced apart from the channel region of the memory transistor by a distance corresponding to the n⁻-type semiconductor region EX1.

In the manufactured semiconductor device, the lower-concentration n⁻-type semiconductor region EX2 is formed under the sidewall spacer SW over the side wall of the control gate electrode CG and the higher-concentration n⁺-type semiconductor region SD2 is formed outside the lower-concentration n⁻-type semiconductor region EX2. Consequently, the lower-concentration n⁻-type semiconductor region EX2 is formed to be adjacent to the channel region of the control transistor and the higher-concentration n⁺-type semiconductor region SD2 is formed to be adjacent to the lower-concentration n⁻-type semiconductor region EX2 and spaced apart from the channel region of the control transistor by a distance corresponding to the n⁻-type semiconductor region EX2.

Under the insulating film MZ under the memory gate electrode MG, the channel region of the memory transistor is formed. On the other hand, under the insulating film GF under the control gate electrode CG, the channel region of the control transistor is formed.

In the respective upper portions of the control gate electrode CG, the memory gate electrode MG, the n⁺-type semiconductor region SD1, and the n⁺-type semiconductor region SD2, the metal silicide layers LS are formed using a salicide technique.

<About Operation of Nonvolatile Memory>

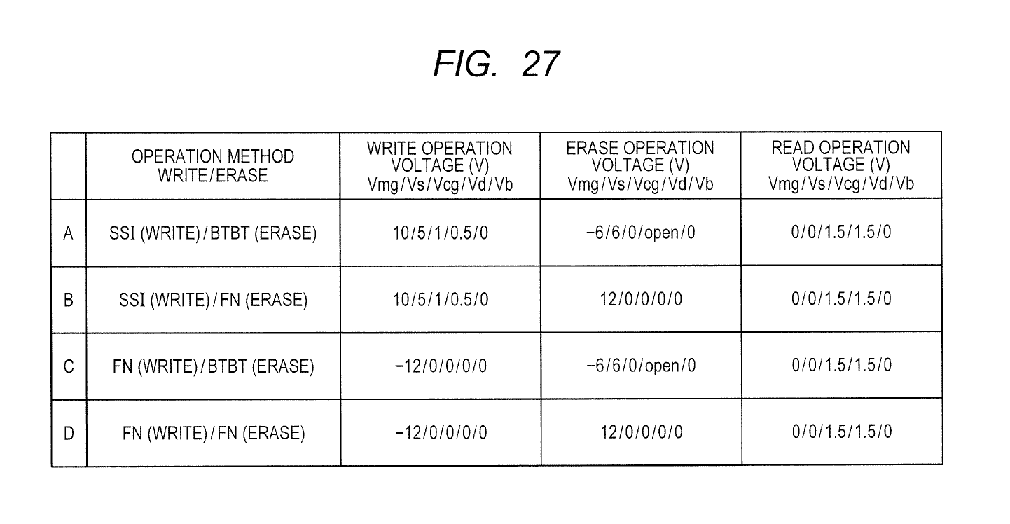

Next, a description will be given of an example of operations to the nonvolatile memory with reference to FIG. 27.

FIG. 27 is a table showing an example of conditions under which voltages are applied to the individual portions of a selected memory cell during “Write”, “Erase”, and “Read” operations in the present embodiment. The table of FIG. 27 shows a voltage Vmg applied to the memory gate electrode MG of a memory cell as shown in FIGS. 25 and 26, a voltage Vs applied to the source region (semiconductor region MS) thereof, a voltage Vcg applied to the control gate electrode CG thereof, a voltage Vd applied to the drain region (semiconductor region MD) thereof, and a base voltage Vb applied to the p-type well PW1 thereof during each of the “Write”, “Erase”, and “Read” operations. Note that what is shown in the table of FIG. 27 is a preferred example of the conditions for voltage application and is not limited thereto. The conditions for voltage application can variously be changed as necessary. In the present embodiment, the injection of electrons into the silicon nitride film MZ2 as the charge storage portion in the insulating film MZ of the memory transistor is defined as the “Write” operation, and the injection of holes into the silicon nitride film MZ2 is defined as the “Erase” operation.

A write method is subdivided into a write method referred to as a so-called SSI (Source Side Injection) method which performs a write operation by performing hot electron injection in accordance with source side injection, and a write method referred to as a so-called FN (Fowler Nordheim) method which performs a write operation using FN tunneling.

A write operation in accordance with the SSI method is performed by applying, e.g., voltages as shown as “Write Operation Voltages” in the row A or B in the table of FIG. 27 to the individual portions of the selected memory cell to which the write operation is to be performed and injecting electrons into the silicon nitride film MZ2 in the insulating film MZ of the selected memory cell. At this time, hot electrons are generated in the channel region (between the source and drain regions) under the space between the two gate electrodes (memory gate electrode MG and control gate electrode CG) and injected into the silicon nitride film MZ2 as the charge storage portion in the insulating film MZ under the memory gate electrode MG. The injected hot electrons (electrons) are trapped by the trap level in the silicon nitride film MZ2 in the insulating film MZ, resulting in an increase in the threshold of the memory transistor. That is, the memory transistor is brought into a written state.

A write operation in accordance with the FN method is performed by applying, e.g., voltages as shown as “Write Operation Voltages” in the row C or D in the table of FIG. 27 to the individual portions of the selected memory cell to which the write operation is to be performed and causing tunneling of electrons from the memory gate electrode MG in the selected memory cell and injection thereof into the silicon nitride film MZ2 in the insulating film MZ. At this time, the electrons from the memory gate electrode MG tunnel through the silicon dioxide film MZ3 by FN tunneling to be injected into the insulating film MZ and trapped by the trap level in the silicon nitride film MZ2 in the insulating film MZ, resulting in an increase in the threshold voltage of the memory transistor. That is, the memory transistor is brought into the written state.

Note that the write operation in accordance with the FN method can also be performed by causing tunneling of electrons from the semiconductor substrate SB and injection thereof into the silicon nitride film MZ2 in the insulating film MZ.

An erase method is subdivided into an erase method referred to as a so-called BTBT (Band-To-Band Tunneling phenomenon) method which performs an erase operation by hot hole injection using the BTBT, and an erase method referred to as the so-called FN (Fowler Nordheim) method which performs an erase operation using the FN tunneling.

An erase operation in accordance with the BTBT method is performed by injecting holes generated by the BTBT into the charge storage portion (silicon nitride film MZ2 in the insulating film MZ). For example, voltages as shown as “Erase Operation Voltages” in the row A or C in the table of FIG. 27 are applied to the individual portions of the selected memory cell to which the erase operation is to be performed. Thus, the holes are generated using the BTBT phenomenon and subjected to electric field acceleration to be injected into the silicon nitride film MZ2 in the insulating film MZ of the selected memory cell, thus reducing the threshold voltage of the memory transistor. That is, the memory transistor is brought into an erased state.

An erase operation in accordance with the FN method is performed by applying, e.g., voltages as shown as “Erase Operation Voltages” in the row B or D in the table of FIG. 27 to the individual portions of the selected memory cell to which the erase operation is to be performed and causing tunneling of holes from the memory gate electrode MG in the selected memory cell and injection thereof into the silicon nitride film MZ2 in the insulating film MZ. At this time, the holes from the memory gate electrode MG tunnel through the silicon dioxide film MZ3 by the FN tunneling to be injected into the insulating film MZ and trapped by the trap level in the silicon nitride film MZ2 in the insulating film MZ, resulting in a reduction in the threshold voltage of the memory transistor. That is, the memory transistor is brought into an erased state.

Note that the erase operation in accordance with the FN method can also be performed by causing tunneling of holes from the semiconductor substrate SB and injection thereof into the silicon nitride film MZ2 in the insulating film MZ.

During a read operation, e.g., voltages as shown as “Read Operation Voltages” in the row A, B, C, or D in the table of FIG. 27 are applied to the individual portions of the selected memory cell to which the read operation is to be performed. By setting the voltage Vmg to be applied to the memory gate electrode MG during the read operation to a value between the threshold voltage of the memory transistor in the written state and the threshold voltage thereof in the erased state, the written state or the erased state can be determined.

<About Study by Present Inventors>

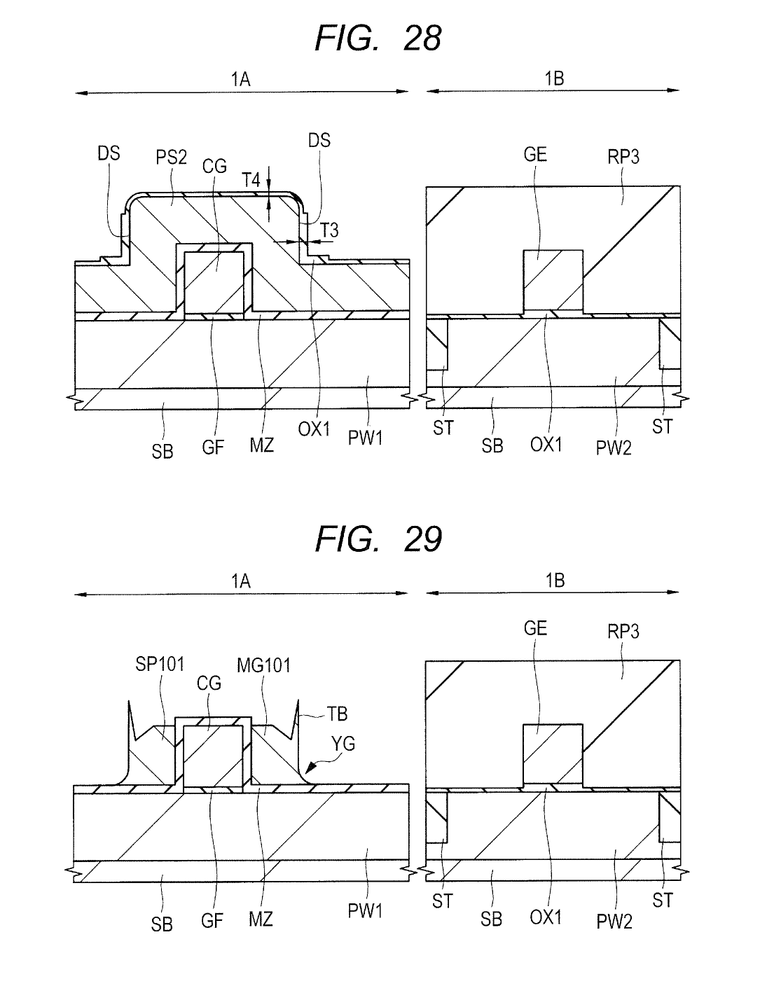

A description will be given of methods of manufacturing semiconductor devices in first and second studied examples studied by the present inventors. FIGS. 28 and 29 are main-portion cross-sectional views of the semiconductor device in the first studied example during the manufacturing process thereof, which show cross sections of the region corresponding to that in each of FIGS. 3 to 16 described above and FIGS. 18 to 24.

In the case of the first studied example also, the manufacturing process is substantially the same as the manufacturing process in the present embodiment until the structure in FIG. 28 corresponding to FIG. 12 described above is obtained by performing Step S11 described above.

However, in the first studied example, after Step S11 described above is performed, unlike in the present embodiment, an etch-back step equivalent to Step S14 described above is performed without performing the step of removing the insulating film OX1 in Step S12 and the step of forming the oxide film OX2 in Step S13. FIG. 29 shows the stage where the etch-back step equivalent to Step S14 described above has been performed.

However, in the case of the first studied example, Steps S12 and S13 have not been performed so that the insulating film OX1 and a silicon film PS2 are etched back using an anisotropic etching technique. By the etch-back step, over the memory cell region 1A, a memory gate electrode MG101 is formed of the silicon film PS2 remaining in a sidewall spacer shape over one of the both side walls of the control gate electrode CG via the insulating film MZ. Also, over the memory cell region 1A, a silicon spacer SP101 is formed of the silicon film PS2 remaining in a sidewall spacer shape over the other of the both side walls of the control gate electrode CG via the insulating film MZ. The memory gate electrode MG101 is an equivalent to the foregoing memory gate electrode MG. The silicon spacer SP101 is an equivalent to the foregoing silicon spacer SP.

However, according to the study by the present inventors, in the case of the first studied example, at the stage where the etch-back step equivalent to Step S14 is started, the thickness of the insulating film OX1 over the memory cell region 1A is not uniform, resulting in a state where the insulating film OX1 has a relatively thicker portion and a relatively thinner portion.

That is, at the stage where the insulating film OX1 has been formed in Step S8, the thickness of the insulating film OX1 is substantially uniform. However, over the memory cell region 1A, parts of the insulating film OX1 are undesirably etched by various steps after the formation of the insulating film OX1 in Step S8, resulting in the non-uniform thickness of the insulating film OX1. Specifically, parts of the insulating film OX1 are etched by the etching step in Step S10, the wet cleaning treatment after the removal of the photoresist pattern RP2, and the etching step in Step S11, resulting in the non-uniform thickness of the insulating film OX1 over the memory cell region 1A. A more specific description thereof is as follows.

First, a description will be given of the etching step in Step S10. Since the etching step in Step S10 is performed to pattern the silicon film PS3, in Step S10, etching is performed under etching conditions such that the insulating film OX1 is less likely to be etched than the silicon film PS3. However, it is difficult to completely eliminate the possibility that the insulating film OX1 is etched. Also, in the etching step in Step S10, anisotropic etching is performed. The portions of the insulating film OX1 which are formed over the stepped portions DS of the silicon film PS2 are less likely to be etched than the portion of the silicon film PS2 which is formed over the horizontal surface (surface generally parallel with the main surface of the semiconductor substrate SB) of the silicon film PS2. As a result, when the etching in Step S10 is performed, over the memory cell region 1A, the portion of the insulating film OX1 other than the portions thereof which are formed over the stepped portions DS of the silicon film PS2 has a thickness smaller than the thickness of each of the portions of the insulating film OX1 which are formed over the stepped portions DS of the silicon film PS2.

Next, wet cleaning treatment after the removal of the photoresist pattern RP2 will be described. In the etching step in Step S10, anisotropic etching is performed so that, over the memory cell region 1A, parts of the silicon film PS3 remain as the remaining portions PS3a at positions adjacent to the stepped portions DS of the silicon film PS2 via the insulating film OX1. Accordingly, the step of removing the photoresist pattern RP2 and the subsequent wet cleaning treatment are performed in the presence of the remaining portions PS3a. In the wet cleaning treatment also, it is difficult to completely eliminate the possibility that the insulating film OX1 is etched. When the wet cleaning treatment after the step of removing the photoresist pattern RP2 is performed, over the memory cell region 1A, the portions of the insulating film OX1 which are covered with the remaining portions PS3a of the silicon film PS3 remain unetched. However, the other portion of the insulating film OX is slightly etched. As a result, when the wet cleaning treatment is performed after the step of removing the photoresist pattern RP2, over the memory cell region 1A, the thickness of the portion of the insulating film OX1 other than the portions thereof which are formed over the stepped portions DS of the silicon film PS2 is increasingly smaller than the thickness of each of the portions of the insulating film OX1 which are formed over the stepped portions DS of the silicon film PS2.

Next, the etching step in Step S11 will be described. The etching step in Step S11 is performed to remove the remaining portions PS3a of the silicon film PS3. Accordingly, in Step S11, etching is performed under etching conditions such that the insulating film OX1 is less likely to be etched than the silicon film PS3. However, it is difficult to completely eliminate the possibility that the insulating film OX1 is etched. Also, in the etching step in Step S11, isotropic etching is performed. The portions of the insulating film OX1 which are covered with the remaining portions PS3a of the silicon film PS3 remain unetched until the remaining portions PS3a of the silicon film PS3 are removed. However, the other portion of the insulating film OX1 is slightly etched. As a result, when the etching in Step S11 is performed, over the memory cell region 1A, the thickness of the portion of the insulating film OX1 other than the portions thereof which are formed over the stepped portions DS of the silicon film PS2 is increasingly smaller than the thickness of each of the portions of the insulating film OX1 which are formed over the stepped portions DS of the silicon film PS2.

Thus, at the stage where the insulating film OX1 has been formed in Step S8, even when the thickness of the insulating film OX1 is substantially uniform, parts of the insulating film OX1 are etched by the etching step in Step S10, the wet cleaning treatment after the removal of the photoresist pattern RP2, and the etching step in Step S11, resulting in the non-uniform thickness of the insulating film OX1 over the memory cell region 1A. That is, the difference between a thickness T3 of each of the portions of the insulating film OX1 which are formed over the stepped portions DS of the silicon film PS2 and a thickness T4 of the other portion of the insulating film OX1 undesirably increases.

Accordingly, in the case of the first studied example, an etch-back step equivalent to Step S14 is performed in a state where the thickness of the insulating film OX1 is non-uniform. In addition, the non-uniform thickness of the insulating film OX1 is not constant among a plurality of the semiconductor substrates SB but tends to fluctuate and may vary from one semiconductor substrate SB to another. Consequently, the cross-sectional shape of the formed memory gate electrode MG101 may vary from one semiconductor substrate SB to another. The cross-sectional shape of the formed memory gate electrode MG101 varying from one semiconductor substrate SB to another is not desirable in terms of stably manufacturing the semiconductor device. However, an attempt to prevent this results in difficult process management.

In addition, over the memory cell region 1A, due to the non-uniform thickness of the insulating film OX1, the memory gate electrode MG101 formed by the etch-back step equivalent to Step S14 may have a cross-sectional shape which is not appropriate for the memory gate electrode. For example, as shown in FIG. 29, the memory gate electrode MG101 may have a cross-sectional shape having projecting portions TB excessively projecting upward at the shoulder portions thereof. When broken in the subsequent step, the excessively projecting portions TB cause contamination so that it is desirable to prevent the excessively projecting portions TB. The memory gate electrode MG101 may also have a cross-sectional shape in which the lower portion of each of the side surfaces trails (the region shown by the arrow YG in FIG. 29). This is disadvantageous in terms of properly forming the n⁻-type semiconductor region EX1 and the n⁺-type semiconductor region SD1 so that it is desirable to prevent the trailing lower side surface. Note that the cross-sectional shape of the silicon spacer SP101 is also the same as the cross-sectional shape of the memory gate electrode MG. However, since the silicon spacer SP101 is removed afterward, the cross-sectional shape of the silicon spacer SP101 is not so important, while the cross-sectional shape of the memory gate electrode MG101 is important.

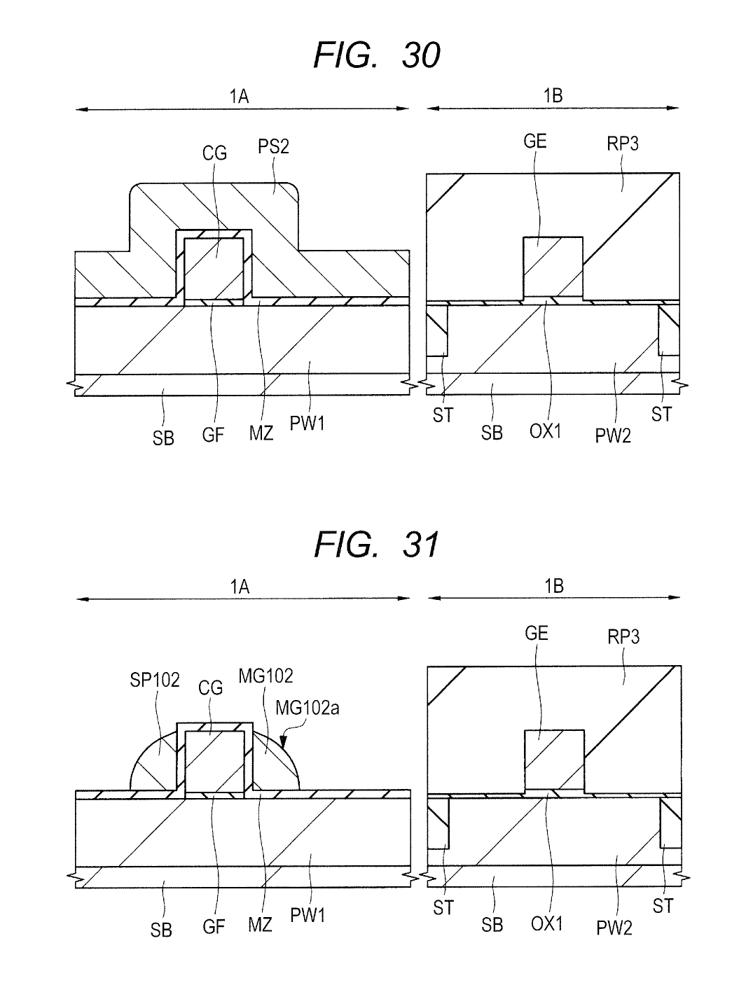

Accordingly, as the second studied example, a description will be given of the case where, after the etching step in Step S11, the step of removing the insulating film OX1 in Step S12 described above is performed but, unlike in the present embodiment, the etch-back step equivalent to Step S14 described above is performed without performing the step of forming the oxide film OX2 in Step S13. FIGS. 30 and 31 are main-portion cross-sectional views of the semiconductor device in the second studied example during the manufacturing process thereof, which show cross sections of the region corresponding to that in each of FIGS. 3 to 16 described above and FIGS. 18 to 24.

In the case of the second studied example, after the structure in FIG. 12 described above is obtained by removing the remaining portions PS3a of the silicon film PS3 in the etching step in Step S11, a step equivalent to Step S12 is performed to remove the insulating film OX1 by isotropic etching (preferably, wet etching), as shown in FIG. 30 corresponding to FIG. 13 described above. Then, as shown in FIG. 31, the etch-back step equivalent to Step S14 is performed without performing the step of removing the photoresist pattern RP3 and with the photoresist pattern RP3 being left to form a memory gate electrode MG102 and a silicon spacer SP102. The memory gate electrode MG102 is an equivalent to the foregoing memory gate electrodes MG and MG101. The silicon spacer SP102 is an equivalent to the foregoing spacers SP and SP101.

In the case of the second studied example, the etch-back step equivalent to Step S14 is performed in a state where an insulating film such as an oxide film is not formed over the top surface of the silicon film PS2. As a result, when the silicon film PS2 is etched back to form the memory gate electrode MG and the silicon spacer SP, the memory gate electrode MG102 is less likely to have a cross-sectional shape appropriate for the memory gate electrode. That is, the memory gate electrode MG102 is more likely to have a cross-sectional shape such as that of the memory gate electrode MG102 shown in FIG. 31.

Specifically, the memory gate electrode MG102 is formed in a sidewall spacer shape over the side wall of the control gate electrode CG via the insulating film MZ, and the height of a shoulder portion MG102a of the memory gate electrode MG102 tends to be reduced. This is because, when the silicon film PS2 is etched back by anisotropic etching, the shoulder portion MG102a of the memory gate electrode MG102 tends to be excessively etched back to reduce the height of the shoulder portion MG102a of the memory gate electrode MG102. When the height of the shoulder portion MG102a of the memory gate electrode MG102 is reduced, in the ion implantation step for forming the n⁻-type semiconductor region EX1 and in the ion implantation step for forming the n⁺-type semiconductor region SD1, the implanted impurity ions are more likely to penetrate the memory gate electrode MG102 in the vicinity of the shoulder portion MG102a of the memory gate electrode MG102. When the implanted impurity ions have penetrated the memory gate electrode MG102, the impurity ions are undesirably implanted into the insulating film MZ and the substrate region (p-type well PW1) each located immediately under the memory gate electrode MG102. This may damage the insulating film MZ or change the impurity concentration of the channel region of the memory transistor. In addition, it is harder to properly form the n⁻-type semiconductor region EX1 and the n⁺-type semiconductor region SD1. This leads to the degradation of the reliability or performance of the semiconductor device. Therefore, it is desirable to maximally prevent the implanted impurity from penetrating the memory gate electrode MG102.

Accordingly, it is desirable to bring the cross-sectional shape of the memory gate electrode closest to a rectangle. This can more reliably inhibit or prevent the implanted impurity ions from penetrating the memory gate electrode MG102 in the ion implantation step for forming the foregoing n⁻-type semiconductor region EX1 and in the ion implantation step for forming the foregoing n⁺-type semiconductor region SD1.

To achieve this, it can be considered that, in a state where an etching inhibiting film is formed over the top surface of the silicon film PS2, the etching inhibiting film and the silicon film PS2 are etched back to thus form the memory gate electrode. This can inhibit or prevent the height of the shoulder portion of the memory gate electrode from being reduced and bring the cross-sectional shape of the memory gate electrode closer to a rectangle.

The etching inhibiting film is less likely to be etched than the silicon film PS2 in the step of etching back the silicon film PS2. In the case of the first studied example, an equivalent to the etching inhibiting film is the insulating film OX1. In the case of the present embodiment, an equivalent to the etching inhibiting film is the oxide film OX2. In the case of the second studied example, there is nothing equivalent to the etching inhibiting film.

However, in the case of the first studied example, the etch-back step equivalent to Step S14 is performed in the state where the thickness of the insulating film OX1 formed over the top surface of the silicon film PS2 is non-uniform, as described above. As a result, even when the insulating film OX1 functions as the etching inhibiting film in the etch-back step, the silicon film PS2 is etched back in a state where there are variations in the thickness of the etching inhibiting film. As a result, the cross-sectional shape of the formed memory gate electrode MG101 also varies. This leads to the degradation of the reliability of the semiconductor device. Therefore, it is desirable to maximally prevent variations in the thickness of the etching inhibiting film.

That is, in etching back the silicon film PS2 to form the memory gate electrode, it is desirable to bring the cross-sectional shape of the formed memory gate electrode closer to a rectangle in terms of improving the reliability or performance of the semiconductor device. To achieve this, it is desirable that, in a state where the etching inhibiting film having a film thickness as uniform as possible is formed over the top surface of the silicon film PS2, the etching inhibiting film and the silicon film PS2 are etched back to form the memory gate electrode.

<About Main Characteristic Features and Effects>

Accordingly, one of the main characteristic features of the present embodiment is that, after the insulating film OX1 is removed in Step S12, the oxide film OX2 is formed in Step S13 and then the oxide film OX2 and the silicon film PS2 are etched back in Step S14 to form the memory gate electrode MG (and the silicon spacer SP). That is, in the present embodiment, not the insulating film OX1, but the oxide film OX2 newly formed after the removal of the insulating film OX1 is used as the etching inhibiting film in the etch-back step in Step S14.

As has been described in relation to the foregoing first studied example, even though the thickness of the insulating film OX1 is substantially uniform at the stage where the insulating film OX1 has been formed in Step S8, parts of the insulating film OX1 over the memory cell region 1A are etched by subsequent various steps, resulting in the non-uniform thickness of the insulating film OX1. Specifically, parts of the insulating film OX1 are etched by the etching step in Step S10, the wet cleaning treatment after the removal of the photoresist pattern RP2, and the etching step in Step S11, resulting in the non-uniform thickness of the insulating film OX1 over the memory cell region 1A. However, in the present embodiment, even when the film thickness of the insulating film OX1 becomes non-uniform as a result of the various steps prior to Step S12, the insulating film OX1 having the non-uniform film thickness is removed by Step S12.

Since the oxide film OX2 is formed in Step S13 and then the etch-back step in Step S14 is performed, the film thickness of the oxide film OX2 and the uniformity of the film thickness thereof at the stage where the etch-back step is performed in Step S14 can be controlled in the step of forming the oxide film OX2 in Step S13. That is, by uniformly forming the oxide film OX2 over the top surface of the silicon film PS2 to an intended thickness in Step S13, the etch-back step in Step S14 can be performed in a state where the oxide film OX2 having the intended thickness is uniformly formed over the top surface of the silicon film PS2. Also, by forming the oxide film OX2 in Step S13 to a thickness appropriate for the oxide film OX2 used as the etching inhibiting film in the etch-back step in Step S14, the etch-back step in Step S14 can be performed in a state where the oxide film OX2 having the thickness appropriate for the etching inhibiting film is formed over the top surface of the silicon film PS2.

As a result, in the etch-back step in Step S14, the oxide film OX2 functions as the etching inhibiting film and can inhibit the side surfaces of the stepped portions DS of the silicon film PS2 from being etched. This allows the formed memory gate electrode MG to have a cross-sectional shape (close to a rectangle) appropriate for the memory gate electrode. Therefore, it is possible to improve the reliability and performance of the semiconductor device.

For example, since the gate electrode MG is provided with the cross-sectional shape (close to a rectangle) appropriate for the memory gate electrode, it is possible to more reliably inhibit or prevent the implanted impurity ions from penetrating the memory gate electrode MG in the ion implantation step for forming the n⁻-type semiconductor region EX1 and in the ion implantation step for forming the n⁺-type semiconductor region SD1. This can prevent trouble resulting from the penetration of the implanted impurity ions through the memory gate electrode MG such as, e.g., damage to the insulating film MZ or a change in the impurity concentration of the channel region. It is also possible to prevent the impurity ions intended to form the n⁻-type semiconductor region EX1 and the impurity ions intended to form the n⁺-type semiconductor region SD1 from being implanted into an unintended region. It is also possible to prevent a situation where the impurity ions intended to form the n⁻-type semiconductor region EX1 and the impurity ions intended to form the n⁺-type semiconductor region SD1 are no longer implanted into the intended regions. This allows the n⁻-type semiconductor region EX1 and the n⁺-type semiconductor region SD1 to be more properly formed. Therefore, it is possible to improve the reliability and performance of the semiconductor device.

Since the insulating film OX1 is used as the gate insulating film (gate insulating film under the gate electrode GE) of the MISFET in the peripheral circuit region 1B, in Step S8, it is necessary to form the insulating film OX1 to a thickness appropriate for the gate insulating film of the MISFET over the peripheral circuit region 1B. Accordingly, it is difficult to set the thickness of the insulating film OX1 to a thickness appropriate for the etching inhibiting film in the etch-back step in Step S14. From this viewpoint also, in the case of the foregoing first studied example in which the insulating film OX1 is used as the etching inhibiting film in the etch-back step in Step S14, it is not easy to form the memory gate electrode MG101 into a rectangular cross-sectional shape.

By contrast, in the present embodiment, the insulating film OX1 is removed in Step S12 and the oxide film OX2 formed in Step S13 is used as the etching inhibiting film in the etch-back step in Step S14. This allows the thickness of the oxide film OX2 formed in Step S13 to be controlled independently of the thickness of the insulating film OX1 formed in Step S8. That is, the oxide film OX2 formed in Step S13 and the insulating film OX1 formed in Step S8 are allowed to have different thicknesses. For example, the oxide film OX2 formed in Step S13 is allowed to have a thickness smaller than that of the insulating film OX1 formed in Step S8. Accordingly, the thickness of the oxide film OX2 formed in Step S13 can be set to a thickness appropriate for the etching inhibiting film in the etch-back step in Step S14. On the other hand, the thickness of the insulating film OX1 formed in Step S8 can be set to a thickness appropriate for the gate insulating film of the MISFET in the peripheral circuit region 1B. Therefore, it is possible to improve the reliability and performance of the semiconductor device.

Also, in Step S18, the oxide film OX2 is preferably formed by plasma oxidation. This allows the relatively thin oxide film (OX2) to be more uniformly formed.

Also, in the present embodiment, the uniformity of the film thickness of the etching inhibiting film (which corresponds to the insulating film OX1 in the case of the foregoing first studied example and corresponds to the oxide film OX2 in the case of the present embodiment) can further be improved than in the foregoing first studied example. From another perspective, the uniformity of the film thickness of the oxide film OX2 immediately before the etch-back step in Step S14 is performed can be set higher than the uniformity of the film thickness of the insulating film OX1 immediately before the step of removing the insulating film OX1 in Step S12 is performed.

Accordingly, ΔT2<ΔT1 is satisfied. Here, ΔT1 corresponds to the difference between the thickness T3 of each of the portions of the insulating film OX1 which are formed over the stepped portions (side surfaces of the stepped portions) DS of the silicon film PS2 and the thickness T4 of the other portion of the insulating film OX1 immediately before the step of removing the insulating film OX1 in Step S12 is performed (FIG. 12) (i.e., ΔT1=T3−T4 is satisfied). On the other hand, ΔT2 corresponds to the difference between a thickness T5 of each of the portions of the oxide film OX2 which are formed over the stepped portions (side surfaces of the stepped portions) DS of the silicon film PS2 and a thickness T6 of the other portion of the oxide film OX2 immediately before the etch-back step in Step S14 is performed (FIG. 15) (i.e., ΔT2=T5−T6 is satisfied). That is, T5−T6<T3−T4 is satisfied.

In the present embodiment, after the gate electrode GE is formed by patterning the silicon film PS3 in Step S10, the remaining portions (PS3a) of the silicon film PS3 over the memory cell region 1A are preferably removed using isotropic etching (preferably wet etching) in Step S11. This keeps the remaining portions (PS3a) of the silicon film PS3 over the memory cell region 1A from adversely affecting the subsequent steps. Consequently, the memory gate electrode MG can more properly be formed. However, by the etching in Step S11, the uniformity of the film thickness of the insulating film OX1 is further reduced. By contrast, in the present embodiment, the insulating film OX1 is removed in Step S12 and the oxide film OX2 formed in Step S13 is used as the etching inhibiting film in the etch-back step in Step S14. This allows a disadvantage resulting from the reduction in the uniformity of the insulating film OX1 in Step S11 to be avoided.

Also, in the present embodiment, it is preferable to form the photoresist pattern RP3 (second mask layer) which covers the peripheral circuit region 1B and exposes the memory cell region 1A over the semiconductor substrate SB and then perform the etching step in Step S11 and the step of removing the insulating film OX1 in Step S12. As a result, the etching in each of Steps S11 and S12 is performed in a state where the gate electrode GE is covered with the photoresist pattern RP3. Therefore, it is possible to prevent the etching in each of Steps S11 and S12 from adversely affecting the gate electrode GE over the peripheral circuit region 1B.

Also, in the present embodiment, after the gate electrode GE is formed by patterning the silicon film PS3 using the photoresist pattern RP2 as an etching mask in Step S10 described above, the foregoing photoresist pattern RP2 is removed. After the removal of the photoresist pattern RP2, wet cleaning treatment is preferably performed. That is, it is preferable that, after the foregoing photoresist pattern RP2 is removed by asking or the like, the wet cleaning treatment is performed and then the photoresist pattern RP3 is formed using a photolithographic method. This can more reliably prevent the residues of the photoresist pattern RR2 from being left. However, by the wet cleaning process, the uniformity of the film thickness of the insulating film OX1 is further reduced. By contrast, in the present embodiment, the insulating film OX1 is removed in Step S12, while the oxide film OX2 formed in Step S13 is used as the etching inhibiting film in the etch-back step in Step S14. This allows a disadvantage resulting from the reduction in the uniformity of the insulating film OX1 in Step S11 to be avoided.

Also, in the present embodiment, after the insulating film OX1 is removed from the top surface of the silicon film PS2 in Step S12, the oxide film OX2 is formed over the top surface of the silicon film PS2 in Step S13. Since the number of the process steps is increased to be larger than that in the foregoing first studied example, if the problem described with reference to the first studied example shown in FIGS. 28 and 29 described above is not noticed, not the present embodiment which forms the oxide film OX2 after removing the insulating film OX1, but the foregoing first studied example should be employed. However, having noticed the problem that, in the case of the foregoing first studied example using the insulating film OX1 as the etching inhibiting film in Step S14, the memory gate electrode is less likely to have a cross-sectional shape appropriate for the memory gate electrode as described above, the present inventors have employed the manufacturing process in the present embodiment which forms the oxide film OX2 after removing the insulating film OX1 even though the number of the process steps increases. Therefore, it can be said that the present embodiment has been achieved only after the problem described with reference to the foregoing first studied example was recognized.

### Embodiment 2

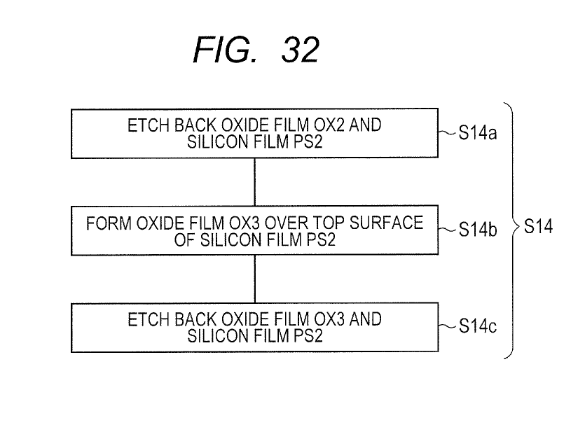

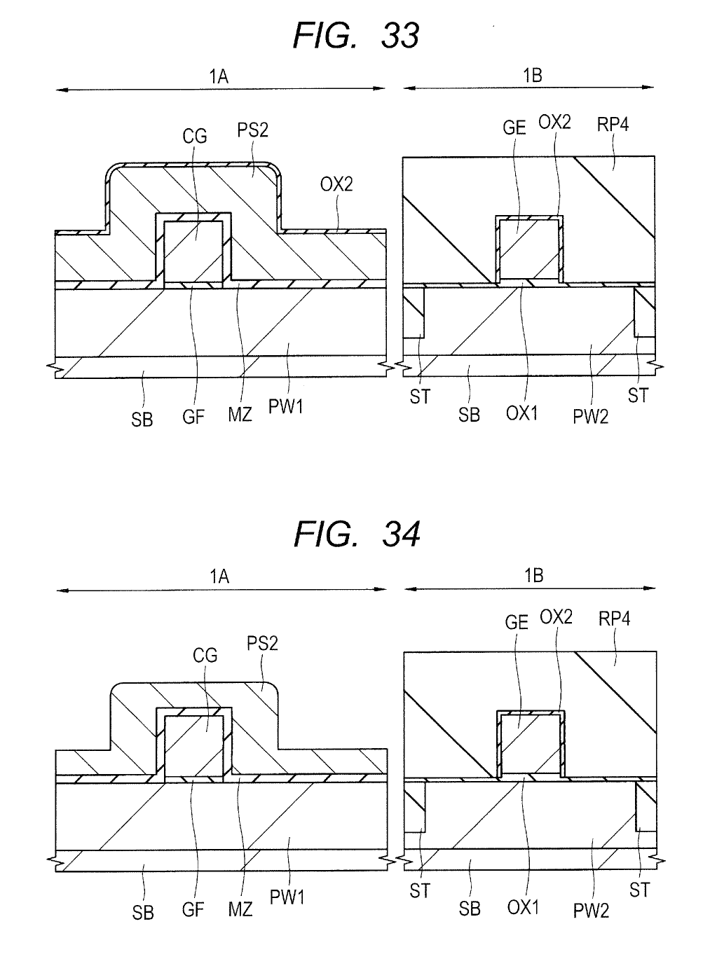

FIG. 32 is a process flow chart showing Step S14 in Embodiment 2. FIGS. 33 to 36 are main-portion cross-sectional views of a semiconductor device in Embodiment 2 during the manufacturing process thereof. FIGS. 33 to 36 show a cross-sectional region corresponding to each of FIGS. 3 to 16 described above and FIGS. 18 to 24 in Embodiment 1 described above.

The manufacturing process of the semiconductor device in Embodiment 2 is substantially the same as the manufacturing process of the semiconductor device in Embodiment 1 described above until the photoresist pattern RP4 is formed and the structure in FIG. 33 corresponding to FIG. 15 described above is obtained. Accordingly, a repetitive description thereof is omitted herein and the difference with Embodiment 1 described above will mainly be described. However, in Embodiment 2, the film thickness of the oxide film OX2 formed in Step S13 can be set smaller than in Embodiment 1 described above.

Embodiment 2 is mainly different from Embodiment 1 described above in Step S14 for forming the memory gate electrode MG. That is, in Embodiment 2, Step S14 for forming the memory gate electrode MG includes three Steps S14a, S14b, and S14c shown in FIG. 32.

Specifically, after the photoresist pattern RP4 is formed and the structure in FIG. 33, which is the same as in FIG. 15 described above, is obtained, as shown in FIG. 34, the oxide film OX2 and the silicon film PS2 are etched back using an anisotropic etching technique (Step S14a in FIG. 32). FIG. 34 corresponds to the stage where the etch-back step in Step S14a is performed.

In the etch-back step in Step S14a, the silicon film PS2 is not etched back over the entire thickness thereof. The etching is ended at the stage where the silicon film PS2 corresponding to a part of the thickness thereof is etched back. Consequently, at the stage where the etch-back step in Step S14 has been ended, the silicon film PS2 remains in the form of a layer, the memory gate electrode MG has not been formed yet, and the insulating film MZ has not been exposed.

In the etch-back process in Step S14a, the oxide film OX2 and the silicon film PS2 are preferably etched under etching conditions such that the oxide film OX2 is less likely to be etched than the silicon film PS2. That is, in Step S14a, the oxide film OX2 and the silicon film PS2 are preferably etched back under etching conditions such that the speed of etching the oxide film OX2 is lower than the speed of etching the silicon film PS2. This allows the oxide film OX2 to properly function as an etching inhibiting film in the etch-back step in Step S14a.

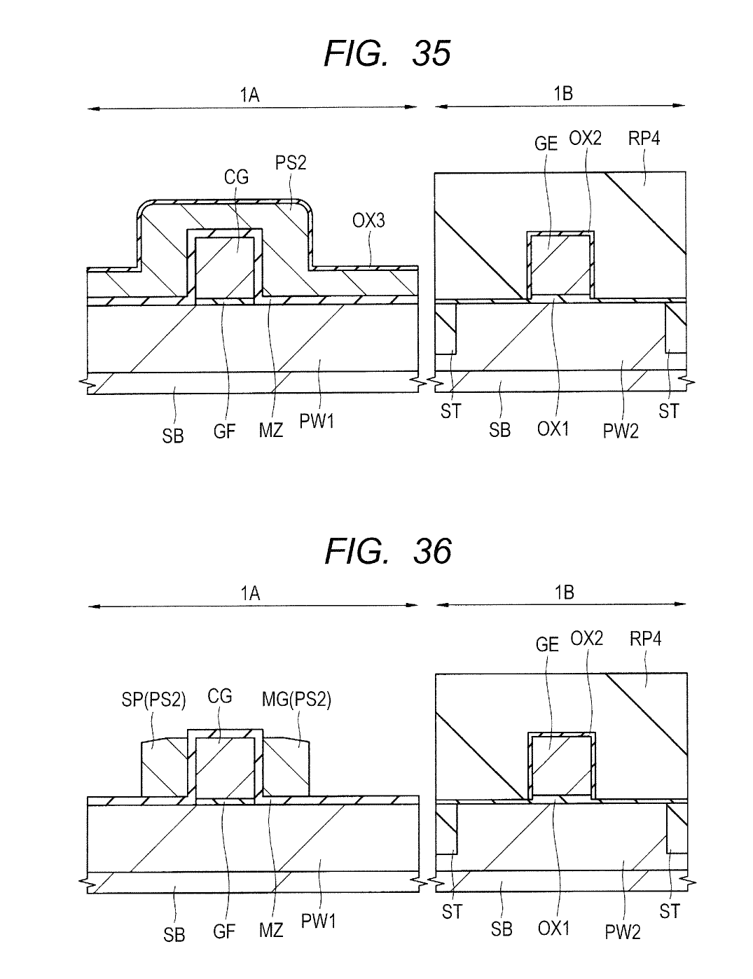

Then, the top surface of the silicon film PS2 exposed by the etch-back process in Step S14a is oxidized to form an oxide film (silicon dioxide film) OX3 over the top surface (exposed surface) of the silicon film PS2 (Step S14b in FIG. 32). FIG. 35 corresponds to the stage where the oxidation step in Step S14b has been performed.

Then, using an anisotropic etching technique, the oxide film OX3 and the silicon film PS2 are etched back (Step S14c in FIG. 32). FIG. 36 corresponds to the stage where the etch-back step in Step S14c has been performed.

In the etch-back process in Step S14c, the oxide film OX3 and the silicon film PS2 are preferably etched back under etching conditions such that the oxide film OX3 is less likely to be etched than the silicon film PS2. That is, in Step S14c, the oxide film OX3 and the silicon film PS2 are preferably etched back under etching conditions such that the speed of etching the oxide film OX3 is lower than the speed of etching the silicon film PS2. This allows the oxide film OX3 to properly function as the etching inhibiting film in the etch-back step in Step S14c.

By the etch-back step in Step S14a and the etch-back step in Step S14c, the silicon film PS2 is etched back over the entire thickness thereof. As a result, when the etch-back step in Step S14c is performed, as shown in FIG. 36, over the memory cell region 1A, the memory gate electrode MG is formed over one of the side walls of the control gate electrode CG via the insulating film MZ and the silicon spacer SP is formed over the other side wall of the control gate electrode CG via the insulating film MZ, while the silicon film PS2 is removed from the other region. When the etch-back step in Step S14c is ended, over the memory cell region 1A, the region of the insulating film MZ which is uncovered with the silicon spacer SP and the memory gate electrode MG is exposed.

Thus, in Embodiment 2, the step of forming the silicon spacer SP and the memory gate electrode MG (Step S14) includes Step S14a of etching back the oxide film OX2 and the silicon film PS2, Step S14b of forming an oxide film OX3 over the exposed top surface of the silicon film PS2, and Step S14c of etching back the oxide film OX3 and the silicon film PS2.

Also, in Embodiment 2, in Step S14b, the oxide film OZ3 is formed by oxidation treatment. The oxidation treatment is preferably plasma oxidation. This allows the formed film thickness of the thin oxide film OX3 to be easily controlled to an intended film thickness. As a result, the oxide film OX3 having a film thickness which is appropriate to allow the oxide film OX3 to function as the etching inhibiting film in the etch-back step in Step S14c can be formed more properly in Step S14b. When plasma oxidation is used as the oxidation treatment in Step S14b, the etch-back step in Step S14a, the oxidation step in Step S14b, and the etch-back step in Step S14c can be performed using the same plasma treatment apparatus. Accordingly, it is possible to perform the etch-back step in Step S14a, the oxidation step in Step S14b, and the etch-back step in Step S14c with the semiconductor substrate SB being placed in the processing room (chamber) of the same plasma treatment apparatus. This allows Steps S14a, S14b, and S14c to be easily performed and can reduce the time and labor which are needed to perform Steps S14a, S14b, and S14c. Therefore, it is possible to improve the throughput of the semiconductor device and reduce the manufacturing cost of the semiconductor device.

When the etch-back step in Step S14a, the oxidation step in Step S14b, and the etch-back step in Step S14c are performed with the semiconductor substrate SB being placed in the processing room (chamber) of the same plasma treatment apparatus, the gas used in the oxidation step in Step S14b is different from the gas used in the etch-back step in each of Steps S14a and S14c. In Step S14b, the oxidation treatment using an oxygen plasma is performed to inhibit etching.

That is, Embodiment 2 corresponds to the case where, while the silicon film PS2 is etched back in Step S14 in Embodiment 1 described above, etching is temporarily stopped, the exposed top surface of the silicon film PS2 is oxidized with the oxygen plasma to form the oxide film OX3, and then the oxide film OX3 is etched back again. In other words, forming the oxide film OX3 over the top surface of the silicon film PS2 during the etching back of the silicon film PS2 in Step S14 in Embodiment 1 described above corresponds to Embodiment 3.

The other process steps in Embodiment 2 are substantially the same as in Embodiment 1 described above so that a repeated description thereof is omitted herein.

In Embodiment 1 described above, the silicon film PS2 is etched back using the oxide film OX2 as the etching inhibiting film in Step S14 to form the memory gate electrode MG. This can bring the cross-sectional shape of the formed memory gate electrode MG closer to a rectangle. On the other hand, in Embodiment 2, the silicon film PS2 is etched back using the oxide film OX2 as the etching inhibiting film in Step S14a and the silicon film PS2 is etched back using the oxide film OX3 as the etching inhibiting film in Step S14c to form the memory gate electrode MG. This can bring the cross-sectional shape of the formed memory gate electrode MG closer to a rectangle.

To bring the cross-sectional shape of the memory gate electrode MG closer to a rectangle, it is necessary to ensure a given thickness to the etching inhibiting film when the silicon film PS2 is etched back. However, when the thickness of the etching inhibiting film when the silicon film PS2 is etched back is increased, the silicon film PS2 except for the portions thereof serving as the memory gate electrode MG and the silicon spacer SP is locally left to increase the risk of leaving the etching residues of the silicon film PS2.

By contrast, in Embodiment 2, a plurality of films, which are the oxide films OX2 and OX3 herein, are used as the etching inhibiting film when the silicon film PS2 is etched back. Accordingly, the respective thicknesses of the oxide films OX2 and OX3 can be reduced. That is, when the sum of the thickness (formed film thickness) of the oxide film OX2 formed in Step S13 in Embodiment 2 and the thickness (formed film thickness) of the oxide film OX3 formed in Step S14b is adjusted to be about the same as the thickness (formed film thickness) of the oxide film OX2 formed in Step S13 in Embodiment 1 described above, the effect of providing the memory gate electrode MG with a rectangular cross-sectional shape is substantially the same. Accordingly, the oxide film OX2 formed in Step S13 in Embodiment 2 can have a thickness smaller than the thickness of the oxide film OX2 formed in Step S13 in Embodiment 1 described above. Also, the oxide film OX3 formed in Step S14b in Embodiment 2 can have a thickness smaller than the thickness of the oxide film OX2 formed in Step S13 in Embodiment 1 described above. As a result, in Embodiment 2, the effect of being able to reduce the risk that, at the stage where Step S14 has been ended, the silicon film PS2 except for the portions thereof serving as the memory gate electrode MG and the silicon spacer SP is locally left to result in the etching residues of the silicon film PS2 can also be obtained in addition to the effects obtained in Embodiment 1 described above. This can further improve the manufacturing yield of the semiconductor device.

On the other hand, in the case of Embodiment 1 described above, the oxidation step in Step S14b need not be performed, while the etch-back step in Step S14 needs to be performed only once. This can reduce the number of the steps in the manufacturing process of the semiconductor device. Accordingly, it is possible to reduce the manufacturing time of the semiconductor device and improve the throughput thereof. It is also possible to reduce the manufacturing cost of the semiconductor device.

Also, in Embodiment 2, after the etch-back step in Step S14a, the oxidation step in Step S14b and the etch-back step in Step S14c can be performed in one or more cycles. That is, the description has been given of the case where, in the case of FIGS. 32 to 36, after the etch-back step in Step S14a, the oxidation step in Step S14b and the etch-back step in Step S14c are performed in one cycle. However, in another form, it is also possible to perform the oxidation step in Step S14b and the etch-back step in Step S14c in two or more cycles after the etch-back step in Step S14a.

The case where, e.g., the oxidation step in Step S14b and the etch-back step in Step S14c are performed in two cycles is as follows.

That is, after the etch-back step in Step S14a is performed, the oxidation treatment is performed in Step S14b to form the oxide film OX3 over the exposed top surface of the silicon film PS2. Then, in Step S14c, the oxide film OX3 and the silicon film PS2 are etched back. At this time, at the stage where Step S14c has been ended, the silicon film PS2 remains in the form of a layer, the memory gate electrode MG has not been formed yet, and the insulating film MZ has not been exposed. Then, in Step S14b, the oxidation treatment is performed again to form an oxide film (equivalent to the oxide film OX3) over the exposed top surface of the silicon film PS2. Then, in Step S14c, the oxide film (equivalent to the oxide film OZ3) and the silicon film PS2 are etched back. As a result, as shown in FIG. 36 described above, the memory gate electrode MG is formed over one of the side walls of the control gate electrode CG via the insulating film MZ over the memory cell region 1A and the silicon spacer SP is formed over the other side wall of the control gate electrode CG via the insulating film MZ, while the silicon film PS2 is removed from the other region. Over the memory cell region 1A, the region of the insulating film MZ which is uncovered with the silicon spacer SP and the memory gate electrode MG is exposed.

### Embodiment 3

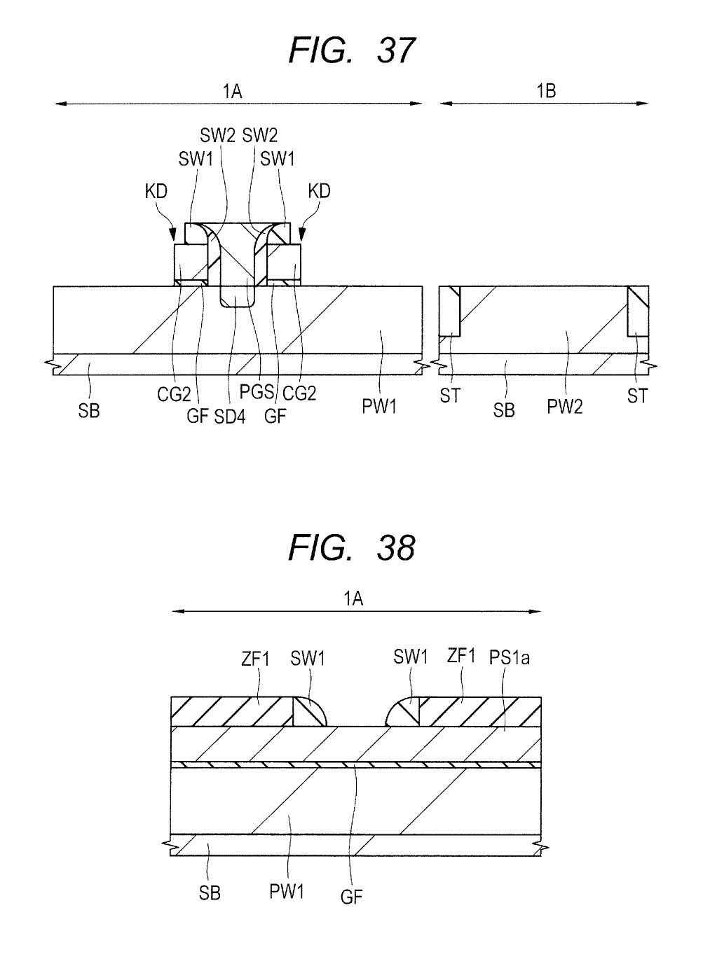

FIGS. 37 to 55 are main-portion cross-sectional views of a semiconductor device in Embodiment 3 during the manufacturing process thereof.

In Embodiment 1 described above, the memory cell in the nonvolatile memory is a memory cell of a type which stores charges in the insulating film (corresponding to the foregoing insulating film MZ). However, in Embodiment 3, a memory cell in a nonvolatile memory is a memory cell of a type which stores charges in a floating gate electrode (corresponding to the gate electrode CG2 described later).

The following will describe the manufacturing process of the semiconductor device in Embodiment 3 with reference to FIGS. 37 to 55. Here, the difference with Embodiment 1 described above will mainly be described and a repetitive description of the same content as that of Embodiment 1 described above is omitted.

In Embodiment 3 also, in the same manner as in Embodiment 1 described above, the semiconductor substrate SB is prepared in Step S1 described above, the isolation region ST is formed in Step S2 described above, and the p-type wells PW1 and PW2 are formed in Step S3 described above to obtain the structure in FIG. 3 described above.

Then, in Embodiment 3, the step equivalent to Step S4 described above is performed to form the gate electrode CG2 over the semiconductor substrate SB (p-type well PW1) via the insulating film (gate insulating film) GF over the memory cell region 1A, as shown in FIG. 37.

In Step S4 in Embodiment 1 described above, the control gate electrode CG is formed over the memory cell region 1A of the semiconductor substrate SB (p-type well PW1) via the insulating film (gate insulating film) GF. By contrast, in Embodiment 3, the gate electrode CG2 is formed instead of the control gate electrode CG in the step equivalent to Step S4 described above. The gate electrode CG is formed over the memory cell region 1A of the semiconductor substrate SB (p-type well PW1) via the insulating film (gate insulating film) GF.

Embodiment 3 is different from Embodiment 1 described above in a specific method for Step S4. An example thereof will be described with reference to FIGS. 38 to 42. Note that FIGS. 38 to 42 show an example of a step equivalent to Step S4 in Embodiment 3 and another method can also be used. Accordingly, only the memory cell region 1A is illustrated and the illustration of the peripheral circuit region 1B is omitted.

First, as shown in FIG. 38, over the main surface of the semiconductor substrate SB, the insulating film GF for a gate insulating film is formed. Then, over the main surface of the semiconductor substrate SB, i.e., over the insulating film GF, a silicon film (doped polysilicon film) PSla is formed as a conductive film for forming the gate electrode CG2. Then, over the silicon film PS1a, an insulating film ZF1 made of a silicon nitride film or the like is formed. Subsequently, the insulating film ZF1 is patterned using a photolithographic method and an etching method. Then, over the side walls of the patterned insulating film ZF1, side-wall insulating films SW1 are formed by the same method of forming the foregoing sidewall spacers SW.

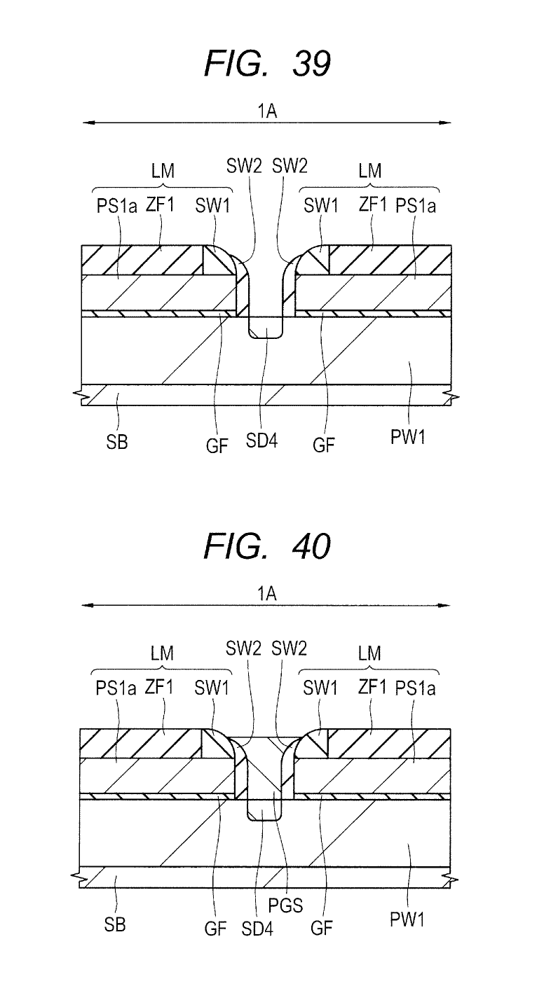

Next, as shown in FIG. 39, using the insulating film ZF1 and the side-wall insulating films SW1 as an etching mask, the silicon film PS1a and the insulating film GF are etched to remove the respective portions of the silicon film PS1a and the insulating film GF which are uncovered with the insulating film ZF1 and the side-wall insulating films SW1. As a result, laminated bodies LM each including the silicon film PS1a and the side-wall insulating film SW1 and the insulating film ZF1 each located over the silicon film PS1a are formed. Then, over the side walls (side walls including the side surfaces of the silicon films PS1a and the side surfaces of the side-wall insulating films SW1) of the laminated bodies LM, side-wall insulating films SW2 are formed by the same method of forming the foregoing sidewall spacers SW. Then, by an ion implantation method, an n-type semiconductor region SD4 is formed in the semiconductor substrate SB (p-type well PW1). The n-type semiconductor region SD4 is a source or drain semiconductor region and can function as the source semiconductor region herein.

The n-type semiconductor region SD4 can be formed by introducing an n-type impurity into the semiconductor substrate SB (p-type well PW1) by an ion implantation method using the laminated bodies LM and the side-wall insulating films SW2 over the side walls of the laminated bodies LM as a mask (ion implantation inhibiting mask). In plan view, the n-type semiconductor region SD4 is formed between the laminated bodies LM adjacent to each other. In another form, the n-type semiconductor region SD4 can also be formed by ion implantation after the silicon film PS1a is etched and before the side-wall insulating films SW2 are formed. Alternatively, the n-type semiconductor region SD4 can also be formed after the side-wall insulating films SW1 are formed and before the silicon film PS1a is etched.

Next, as shown in FIG. 40, between the adjacent laminated bodies LM, a silicon plug PGS is formed. The silicon plug PGS is adjacent to the side walls of the laminated bodies LM via the side-wall insulating films SW2. For example, a silicon film (preferably, a doped polysilicon film) for the silicon plug PGS is formed over the semiconductor substrate SB so as to cover the laminated bodies LM and be embedded in the space between the adjacent laminated bodies LM. Then, the silicon film is etched back to thus be able to form the silicon plug PGS. The silicon plug PGS is formed over the n-type semiconductor region SD4. The lower surface of the silicon plug PGS comes in contact with the upper surface of the n-type semiconductor region SD4 to electrically couple the silicon plug PGS to the n-type semiconductor region SD4.

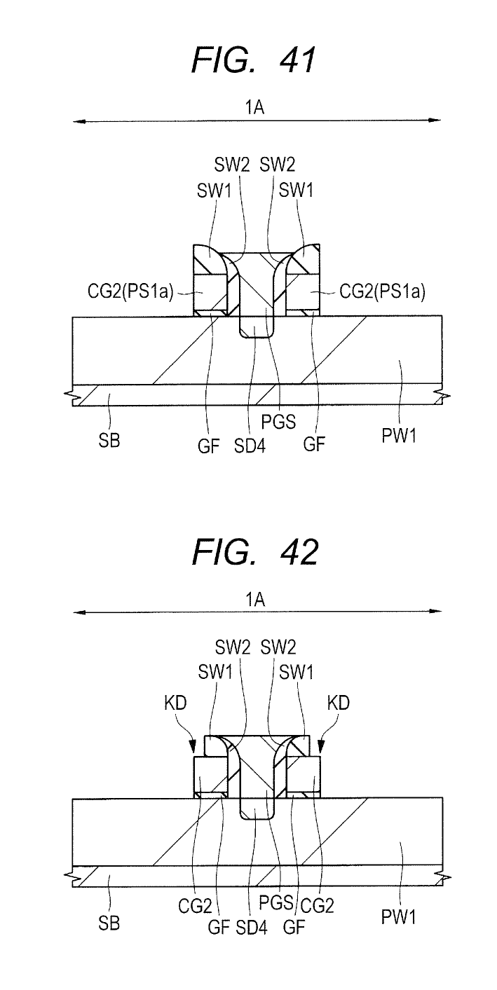

Next, as shown in FIG. 41, the insulating film ZF1 included in each of the laminated bodies LM is removed by etching and then the silicon film PS1a exposed as a result of removing the insulating film ZF1 is removed by etching. At this time, the silicon film PS1a remains under each of the side-wall insulating films SW1. The silicon films PS1a remaining under the side-wall insulating films SW1 form the gate electrodes CG2. Accordingly, at this stage, in plan view, the two-dimensional shapes of the gate electrodes CG2 and the two-dimensional shapes of the side-wall insulating films SW1 substantially match.

Next, as shown in FIG. 42, the side-wall insulating films SW1 are isotropically etched. At this time, not the entire side-wall insulating films SW1 are etched and removed, but parts of the side-wall insulating films SW1 are etched. As a result, even when the etching is ended, the side-wall insulating films SW1 having reduced dimensions remain. That is, the dimensions of the side-wall insulating films SW1 at the stage immediately after the isotropic etching is performed are smaller than the dimensions of the side-wall insulating films SW1 at the stage immediately before the isotropic etching. Also, in the isotropic etching, the side surfaces of the side-wall insulating films SW1 which are adjacent to the silicon plug PGS via the side-wall insulating films SW2 are covered with the side-wall insulating films SW2 and therefore are not etched, while the opposite side surfaces of the side-wall insulating films SW1 are side-etched. As a result, at the stage after the isotropic etching has been performed, the two-dimensional shapes of the side-wall insulating films SW1 are smaller than the two-dimensional shapes of the gate electrodes CG2 in plan view. Accordingly, the regions of the upper surfaces of the gate electrodes CG2 which are closer to the n-type semiconductor region SD4 (closer to the source) are covered with the side-wall insulating films SW1, while the opposite regions of the upper surfaces of the gate electrodes CG2 are uncovered with the side-wall insulating films SW1 and exposed. Consequently, upper-surface corner portions KD of the gate electrodes CG2 and the regions in the vicinities thereof are also uncovered with the side-wall insulating films SW1 and exposed. Here, the upper-surface corner portions KD of the gate electrodes CG2 correspond to the upper-surface corner portions of the gate electrodes CG2 which are farther away from the n-type semiconductor region SD4. The insulating films GF remaining under the gate electrodes CG2 serve as gate insulating films.

In this manner, the structure of FIG. 42 is formed in the memory cell region 1A and the structure in FIG. 37 described above is thus obtained. The structure in the memory cell region 1A in FIG. 37 described above corresponds to the structure in FIG. 42.

Thus, the step equivalent to Step S4 is performed and, as shown in FIGS. 37 and 42 described above, the gate electrodes CG2 are formed over the memory cell region 1A of the semiconductor substrate SB (p-type well PW1) via the insulating films (gate insulating films) GF.

In the case of Embodiment 3, at this stage, the n-type semiconductor region SD4 and the silicon plug PGS placed over the n-type semiconductor region SD and electrically coupled to the n-type semiconductor region SD4 are formed. The gate electrodes CG2 are adjacent to the silicon plugs PGS via the side-wall insulating films SW2.

Note that FIGS. 37 to 55 show the formation of the two memory cells sharing the source region (which is the n-type semiconductor region SD4 herein) over the memory cell region 1A. As a result, the silicon plug PGS is placed between the gate electrodes CG2 of the memory cells which are adjacent to each other with the source n-type semiconductor region SD4 being interposed therebetween.

The following steps are similar to the steps including and subsequent to Step S5 in Embodiment 1 described above.

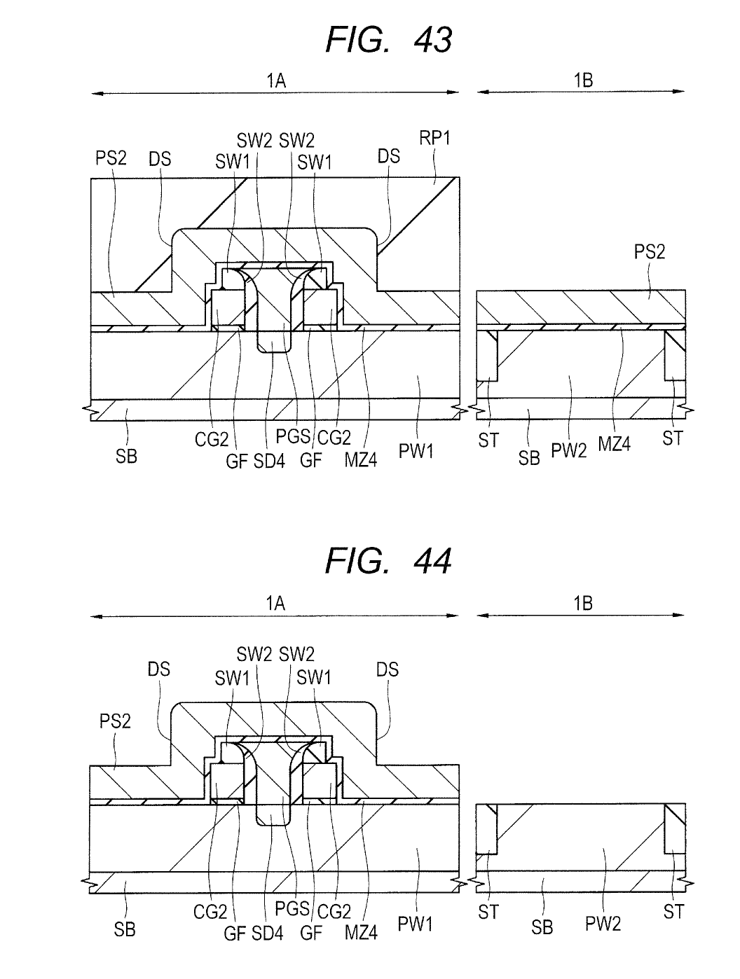

That is, in Embodiment 3 also, the step equivalent to Step S5 described above is performed to form an insulating film MZ4 for the gate insulating films over the main surface (top surface) of the semiconductor substrate SB and over the exposed surfaces (the side surfaces and the portions of the upper surfaces which are uncovered with the side-wall insulating films SW1) of the gate electrodes CG2, as shown in FIG. 43. Consequently, the insulating film MZ4 is formed over the semiconductor substrate SB so as to cover the gate electrodes CG2, the side-wall insulating films SW1, and the silicon plug PGS. Note that there may also be a case where, over the top surfaces of the side-wall insulating films SW1 and over the isolation region ST, the insulating film MZ4 is not formed.

In Embodiment 1 described above, the insulating film MZ is formed in Step S5. However, in the case of Embodiment 3, in the step equivalent to Step S5, the insulating film MZ4 is formed instead of the insulating film MZ. In the case of Embodiment 1 described above, the insulating film MZ has the charge storage portion. By contrast, in the case of Embodiment 3, each of the gate electrodes CG2 has a charge storing function so that the insulating film MZ4 has no charge storage portion and therefore is not a trapping insulating film. Accordingly, as the insulating film MZ4, a single-layer insulating film can be used and, e.g., a silicon dioxide film can be used. The silicon dioxide film forming the insulating film MZ4 can be formed using, e.g., a thermal oxidation method or a CVD method.

Next, the step corresponding to Step S6 described above is performed to form the silicon film PS2 as the conductive film for forming gate electrodes MG2 over the entire main surface of the semiconductor substrate SB, i.e., over the insulating film MZ4 so as to cover the gate electrodes CG2 and the silicon plug PGS over the memory cell region 1A as shown in FIG. 43. Note that, in Embodiment 1 described above, the silicon film PS2 is the film (conductive film) for forming the memory gate electrodes MG of the memory cells. By contrast, in the case of Embodiment 3, the silicon film PS2 is a film (conductive film) for forming the gate electrodes MG2 of the memory cells.

By thus performing the steps equivalent to Steps S5 and S6, the conductive film for the gate electrodes MG2 of the memory cells (which is the silicon film PS2 herein) is formed over the semiconductor substrate SB via the insulating film MZ4 so as to cover the gate electrodes CG2 and the silicon plug PGS.

Next, a step equivalent to Step S7 described above is performed. That is, as shown in FIG. 43, the same photoresist pattern RP1 as formed in Embodiment 1 described above is formed. Then, using the photoresist pattern RP1 as an etching mask, the silicon film PS2 and the insulating film MZ4 over the peripheral circuit region 1B are etched and removed. Subsequently, the photoresist pattern RP1 is removed. FIG. 44 shows this stage.

Thus, in the step equivalent to Step S7, the silicon film PS22 and the insulating film MZ4 are removed from the peripheral circuit region 1B, while the silicon film PS2 and the insulating film MZ4 are left over the memory cell region 1A.

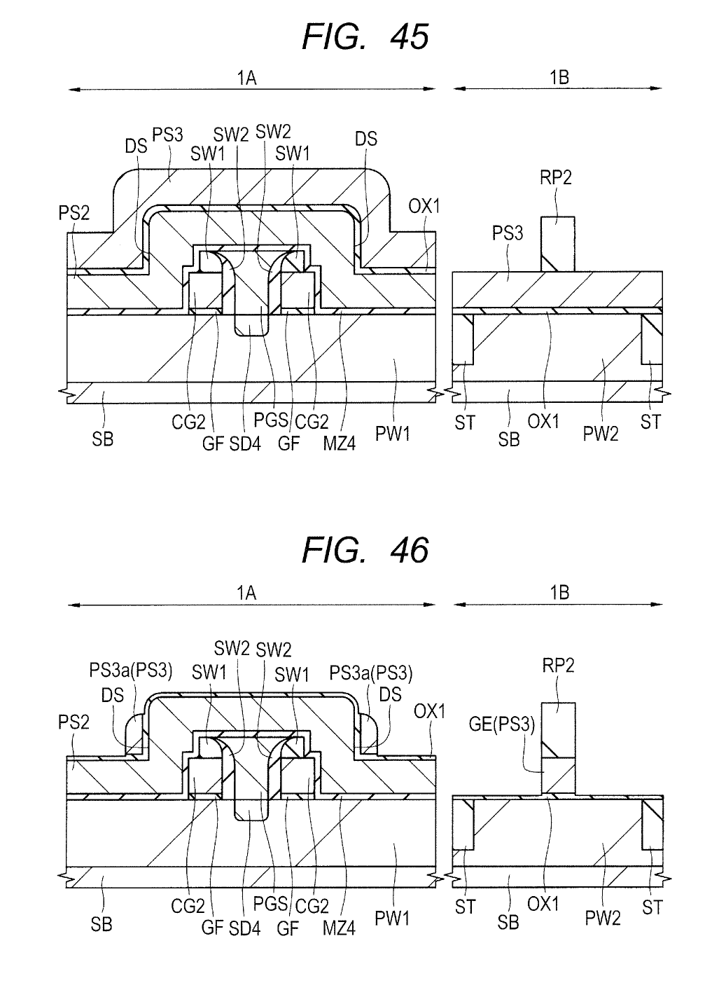

Next, a step equivalent to Step S8 described above is performed. The step equivalent to Step S8 is substantially the same as in Embodiment 1 described above. That is, as shown in FIG. 45, the insulating film OX1 is formed over the top surface of the silicon film PS2 and the peripheral circuit region 1B of the main surface of the semiconductor substrate SB (top surface of the p-type well PW2).

Next, a step equivalent to Step S9 described above is performed. The step equivalent to Step S9 is substantially the same as in Embodiment 1 described above. That is, as shown in FIG. 45, over the entire main surface of the semiconductor substrate SB, i.e., over the insulating film OX1, the silicon film PS3 is formed as the conductive film for forming the gate electrode GE.

By thus performing the step equivalent to Step S8 and the step equivalent to Step S9, over the silicon film PS2 over the memory cell region 1A and over the peripheral circuit region 1B of the semiconductor substrate SB, the conductive film for the gate electrode GE of the MISFET is formed via the insulating film OX1 (which is the silicon film PS3 herein).

Next, a step equivalent to Step S10 described above is performed. The step equivalent to Step S10 is substantially the same as in Embodiment 1 described above. That is, as shown in FIG. 45, the same photoresist pattern RP2 as formed in Embodiment 1 described above is formed. Then, as shown in FIG. 46, using the photoresist pattern RP2 as an etching mask, the silicon film PS3 is etched using an anisotropic etching technique to form the gate electrode GE. At this stage, in the same manner as in Embodiment 1 described above, parts of the silicon film PS3 are left as the remaining portions PS3a at the positions adjacent to the stepped portions DS of the silicon film PS2 via the insulating film OX1.

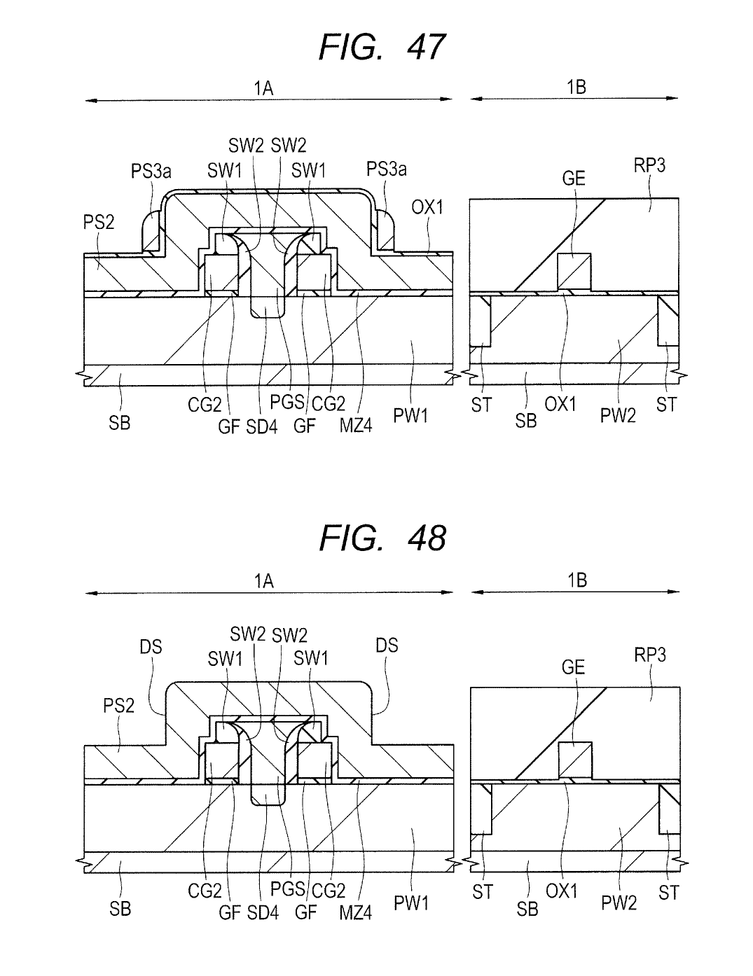

Next, a step equivalent to Step S11 described above is performed. The step equivalent to Step S11 is substantially the same as in Embodiment 1 described above. That is, as shown in FIG. 47, the same photoresist pattern RP3 as formed in Embodiment 1 described above is formed. Then, using the photoresist pattern RP3 as an etching mask, isotropic etching is performed to thus etch and remove the remaining portions PS3a of the silicon film PS3 from the memory cell region 1A, as shown in FIG. 48.

Next, a step equivalent to Step S12 described above is performed. The step equivalent to Step S12 is substantially the same as in Embodiment 1 described above. That is, using the photoresist pattern RP3 as an etching mask, the insulating film OX1 over the memory cell region 1A is etched to be removed. FIG. 48 shows this stage.

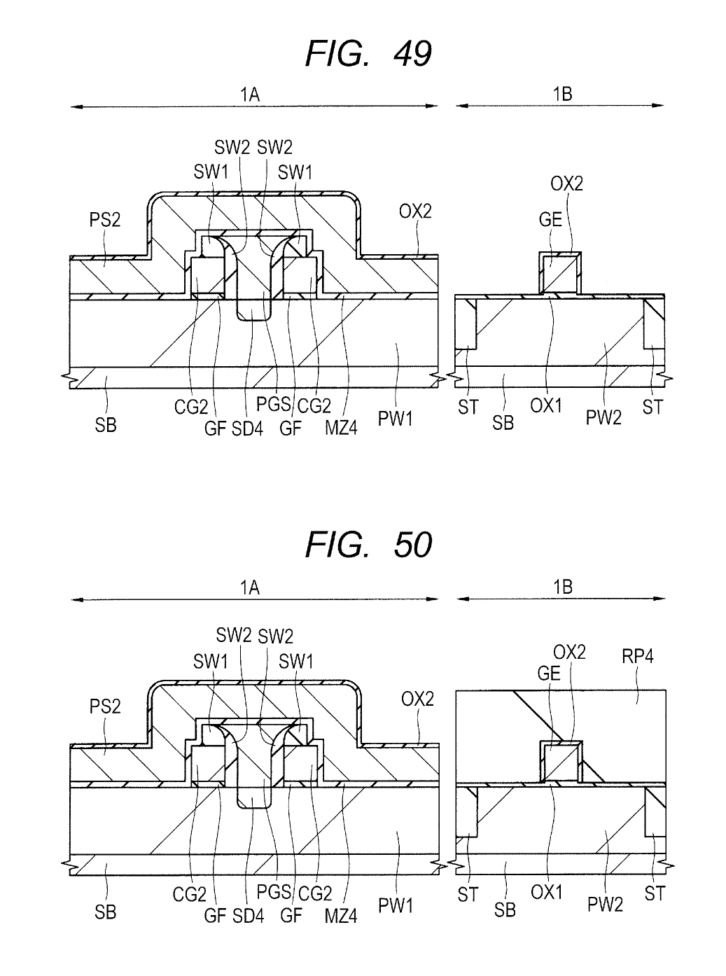

Next, a step equivalent to Step S13 described above is performed. The step equivalent to Step S13 is substantially the same as in Embodiment 1 described above. That is, as shown in FIG. 49, the top surface of the silicon film PS2 is oxidized to form the oxide film OX2 as an insulating film over the top surface of the silicon film PS2.

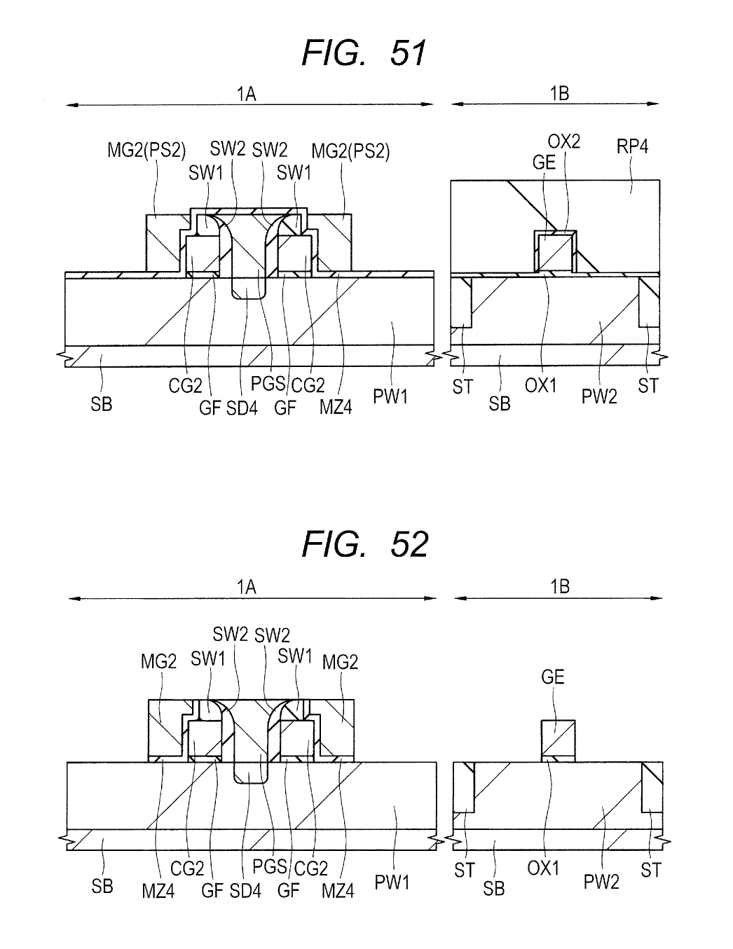

Next, a step equivalent to Step S14 described above is performed. The step equivalent to Step S14 described above is substantially the same as in Embodiment 1 described above. That is, as shown in FIG. 50, the same photoresist pattern RP4 as in Embodiment 1 described above is formed. Then, as shown in FIG. 51, the oxide film OX2 and the silicon film PS2 are etched back using an anisotropic etching technique to form the gate electrodes MG2. Each of the gate electrodes MG2 is made of the silicon film PS2 remaining over one of the side walls (side wall opposite to the side wall adjacent to the silicon plug PGS via the side-wall insulating film SW2) of the gate electrode CG2 via the insulating film MZ4. The gate electrodes MG2 are formed over the insulating film MZ4 so as to be adjacent to the gate electrodes CG2 via the insulating film MZ4. Then, the photoresist pattern RP4 is removed.

The gate electrodes MG2 are adjacent to the gate electrodes CG2 via the insulating film MZ4. Of the both side walls of each of the gate electrodes CG2, the side wall closer to the source (closer to the n-type semiconductor region SD4) is adjacent to the silicon plug PGS via the side-wall insulating film SW2 and the side wall opposite thereto is adjacent to the gate electrode MG2 via the insulating film MZ4.

Note that, in Embodiment 1 described above, the memory gate electrode MG is formed over one of the side walls of the control gate electrode CG and the silicon spacer SP is formed over the other side wall thereof. On the other hand, in Embodiment 3, the silicon plug PGS is present over the source of the gate electrodes CG2 via the side-wall insulating films SW2. Accordingly, the gate electrodes MG2 equivalent to the memory gate electrode MG are formed, but no equivalent to the silicon spacer SP is formed. Therefore, in Embodiment 3, Step S15 (the step of removing the silicon spacer SP) described above need not be performed.

Next, a step equivalent to Step S16 described above is performed to remove the portions of the insulating film MZ4 which are uncovered with the gate electrodes MG2 and exposed by etching (e.g., wet etching), as shown in FIG. 52. In the case of Embodiment 1 described above, the insulating film MZ is removed while, in the case of Embodiment 3, the insulating film MZ4 is removed.

Thus, the gate electrodes MG2 are formed over the semiconductor substrate SB (p-type well PW1) via the insulating films MZ4 so as to be adjacent to the gate electrodes CG2 via the insulating films MZ4. The gate electrodes CG2 and the gate electrodes MG2 are gate electrodes included in the memory cells of the nonvolatile memory.

Next, a step equivalent to Step S17 described above is performed to form the n⁻-type semiconductor regions (n-type impurity diffusion layers, extension regions, or LDD regions) EX3 and EX5 using an ion implantation method. The n⁻-type semiconductor region EX3 in the peripheral circuit region 1B is the same as in Embodiment 1 described above. In the memory cell region 1A, the n⁻-type semiconductor regions EX5 are formed by self-alignment with the side walls (side walls opposite to the side walls adjacent to the gate electrodes CG2 via the insulating films MZ4) of the gate electrodes MG2 as a result of the gate electrodes MG2 functioning as a mask (ion implantation inhibiting mask).

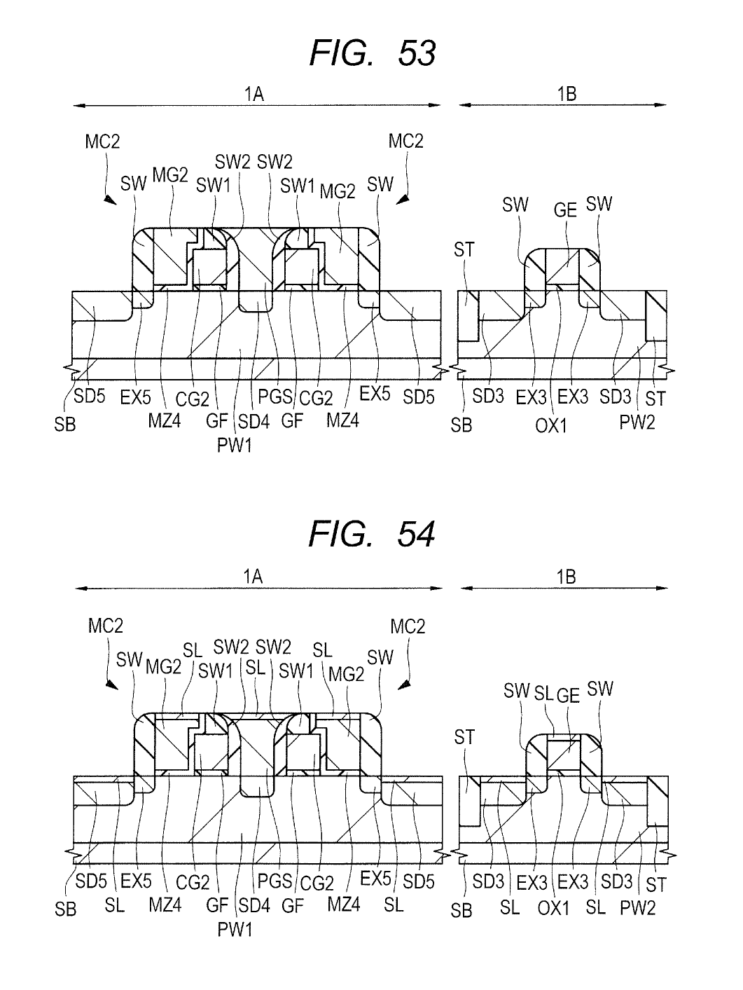

Next, a step equivalent to Step S18 described above is performed to form the sidewall spacers SW, as shown in FIG. 53. The sidewall spacers SW are formed over the both side walls of the gate electrode GE over the peripheral circuit region 1B, while the sidewall spacer SW is formed over one of the side walls (side wall opposite to the side wall adjacent to the gate electrode CG2 via the insulating film MZ4) of each of the gate electrodes MG2 over the memory cell region 1A.

Next, a step equivalent to Step S19 described above is performed to form the n⁺-type semiconductor regions (n-type impurity diffusion layers or source/drain regions) SD3 and SD5 using an ion implantation method, as shown in FIG. 53. The n⁻-type semiconductor region SD3 in the peripheral circuit region 1B is the same as in Embodiment 1 described above. In the memory cell region 1A, the n⁺-type semiconductor regions SD5 are formed by self-alignment with the sidewall spacers SW over the side walls (side walls opposite to the side walls adjacent to the gate electrodes CG2 via the insulating films MZ4) of the gate electrodes MG2 as a result of the gate electrodes MG2 and the sidewall spacers SW functioning as a mask (ion implantation inhibiting mask). Each of the n⁺-type semiconductor regions SD5 has an impurity concentration higher than that of each of the n⁻-type semiconductor regions EX5 and a junction depth deeper than that thereof. The n⁻-type semiconductor regions EX5 and SD5 form a source or drain semiconductor region of the memory cell. One of the source semiconductor region and the drain semiconductor region of the memory cell is formed of the n-type semiconductor region SD4, while the other of the source semiconductor region and the drain semiconductor region is formed of the n⁻-type semiconductor region EX5 and the n⁺-type semiconductor region SD5. Here, the n-type semiconductor region SD4 can function as the source semiconductor region, while the n⁻-type semiconductor region EX5 and the n⁺-type semiconductor region SD5 can function as the drain semiconductor region.

Next, an activation anneal step equivalent to Step S20 described above is performed. The activation anneal step equivalent to Step S20 is substantially the same as in Embodiment 1.

Thus, as shown in FIG. 53, the memory cells MC2 of the nonvolatile memory are formed in the memory cell region 1A, while the MISFET is formed in the peripheral circuit region 1B.

Next, as shown in FIG. 54, the metal silicide layers SL are formed as necessary. The metal silicide layers SL can be formed in the respective upper portions of the gate electrodes MG2, the gate electrode GE, the n⁺-type semiconductor regions SD3 and SD5, and the silicon plug PGS by performing a salicide process.

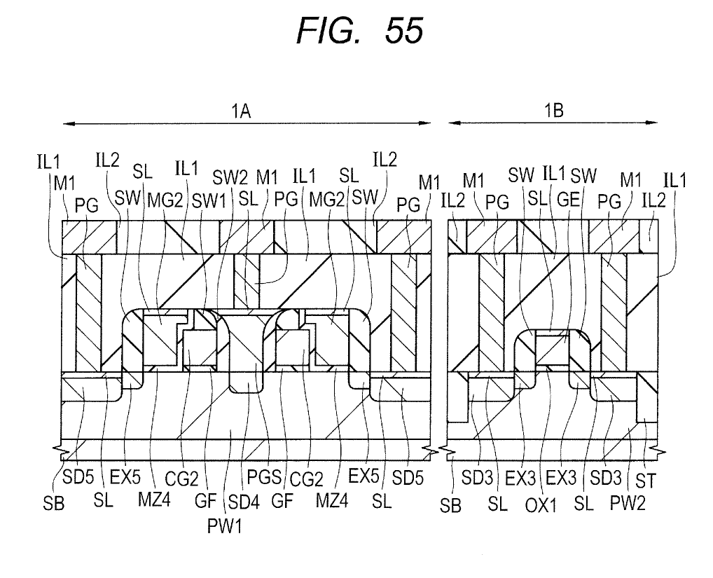

Next, as shown in FIG. 55, over the entire main surface of the semiconductor substrate SB, the interlayer insulating film IL1 is formed so as to cover the gate electrodes CG2, the gate electrodes MG2, the gate electrode GE, the silicon plug PGS, and the sidewall spacers SW in the same manner as in Embodiment 1 described above. Then, in the same manner as in Embodiment 1 described above, contact holes are formed in the interlayer insulating film IL1 and the plugs PG are formed in the contact holes. Note that, in Embodiment 3, the respective plugs PG are formed over the gate electrodes MG2, the gate electrode GE, the silicon plug PGS, the n⁺-type semiconductor regions SD3, and the n⁺-type semiconductor regions SD5, but the plugs PG are not formed over the gate electrodes CG2. That is, the plugs PG and the wires M1 which are electrically coupled to the gate electrodes CG2 are not formed to set each of the gate electrodes CG2 at a floating potential. The gate electrodes CG2 are floating gate electrodes for storing charges.

Next, as shown in FIG. 55, in the same manner as in Embodiment 1 described above, the insulating film IL2 and the wires M1 are formed over the interlayer insulating film IL1 in which the plugs PG are embedded.

Thus, the semiconductor device in Embodiment 3 is manufactured.

A brief description will be given of a structure of each of the memory cells in the nonvolatile memory in the manufactured semiconductor device.

The memory cell in the nonvolatile memory includes the source semiconductor region (n-type semiconductor region SD4) formed in the p-type well PW1 of the semiconductor substrate SB, the drain semiconductor region (n⁻-type semiconductor region EX5 and n⁺-type semiconductor region SD5), and the gate electrode CG and the gate electrode MG2 which are formed over the semiconductor substrate SB (p-type well PW1) located between the source semiconductor region and the drain semiconductor region. Note that the gate electrode CG2 is formed over the semiconductor substrate SB (p-type well PW1) via the insulating film GF, while the gate electrode MG2 is formed over the semiconductor substrate SB (p-type well PW1) via the insulating film MZ4. Of the gate electrodes CG2 and MG2, the gate electrode CG2 is located closer to the source (closer to the n-type semiconductor region SD4) and the gate electrode MG2 is located closer to the drain (closer to the n⁻-type semiconductor region EX5 and the n⁺-type semiconductor region SD5). The gate electrodes MG2 and CG2 are adjacent to each other with the insulating film MZ4 being interposed therebetween. The insulating film MZ4 extends over the two regions which are the region between the gate electrode MG2 and the semiconductor substrate SB (p-type well PW1) and the region between the gate electrode MG2 and the gate electrode CG2.

To the gate electrode MG2, an intended voltage can be applied via the wire M1 and the plug PG. To the n⁺-type semiconductor region SD5, an intended voltage can be applied via the wire M1 and the plug PG. To the n-type semiconductor region SD4, an intended voltage can be applied via the wire M1, the plug PG, and the silicon plug PGS. On the other hand, the plug PG and the wire M1 are not coupled to the gate electrode CG2 which is circumferentially surrounded by the insulating films (which are the insulating film GF, the insulating film MZ4, and the side-wall insulating films SW1 and SW2 herein) and set at the floating potential. The gate electrode CG2 is floating gate electrode for storing charges. Through the storage of charges in the gate electrode CG2, information is stored. The gate electrode MG2 is a control gate electrode.

The gate electrode MG2 covers a part of the upper surface of the gate electrode CG2 (upper surface of the portion of the gate electrode CG2 which is uncovered with the side-wall insulating film SW1). From another perspective, a part of the gate electrode MG2 is mounted over the gate electrode CG2. However, the gate electrodes MG2 and CG2 are not in contact with each other, but the insulating film MZ4 is interposed therebetween. As a result, the upper-surface corner portion KD (see FIG. 42) of the gate electrode CG2 and the vicinity thereof are covered with the gate electrode MG2 via the insulating film MZ4. The upper-surface corner portion KD (see FIG. 42) of the gate electrode CG2 faces the gate electrode MG2 via the insulating film MZ4. As a result, during an erase operation, electrons are more easily moved from the upper-surface corner portion KD of the gate electrode CG2 to the gate electrode CG2 by tunneling through the insulating film MZ4.

Next, a brief description will be given of an example of operations to the nonvolatile memory in the present embodiment.

At the time of a write operation, a high voltage is applied between the source and drain regions (n-type semiconductor region SD4 and the n⁺-type semiconductor region SD5) and generated hot electrons are injected into the gate electrode CG2. The injected hot electrons (electrons) are stored in the gate electrode CG2 so that the memory cell is brought into a written state. At the time of an erase operation, a high voltage (positive high voltage) is applied to the gate electrode MG2 to cause the electrons stored in the gate electrode CG2 to tunnel through the insulating film MZ4 and move into the gate electrode MG2 (be extracted). This brings the memory cell into an erased state. At the time of a read operation, the written state or the erased state can be determined based on the threshold voltage which is different between the written state (state where electrons are stored in the gate electrode CG2) and the erased state (state where electrons are not substantially stored in the gate electrode CG2).

The technique according to Embodiment 2 described above can also be applied to Embodiment 3.

As described above, the steps including and subsequent to Step S5 in Embodiment 3 are also similar to those in Embodiment described above. Accordingly, Embodiment 3 also has the foregoing characteristic features of Embodiment 1 described above. Consequently, in Embodiment 3 also, even when the thickness of the insulating film OX1 is substantially uniform at the stage where the insulating film OX1 has been formed in the step equivalent to Step S8, parts of the insulating film OX1 are etched over the memory cell region 1A in the subsequent various steps, resulting in the non-uniform thickness of the insulating film OZ1. However, in Embodiment 3 also, in the same manner as in Embodiment 1 described above, the insulating film OX1 having the non-uniform film thickness is removed in the step equivalent to Step S12, the oxide film OX2 is formed in a step equivalent to Step S13, and then an etch-back step equivalent to Step S14 is performed. Accordingly, in Embodiment 3 also, it is possible to inhibit or prevent the height of the shoulder portion of the formed gate electrode MG2 from being reduced and bring the cross-sectional shape of the gate electrode MG2 closer to a shape (shape close to a rectangle) for the gate electrode. That is, it is possible to provide the formed gate electrode MG2 with the side surface (side surface opposite to the side surface adjacent to the gate electrode CG2 via the insulating film MZ4) which is generally perpendicular to the main surface of the semiconductor substrate SB. This can more reliably inhibit or prevent the impurity ions implanted in, e.g., the ion implantation step for forming the n⁻-type semiconductor regions EX5 or the ion implantation step for forming the n⁺-type semiconductor regions SD5 from penetrating through the gate electrodes MG2. In addition, the n⁻-type semiconductor regions EX5 and the n⁺-type semiconductor regions SD5 can more properly be formed. Therefore, it is possible to improve the reliability and performance of the semiconductor device.

While the invention achieved by the present inventors has been specifically described heretofore on the basis of the embodiments thereof, the present invention is not limited to the foregoing embodiments. It will be appreciated that various changes and modifications can be made in the invention within the scope not departing from the gist thereof.

What is claimed is:

1. A method of manufacturing a semiconductor device including a memory cell in a nonvolatile memory formed in a first region of a semiconductor substrate and a MISFET formed in a second region of the semiconductor substrate, the method comprising the steps of:
(a) providing the semiconductor substrate;
(b) forming a first gate electrode for the memory cell over the first region of the semiconductor substrate via a first insulating film;
(c) forming a first conductive film for a second gate electrode of the memory cell over the semiconductor substrate via a second insulating film so as to cover the first gate electrode;
(d) removing the first conductive film and the second insulating film from the second region to leave the first conductive film and the second insulating film over the first region;
(e) after the step (d), forming a second conductive film for a third crate electrode of the MISFET over the first conductive film over the first region and over the second region of the semiconductor substrate via a third insulating film;
(f) patterning the second conductive film to form the third gate electrode for the MISFET over the second region;
(g) after the step (f), removing the third insulating film from the first region;
(h) after the step (g), forming a fourth insulating film over the first conductive film over the first region; and
(i) etching back the fourth insulating film and the first conductive film to form the second gate electrode for the memory cell which is adjacent to the first gate electrode via the second insulating film.

2. The method of manufacturing the semiconductor device according to claim 1,
wherein, in the step (i), the fourth insulating film and the first conductive film are etched back under etching conditions such that a speed of etching the fourth insulating film is lower than a speed of etching the first conductive film.

3. The method of manufacturing the semiconductor device according to claim 1,
wherein the first conductive film is made of silicon, and
wherein the second conductive film is made of silicon.

4. The method of manufacturing the semiconductor device according to claim 3,
wherein, in the step (h), a surface of the first conductive film is oxidized to form the fourth insulating film made of an oxide film over the first conductive film over the first region.

5. The method of manufacturing the semiconductor device according to claim 3,
wherein, in the step (h), a surface of the first conductive film is plasma-oxidized to form the fourth insulating film made of an oxide film over the first conductive film over the first region.

6. The method of manufacturing the semiconductor device according to claim 1,
wherein the step (f) includes the steps of:
(f1) forming a first mask layer over the second conductive film;
(f2) anisotropically etching the second conductive film using the first mask layer as an etching mask to pattern the second conductive film and form the third gate electrode over the second region; and
(f3) removing the first mask layer.

7. The method of manufacturing the semiconductor device according to claim 6, further comprising, after the step (f3) and before the step (g), the step of:
(f4) removing a remaining portion of the second conductive film from the first region by isotropic etching.

8. The method of manufacturing the semiconductor device according to claim 7,
wherein, as the isotropic etching in the step (f4), wet etching is used.

9. The method of manufacturing the semiconductor device according to claim 7, further comprising, after the step (f3) and before the step (f4), the step of:
(f5) forming, over the semiconductor substrate, a second mask layer covering the second region and exposing the first region,
the method further comprising, after the step (g) and before the step (h), the step of:
(g1) removing the second mask layer.

10. The method of manufacturing the semiconductor device according to claim 8,
wherein, in the step (g), the third insulating film is removed from the first region by wet etching.

11. The method of manufacturing the semiconductor device according to claim 9, further comprising, after the step (f3) and before the step (f5), the step of:
(f6) performing wet cleaning treatment on the semiconductor substrate.

12. The method of manufacturing the semiconductor device according to claim 1,
wherein the second insulating film has an internal charge storage portion.

13. The method of manufacturing the semiconductor device according to claim 1,
wherein the second gate electrode is a floating gate electrode for storing charges.

14. The method of manufacturing the semiconductor device according to claim 1,
wherein the step (i) includes the steps of:
(i1) etching back the fourth insulating film and the first conductive film;
(i2) after the step (i1), oxidizing an exposed surface of the first conductive film to form a first oxide film over the exposed surface of the first conductive film; and
(i3) after the step (i2), etching back the first oxide film and the first conductive film.

15. The method of manufacturing the semiconductor device according to claim 14,
wherein, in the step (i3), the first oxide film and the first conductive film are etched back under etching conditions such that a speed of etching the first oxide film is lower than a speed of etching the first conductive film.
